(19) United States
(12) Patent Application Publication
(10) Pub. No.: US 2018/0366653 A1
(43) Pub. Date: Dec. 20, 2018

(54) D-A TYPE COMPOUND AND APPLICATION THEREOF

(71) Applicant: GUANGZHOU CHINARAY OPTOELECTRONIC MATERIALS LTD., Guangzhou, Guangdong (CN)

(72) Inventors: Ruifeng HE, Guangzhou, Guangdong (CN); Peng SHU, Guangzhou, Guangdong (CN); Jun WANG, Guangzhou, Guangdong (CN); Junyou PAN, Guangzhou, Guangdong (CN)

(21) Appl. No.: 15/781,371

(22) PCT Filed: Oct. 13, 2016
(86) PCT No.: PCT/CN2016/101997

§ 371 Date: Jun. 4, 2018

(30) Foreign Application Priority Data
Dec. 4, 2015 (CN) 201510888916.X

(51) Int. Cl. H01L 51/00; C07F 5/02; C09K 11/06

(52) U.S. Cl. CPC H01L 51/0067; C07F 5/027; H01L 51/5016; C09K 2211/1018; C09K 2211/1007; C09K 11/06

(57) ABSTRACT

A D-A type compound and an application thereof. The D-A type compound has the general formula (1) as follows,

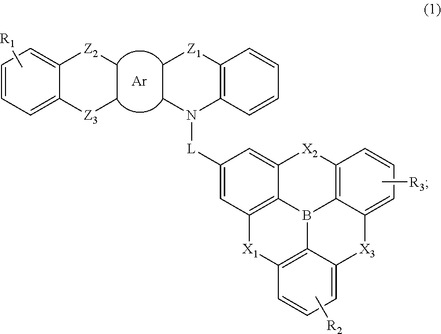

wherein L is a linking unit, -L- is selected from a single bond, a double bond, a triple bond, an aromatic group with a carbon atom number of 6 to 40, or a heteroaromatic group with a carbon atom number of 3 to 40; Ar is an aromatic group with a carbon atom number of 6 to 20, or a heteroaromatic group with a carbon atom number of 3 to 20; Z₁, Z₂ and Z₃ independently represent a single bond, N(R), B(R), C(R)₂, Si(R)₂, O, C═N(R), C═C(R)₂, P(R), P(═O)R, S, S═O or SO₂ respectively; X₁, X₂ and X₃ independently optionally represent N(R), C(R)₂, Si(R)₂, O, C═N(R), C═C(R)₂, P(R), P(═O)R, S, S═O or SO₂ respectively.

### TECHNICAL FIELD

The present disclosure relates to the field of electroluminescent materials, particularly to a D-A type compound and an application thereof.

### BACKGROUND

With the characteristics of structural diversity, relatively low manufacturing cost, superior photoelectric property, etc., organic semiconductor materials show great potential for a use in optoelectronic devices such as organic light-emitting diode (OLED), such as flat panel displays and lighting.

In order to improve the luminescence properties of the organic light-emitting diodes and promote the large-scale industrialization of the organic light-emitting diodes, a variety of new structural material systems with organic photoelectric properties have been widely developed. Wherein donor-acceptor (D-A) type photoelectric materials have been widely used in optoelectronic devices due to their good dual carrier transport properties and photoelectric properties. Particularly, nitrogen-containing donors, such as triphenylamine, carbazole, and indolocarbazole, etc., have been endued with good electron-donating properties due to lone pair electrons on nitrogen atoms. However, the properties of the D-A type photoelectric materials with nitrogen-containing donors cannot yet meet the requirements for use so far, particularly its stability still needs to be improved when used as a host. Nitrogen-containing donors are also used to construct D-A type of thermally activated delayed fluorescence (TADF) materials, but the lifetime of devices containing such TADF materials is still low.

### SUMMARY OF THE INVENTION

In view of the deficiencies of the prior art mentioned above, the purpose of the present disclosure is to provide a novel D-A type compound, a mixture and a formulation comprising the D-A compound, and its application in organic electronic devices, to solve the existing problem that D-A materials and related organic electronic devices have a low lifetime.

According to one aspect of the present disclosure, a D-A type compound with the following general formula (1) is provided:

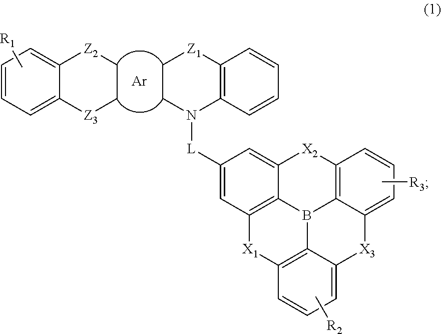

wherein, L is a linking unit, and L is selected from the group consisting of a single bond, a double bond, a triple bond, an aromatic group with a carbon atom number of 6 to 40, and a heteroaromatic group with a carbon atom number of 3 to 40;

Ar is an aromatic group with a carbon atom number of 6 to 20, or a heteroaromatic group with a carbon atom number of 3 to 20;

Z₁, Z₂ and Z₃ independently represent a single bond, N(R), B(R), C(R)₂, Si(R)₂, O, C═N(R), C═C(R)₂, P(R), P(═O)R, S, S═O or SO₂, respectively;

X₁, X₂ and X₃ independently optionally represent N(R), C(R)₂, Si(R)₂, O, C═N(R), C═C(R)₂, P(R), P(═O)R, S, S═O or SO₂, respectively;

R, R₁, R₂ and R₃ independently represent H, D, F, CN, aralkyl, alkenyl, alkynyl, nitrile, amine, nitro, acyl, alkoxy, carbonyl, sulfonyl, hydroxyl, alkyl with a carbon atom number of 1 to 30, cycloalkyl with a carbon atom number of 3 to 30, aromatic hydrocarbyl with a carbon atom number of 6 to 60, or aromatic heterocyclyl with a carbon atom number of 3 to 60, respectively.

According to another aspect of the present disclosure, a polymer in which a repeating unit comprises the above D-A type compound.

According to further aspect of the present disclosure, a mixture comprising the above D-A type compound and organic functional materials, or the above polymer and organic functional materials.

The organic functional materials may be selected from at least one of the group consisting of a hole injection material, a hole transport material, an electron injection material, an electron transport material, a hole blocking material, an electron blocking material, a light-emitting material, a host material, and an organic dyes.

According to yet another aspect of the present disclosure, a formulation comprising the above D-A type compound and at least one organic solvent;

or comprising the above polymer and at least one organic solvent;

or comprising the above mixture and at least one organic solvent.

According to still another aspect of the present disclosure, an application of the above D-A type compound or the above polymer in electronic devices.

According to another aspect of the present disclosure, an electronic device comprising the above D-A type compound, the above polymer, or the above mixture.

The use of the above D-A type compound in OLED, particularly as a light-emitting layer material, can provide higher quantum efficiency and device lifetime. The possible reasons are as follows, but not limited thereto, the D-A type compound have good electron and hole bipolar transport properties, higher fluorescence quantum efficiency and structural stability, which make it possible to improve the photoelectric properties and device stability of related devices.

### DETAILED DESCRIPTION OF THE EMBODIMENTS

The present disclosure provides a novel D-A type compound, a mixture and a formulation comprising the D-A compound, and its application in organic electronic devices. In order to make the purpose, technical solution and effects of the present disclosure clearer and more specific, the present disclosure will be furthermore described in detail below. It should be noted that, the specific embodiment illustrated herein is merely for the purpose of explanation, and should not be deemed to limit the disclosure.

In the present disclosure, formulation and printing ink, or ink, have the same meaning and they can be used interchangeably. Host material, matrix material, Host or Matrix material have the same meaning and they can be used interchangeably. Metal organic complex and organometallic complex have the same meaning and can be used interchangeably.

According to one embodiment, a D-A type compound has the following general formula (1):

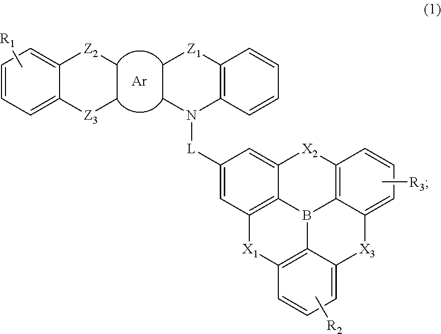

Wherein, L is a linking unit, L is selected from a single bond, a double bond, a triple bond, an aromatic group with a carbon atom number of 6 to 40, or a heteroaromatic group with a carbon atom number of 3 to 40;

Ar is an aromatic group with a carbon atom number of 6 to 20, or a heteroaromatic group with a carbon atom number of 3 to 20;

Z₁, Z₂ and Z₃ independently represent a single bond, N(R), B(R), C(R)₂, Si(R)₂, O, C═N(R), C═C(R)₂, P(R), P(═O)R, S, S═O or SO₂, respectively;

X₁, X₂ and X₃ independently optionally represent N(R), C(R)₂, Si(R)₂, O, C═N(R), C═C(R)₂, P(R), P(═O)R, S, S═O or SO₂, respectively.

In one embodiment, X₁, X₂ and X₃ may also be absent, i.e. none, which means that there is no atom or no bond linking on the positions indicated by X₁, X₂ and X₃, but at least one of X₁, X₂ and X₃ is not absent.

R, R₁, R₂ and R₃ independently represent H, deuterium, F, CN, aralkyl, alkenyl, alkynyl, nitrile, amine, nitro, acyl, alkoxy, carbonyl, sulfonyl, hydroxyl, alkyl with a carbon atom number of 1 to 30, cycloalkyl with a carbon atom number of 3 to 30, aromatic hydrocarbyl with a carbon atom number of 6 to 60, or aromatic heterocyclyl with a carbon atom number of 3 to 60, respectively.

Specifically, the aromatic group refers to hydrocarbyl comprising at least one aromatic ring, including monocyclic group and polycyclic ring system. The heteroaromatic group refers to hydrocarbyl (containing heteroatoms) comprising at least one heteroaromatic ring, including monocyclic group and polycyclic ring system. Such polycyclic rings may have two or more rings, wherein two carbon atoms are shared by two adjacent rings, i.e., fused ring. At least one of such polycyclic rings is heteroaromatic. For the purpose of the present disclosure, the aromatic or heteroaromatic ring systems not only include aromatic or heteroaromatic systems, but also a plurality of aryl or heteroaryl groups in the systems may be interrupted by short non-aromatic units (<10% of non-H atoms, preferably less than 5% of non-H atoms, such as C, N or O atoms). Therefore, systems such as 9,9′-spirobifluorene, 9,9-diarylfluorene, triarylamine, diaryl ether and the like are also considered to be aromatic ring systems for the purpose of this disclosure.

Specifically, examples of the aromatic group include: benzene, naphthalene, anthracene, phenanthrene, perylene, tetracene, pyrene, benzopyrene, triphenylene, acenaphthene, fluorene, and derivatives thereof.

Specifically, examples of the heteroaromatic group include: furan, benzofuran, thiophene, benzothiophene, pyrrole, pyrazole, triazole, imidazole, oxazole, oxadiazole, thiazole, tetrazole, indole, carbazole, pyrroloimidazole, pyrrolopyrrole, thienopyrrole, thienothiophene, furopyrrole, furofuran, thienofuran, benzisoxazole, benzisothiazole, benzimidazole, pyridine, pyrazine, pyridazine, pyrimidine, triazine, quinoline, isoquinoline, phthalazine, cinnoline, quinoxaline, phenanthridine, perimidine, quinazoline, quinazolinone and derivatives thereof.

In one embodiment, L shown in general formula (1) is selected from an aromatic group with a carbon atom number of 6 to 30, or a heteroaromatic group with a carbon atom number of 3 to 30. Furthermore, L is selected from an aromatic group with a carbon atom number of 6 to 25, or a heteroaromatic group with a carbon atom number of 3 to 25. Furthermore, L is selected from an aromatic group with a carbon atom number of 6 to 20, or a heteroaromatic group with a carbon atom number of 3 to 20.

Suitable examples of heteroaromatic group that can be used as L include, but not limited to, groups such as benzene, naphthalene, anthracene, phenanthrene, pyrene, pyridine, pyrimidine, triazine, fluorene, dibenzothiophene, silafluorene, carbazole, thiophene, furan, thiazole, triphenylamine, triphenylphosphine oxide, tetraphenyl silicane, spirofluorene, spirosilabifluorene and the like.

Furthermore, L shown in general formula (1) is selected from the group consisting of a single bond, benzene, pyridine, pyrimidine, triazine, carbazole, and the like.

Suitable examples that can be used as R₁, R₂ and R₃ include groups such as methyl, benzene, naphthalene, anthracene, phenanthrene, pyrene, pyridine, pyrimidine, triazine, fluorene, dibenzothiophene, silafluorene, carbazole, thiophene, furan, thiazole, triphenylamine, triphenylphosphine oxide, tetraphenyl silicane, spirofluorene, spirosilabifluorene and the like.

Furthermore, R₁, R₂ and R₃ shown in general formula (1) are selected from the group consisting of benzene, pyridine, pyrimidine, triazine, carbazole, and the like.

In one embodiment, the above linking unit L may be selected from one of the following structural units, or substituted groups obtained by substituting the following structural groups,

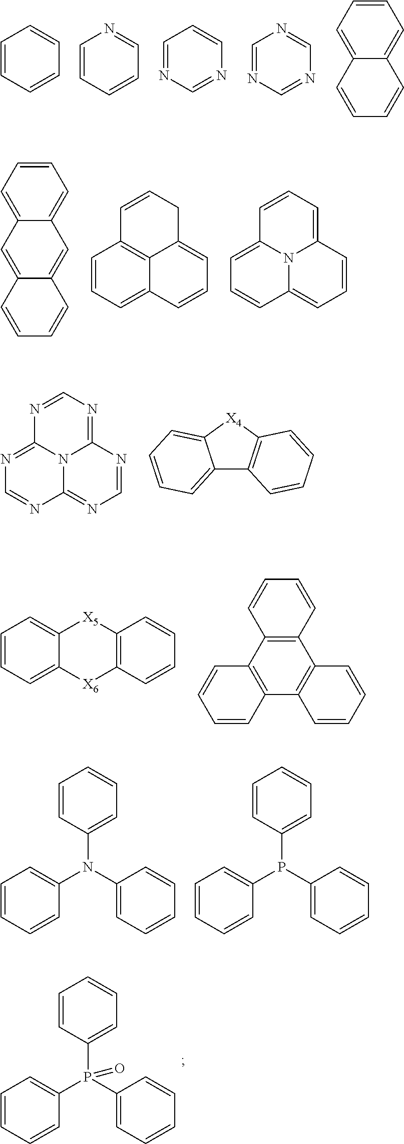

wherein X₄, X₅ and X₆ independently optionally represent N(R), C(R)₂, Si(R)₂, O, C═N(R), C═C(R)₂, P(R), P(═O)R, S, S═O or SO₂, respectively; Specifically, the definition of R in X₄, X₅ and X₆ can be referred to the description of R in general formula (1).

In one embodiment, X₄, X₅ and X₆ may also be absent, i.e. none, which means that there is no atom or no bond linking on the positions indicated by X₄, X₅ and X₆, but at least one of X₅, X₆ and X₃ is not absent.

In one embodiment, Ar shown in general formula (1) is an aromatic ring with a carbon atom number of 6 to 22, or a heteroaromatic ring with a carbon atom number of 3 to 22. Furthermore, Ar is an aromatic ring with a carbon atom number of 6 to 20, or a heteroaromatic ring with a carbon atom number of 3 to 20. Furthermore, Ar is an aromatic ring with a carbon atom number of 6 to 15, or a heteroaromatic ring with a carbon atom number of 3 to 15.

Specifically, Ar may be selected from one of the following structural groups:

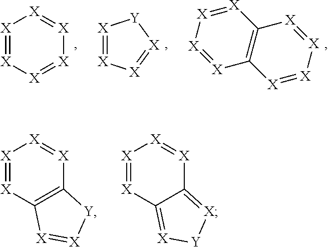

wherein X is CR¹ or N; Y is selected from the group consisting of: CR²R³, SiR²R³, NR², C(═O), S and O. R¹, R², and R³ are H, or deuterium, or linear alkyl containing 1 to 20 carbon atoms, linear alkoxy containing 1 to 20 carbon atoms or linear thioalkoxy groups containing 1 to 20 carbon atoms, or branched or cyclic alkyl containing 3 to 20 carbon atoms, branched or cyclic alkyl alkoxy containing 3 to 20 carbon atoms or branched or cyclic alkyl thioalkoxy groups containing 3 to 20 carbon atoms or branched or cyclic alkyl silyl group containing 3 to 20 carbon atoms, or substituted keto groups containing 1 to 20 carbon atoms, alkoxycarbonyl groups containing 2 to 20 carbon atoms, aryloxycarbonyl groups containing 7 to 20 carbon atoms, cyano group (—CN); carbamoyl group (—C(═O)NH₂), haloformyl group (—C(═O)-A, wherein A represents halogen atom), formyl group (—C(═O)—H), isocyano group; isocyanate group, thiocyanate group, or isothiocyanate group, hydroxyl group, nitro group, CF₃ group, Cl, Br, F, a crosslinkable group, or substituted or unsubstituted aromatic or heteroaromatic ring systems containing 5 to 40 ring atoms, aryloxy or heteroaryloxy groups containing 5 to 40 ring atoms, or combination of these systems, wherein R¹, R², and R³ may form a monocyclic or polycyclic aliphatic or aromatic ring system with each other and/or with a ring bonded thereto.

Furthermore, Ar may be selected from one of the following structural groups, or substituted groups obtained by substituting the following structural groups.

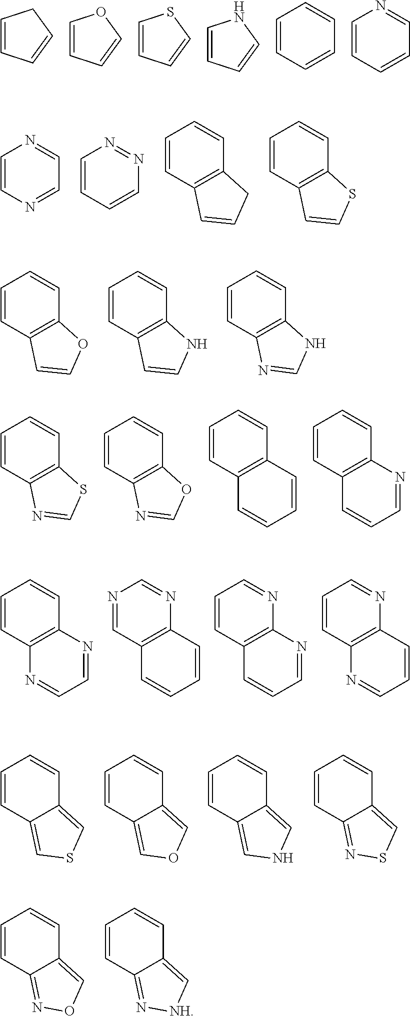

Wherein, the linking position of an Ar group may be on any adjacent carbon atom on the selected group.

Specifically, the D-A type compound according to the present disclosure may be represented by any one of the following chemical formulas (2) to (4):

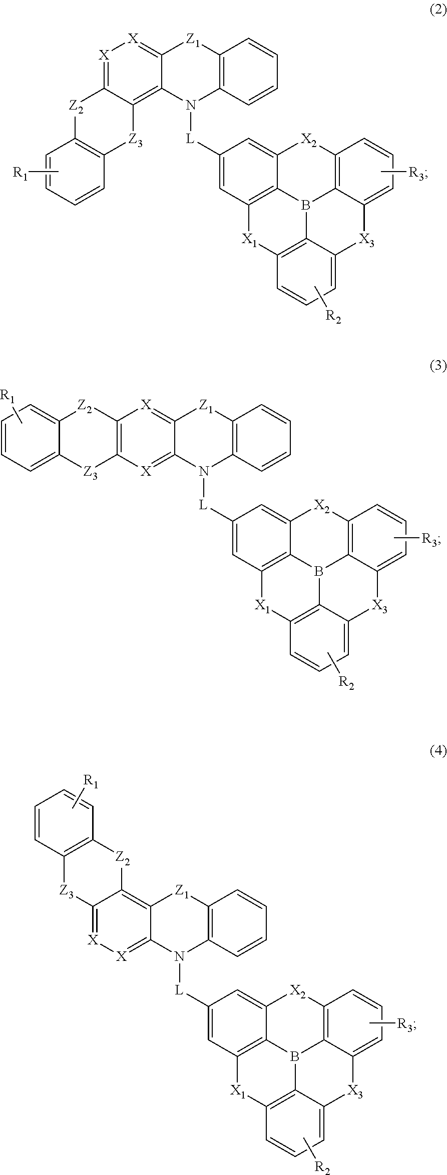

wherein L, Z₁, Z₂, Z₃, X, X₁, X₂, X₃ and R, R₁, R₂, R₃ are as defined above.

In one embodiment, Z₁, Z₂ and Z₃ are selected from the group consisting of a single bond, N(R), C(R)₂, Si(R)₂, O and S.

More specifically, the D-A type compound according to the present disclosure is selected from one of the following structural formulas:

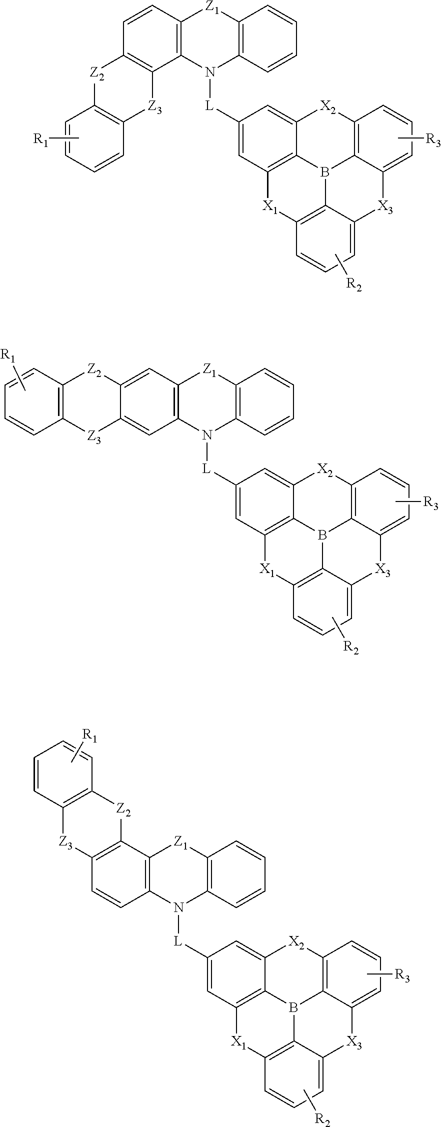

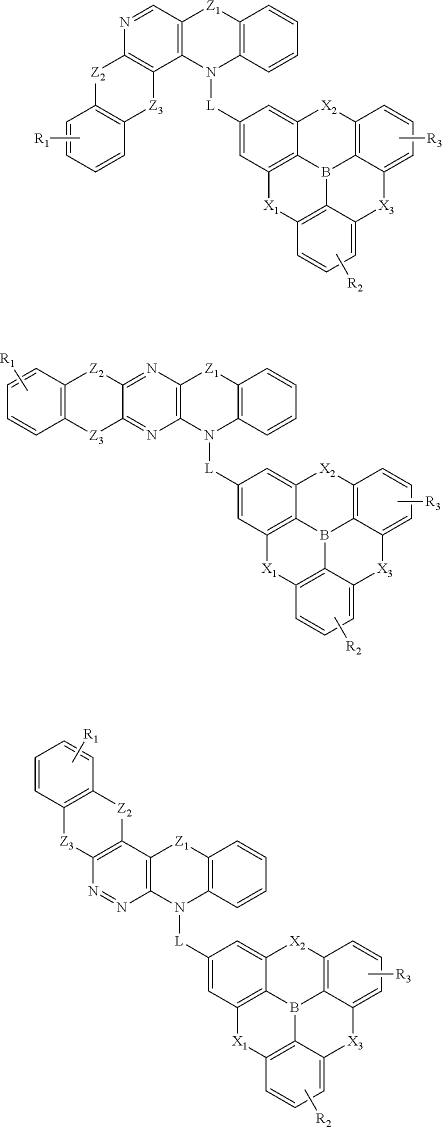

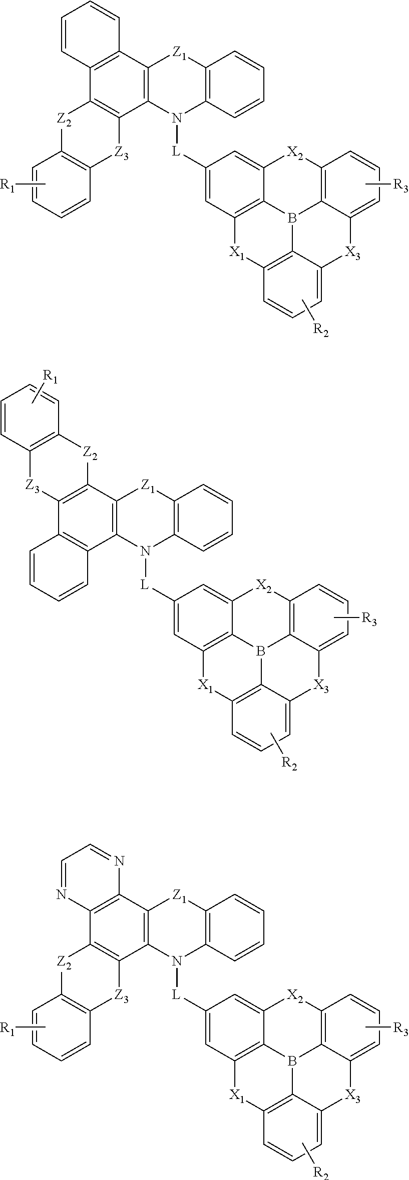

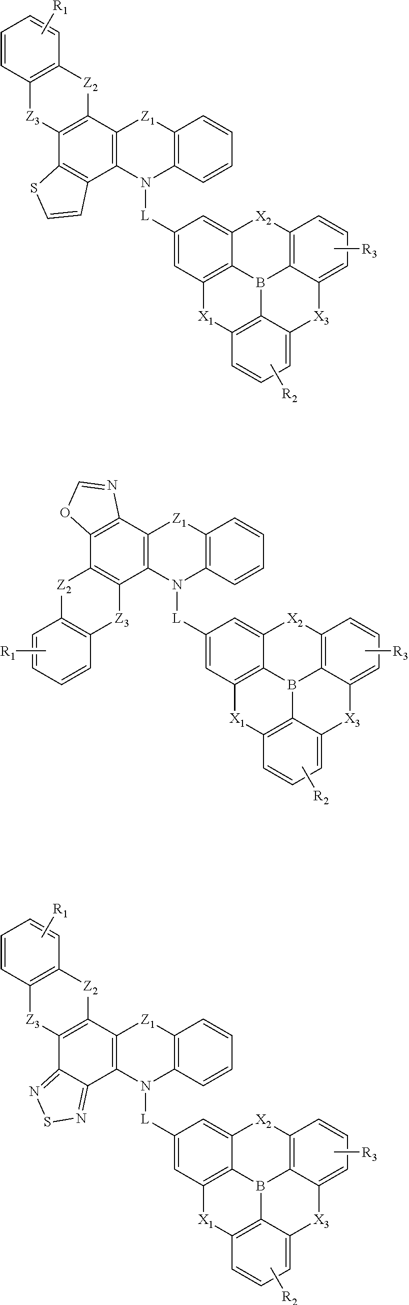

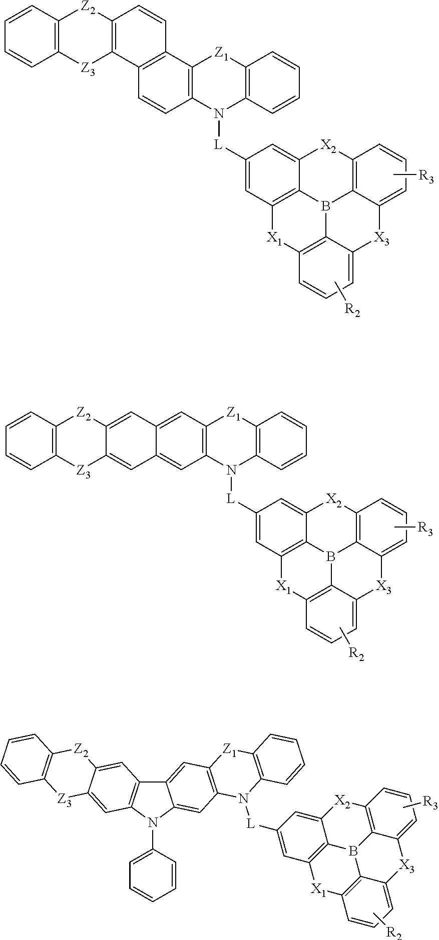

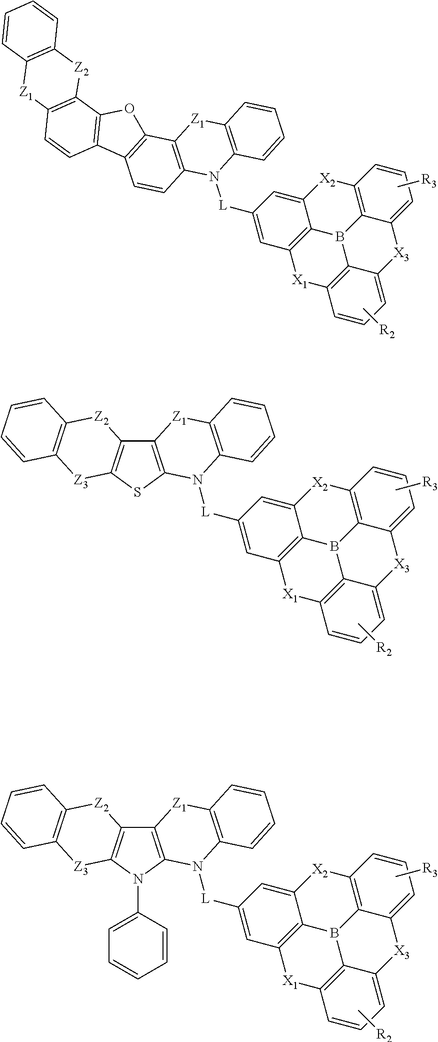

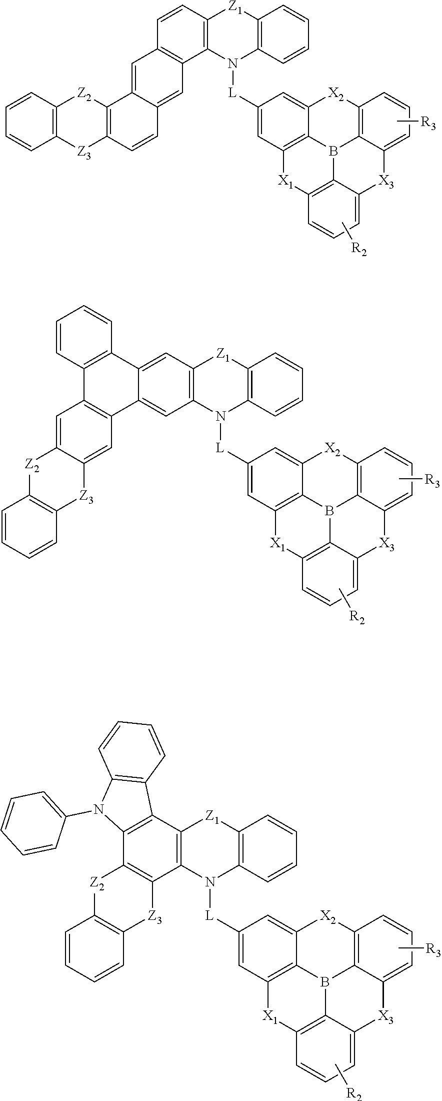

wherein, R₁, R₂, R₃, Z₁, Z₂, Z₃, X₁, X₂, and X₃ are as defined above.

X₁, X₂, and X₃ can be selected in various ways. In one specific embodiment, suitable examples that may be used as X₁, X₂, X₃ are: N(R), C(R)₂, O, S, or absent, but at least one is not absent.

Furthermore, the compound according to the present disclosure is selected from one of the following structural formulas:

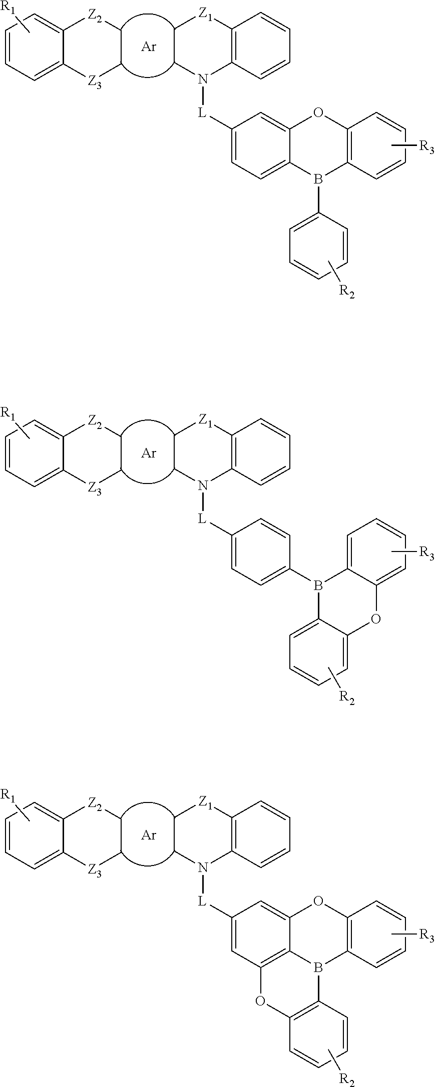

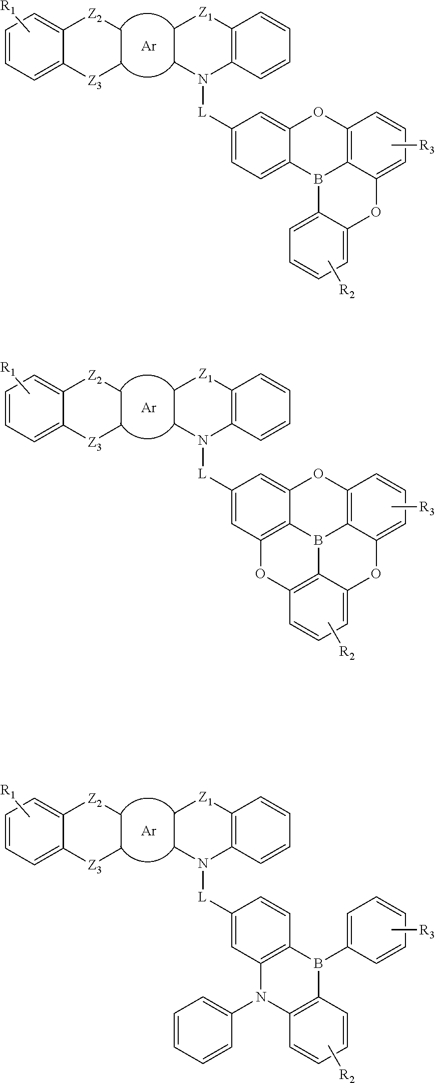

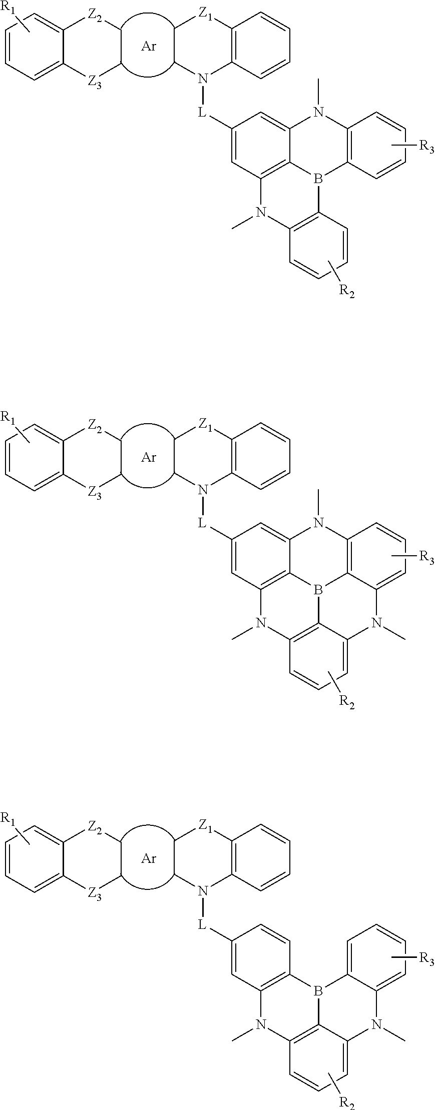

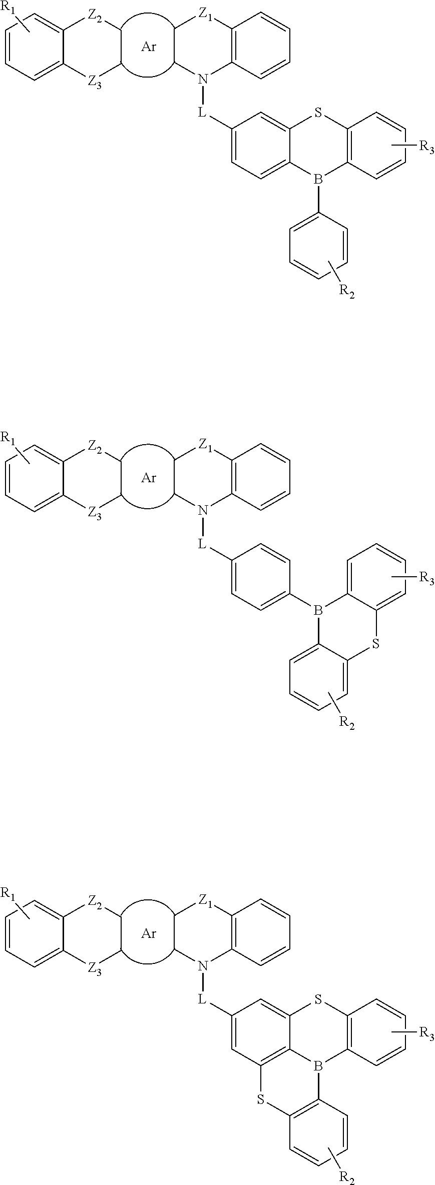

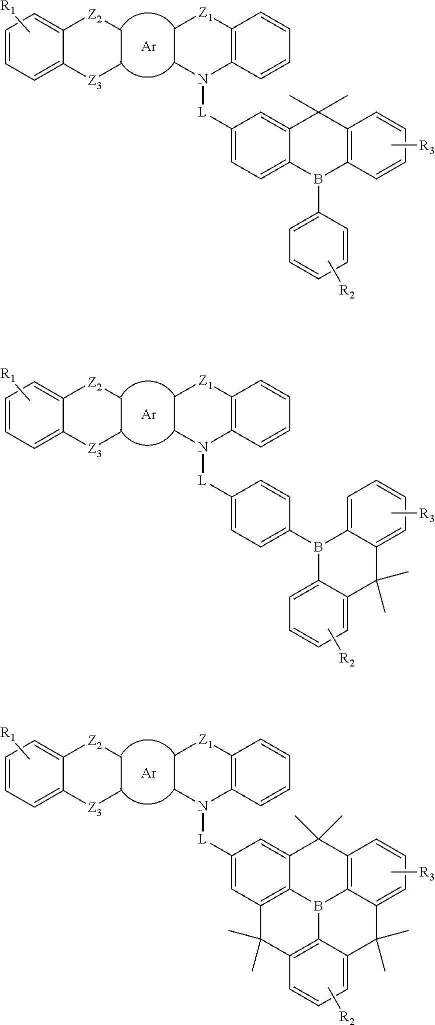

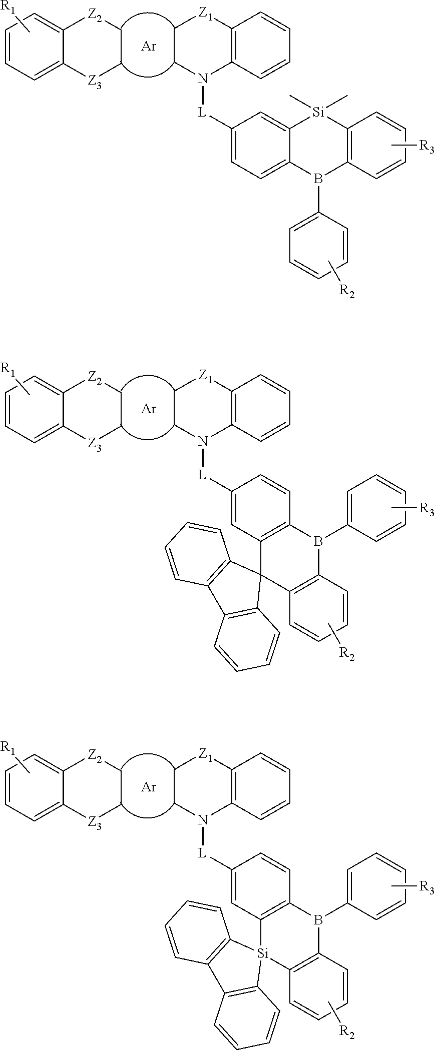

wherein, R₁, R₂, R₃, Z₁, Z₂, Z₃, and Ar are as defined above.

The above D-A type compound can be used as a functional material in electronic devices. Organic functional materials can be classified into a hole injection material (HIM), a hole transport material (HTM), an electron transport material (ETM), an electron injection material (EIM), an electron blocking material (EBM), a hole blocking material (HBM), emitter, host material, or organic dyes. Specifically, the above D-A type compound can be used as a host material, or an electron transport material or a hole transport material. More specifically, the above D-A type compound can be used as a phosphorescent host material.

Generally, phosphorescent host materials must have a proper triplet energy level, i.e., T₁. In certain embodiments, the D-A type compound has T₁≥2.2 eV, T₁≥2.4 eV in other embodiments, T₁≥2.6 eV in other embodiments, T₁≥2.65 eV in other embodiments, T₁≥2.7 eV in other embodiments.

Typically, the triplet energy level T₁ of the organic compound depends on the substructure having the largest conjugated system in the compound. In general, T₁ decreases as the conjugated system increases. Specifically, the substructure in the chemical formula (1) of the D-A type compound has the largest conjugated system as shown in general formula (1a).

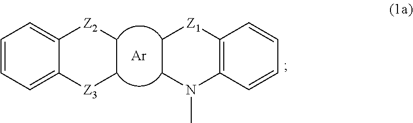

In some embodiments, specifically, the number of ring atoms of the substructure according to general formula (1a), in the case where substituents are removed, is no more than 36, furthermore no more than 30, still furthermore no more than 26, and more specifically, no more than 20.

Specifically, the substructure according to general formula (1a) has T₁≥2.3 eV, T₁≥2.5 eV in other embodiments, T₁≥2.7 eV in other embodiments, T₁≥2.75 eV in other embodiments.

Specifically, the above D-A type compound has a glass transition temperature T_{g}≥100° C., in some embodiments, furthermore, T_{g}≥120° C., in some embodiments, furthermore, T_{g}≥140° C., in some embodiments, furthermore, T_{g}≥160° C., in some embodiments, furthermore, T_{g}≥180° C. It is shown that the above D-A type compound has good thermal stability and can be used as a phosphorescent host material.

Specifically, the above D-A type compound has a difference between the singlet and triplet energy levels Δ(S₁−T₁)≤0.30 eV, in some embodiments, furthermore, Δ(S₁−T₁)≤0.25 eV, in some embodiments, furthermore, Δ(S₁−T₁)≤0.20 eV, in some embodiments, furthermore, Δ(S₁−T₁)≤0.15 eV, in some embodiments, furthermore, Δ(S₁−T₁)≤0.10 eV. It is shown that the above D-A type compound has a smaller difference between the singlet and triplet energy levels Δ(S₁−T₁).

For the synthesis of the above D-A type compound, generally, a fused heterocyclic ring containing N may be first synthesized, then coupled with a group containing L, and then a boron-containing group may be linked, and finally the ring may be closed to obtain the target compound.

Non-limiting examples of the D-A type compound according to the present disclosure are given below.

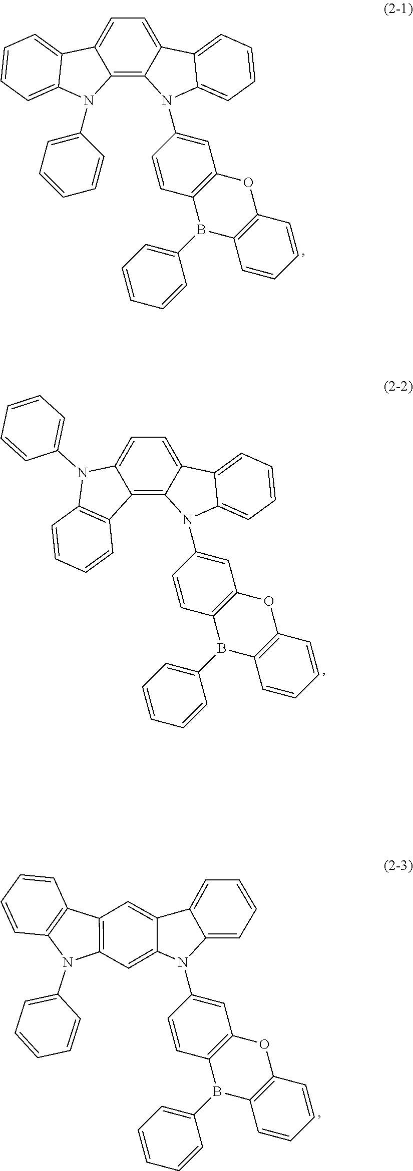 [SMILES: c1ccc(B2c3ccccc3Oc3cc(-n4c5ccccc5c5ccc6c7ccccc7n(-c7ccccc7)c6c54)ccc32)cc1 ; c1ccc(B2c3ccccc3Oc3cc(-n4c5ccccc5c5ccc6c(c7ccccc7n6-c6ccccc6)c54)ccc32)cc1 ; c1ccc(B2c3ccccc3Oc3cc(-n4c5ccccc5c5cc6c7ccccc7n(-c7ccccc7)c6cc54)ccc32)cc1]

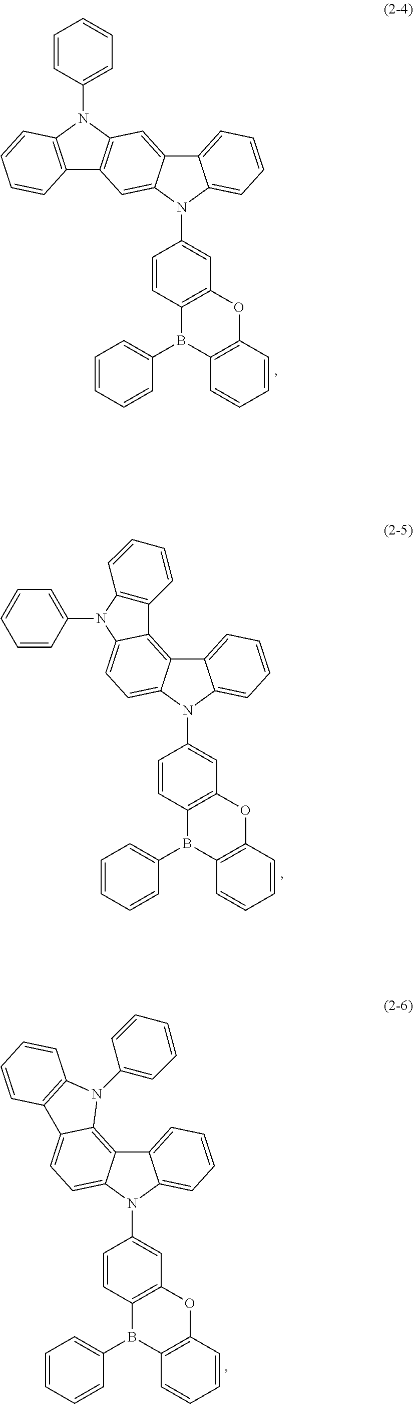 [SMILES: c1ccc(B2c3ccccc3Oc3cc(-n4c5ccccc5c5cc6c(cc54)c4ccccc4n6-c4ccccc4)ccc32)cc1 ; c1ccc(B2c3ccccc3Oc3cc(-n4c5ccccc5c5c6c7ccccc7n(-c7ccccc7)c6ccc54)ccc32)cc1 ; c1ccc(B2c3ccccc3Oc3cc(-n4c5ccccc5c5c4ccc4c6ccccc6n(-c6ccccc6)c45)ccc32)cc1]

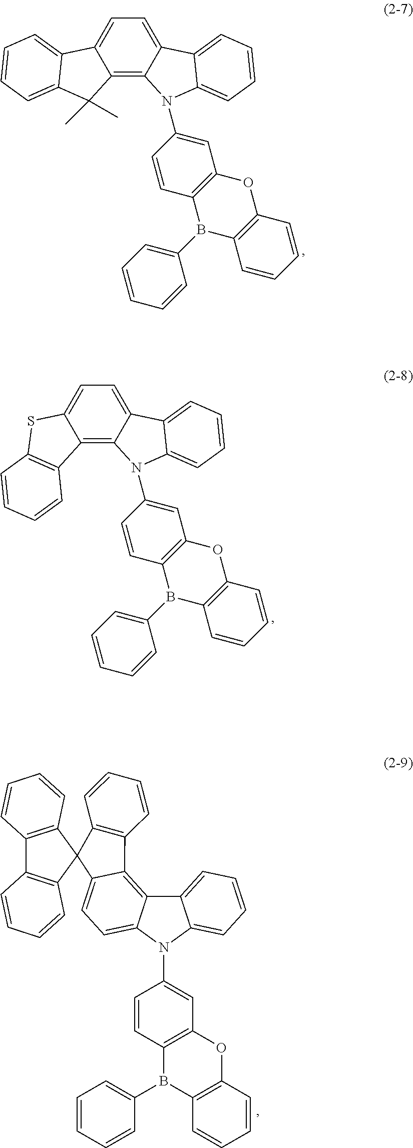 [SMILES: CC1(C)c2ccccc2-c2ccc3c4ccccc4n(-c4ccc5c(c4)Oc4ccccc4B5c4ccccc4)c3c21 ; c1ccc(B2c3ccccc3Oc3cc(-n4c5ccccc5c5ccc6sc7ccccc7c6c54)ccc32)cc1 ; c1ccc(B2c3ccccc3Oc3cc(-n4c5ccccc5c5c6c(ccc54)C4(c5ccccc5-c5ccccc54)c4ccccc4-6)ccc32)cc1]

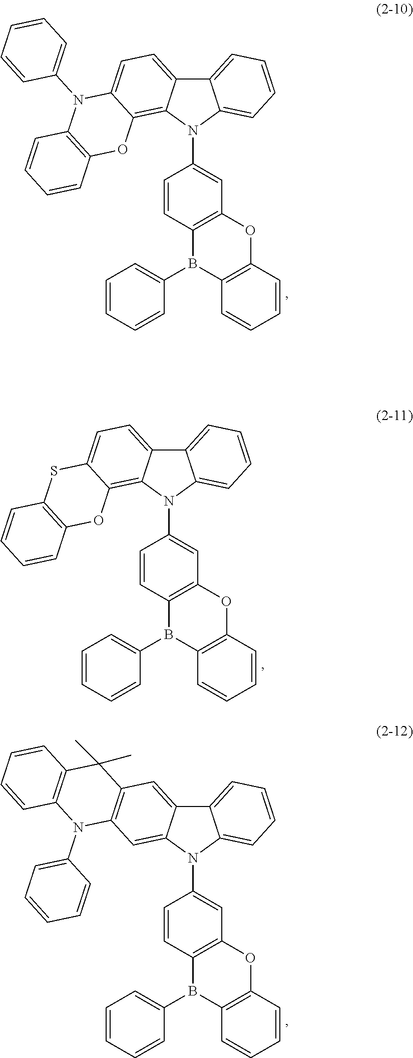 [SMILES: c1ccc(B2c3ccccc3Oc3cc(-n4c5ccccc5c5ccc6c(c54)Oc4ccccc4N6c4ccccc4)ccc32)cc1 ; c1ccc(B2c3ccccc3Oc3cc(-n4c5ccccc5c5ccc6c(c54)Oc4ccccc4S6)ccc32)cc1 ; CC1(C)c2ccccc2N(c2ccccc2)c2cc3c(cc21)c1ccccc1n3-c1ccc2c(c1)Oc1ccccc1B2c1ccccc1]

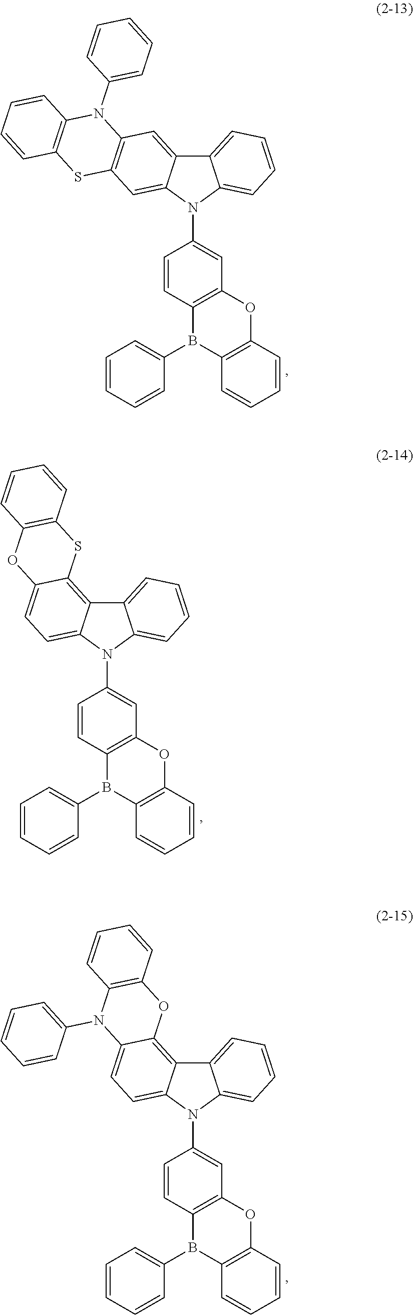 [SMILES: c1ccc(B2c3ccccc3Oc3cc(-n4c5ccccc5c5cc6c(cc54)Sc4ccccc4N6c4ccccc4)ccc32)cc1 ; c1ccc(B2c3ccccc3Oc3cc(-n4c5ccccc5c5c6c(ccc54)Oc4ccccc4S6)ccc32)cc1 ; c1ccc(B2c3ccccc3Oc3cc(-n4c5ccccc5c5c6c(ccc54)N(c4ccccc4)c4ccccc4O6)ccc32)cc1]

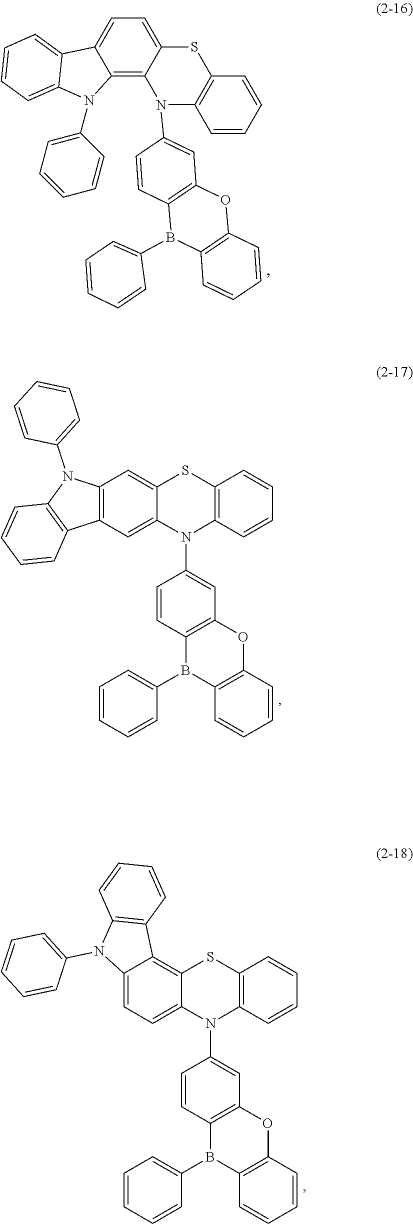 [SMILES: c1ccc(B2c3ccccc3Oc3cc(N4c5ccccc5Sc5ccc6c7ccccc7n(-c7ccccc7)c6c54)ccc32)cc1 ; c1ccc(B2c3ccccc3Oc3cc(N4c5ccccc5Sc5cc6c(cc54)c4ccccc4n6-c4ccccc4)ccc32)cc1 ; c1ccc(B2c3ccccc3Oc3cc(N4c5ccccc5Sc5c4ccc4c5c5ccccc5n4-c4ccccc4)ccc32)cc1]

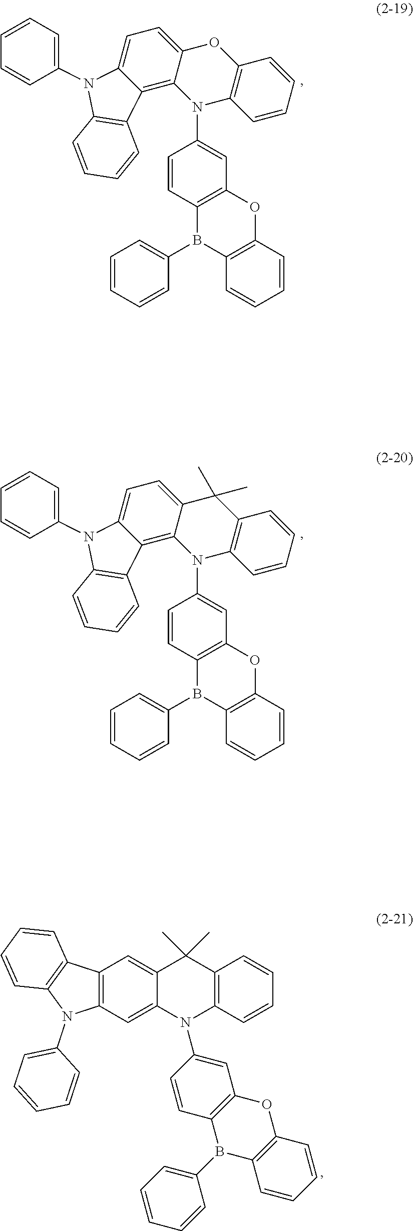 [SMILES: c1ccc(B2c3ccccc3Oc3cc(N4c5ccccc5Oc5ccc6c(c54)c4ccccc4n6-c4ccccc4)ccc32)cc1 ; CC1(C)c2ccccc2N(c2ccc3c(c2)Oc2ccccc2B3c2ccccc2)c2c1ccc1c2c2ccccc2n1-c1ccccc1 ; CC1(C)c2ccccc2N(c2ccc3c(c2)Oc2ccccc2B3c2ccccc2)c2cc3c(cc21)c1ccccc1n3-c1ccccc1]

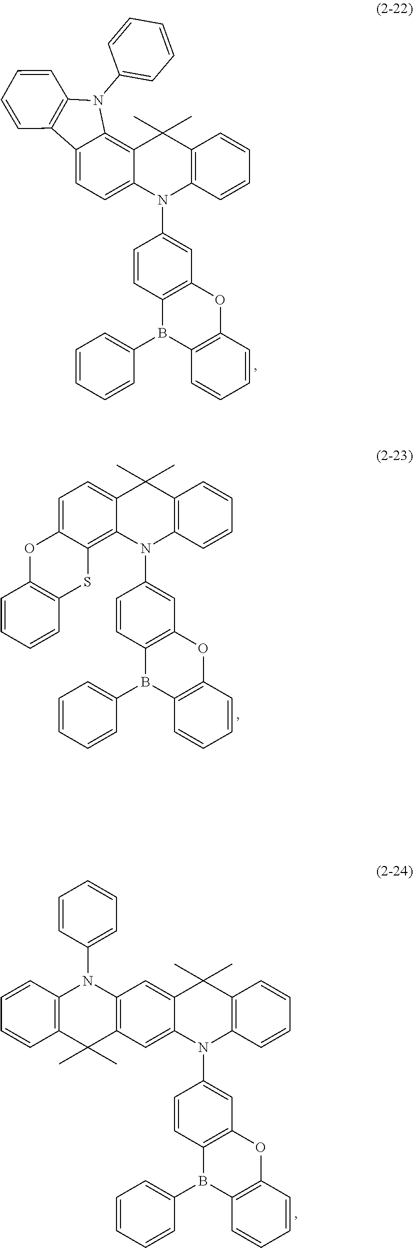 [SMILES: CC1(C)c2ccccc2N(c2ccc3c(c2)Oc2ccccc2B3c2ccccc2)c2ccc3c4ccccc4n(-c4ccccc4)c3c21 ; CC1(C)c2ccccc2N(c2ccc3c(c2)Oc2ccccc2B3c2ccccc2)c2c1ccc1c2Sc2ccccc2O1 ; CC1(C)c2ccccc2N(c2ccccc2)c2cc3c(cc21)N(c1ccc2c(c1)Oc1ccccc1B2c1ccccc1)c1ccccc1C3(C)C]

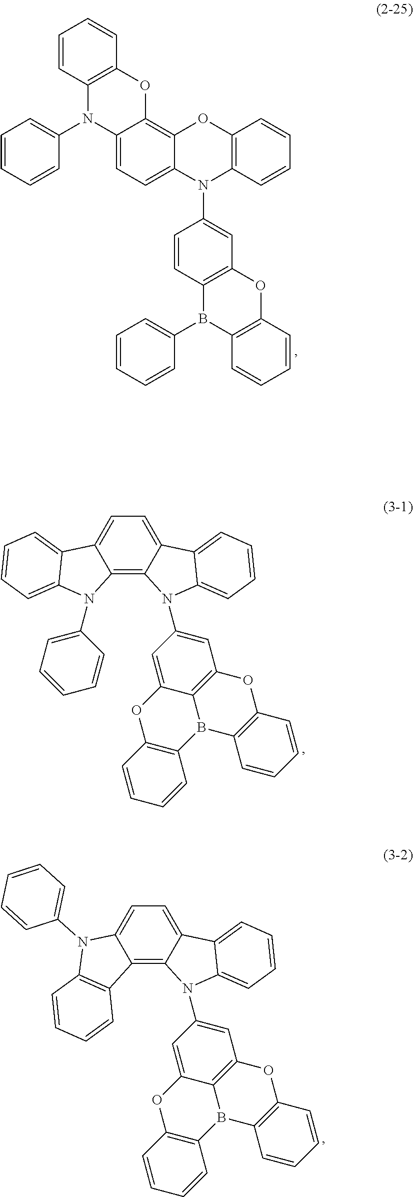 [SMILES: c1ccc(B2c3ccccc3Oc3cc(-n4c5ccccc5oc5c6oc7ccccc7n(-c7ccccc7)c6ccc54)ccc32)cc1 ; c1ccc(-n2c3ccccc3c3ccc4c5ccccc5n(-c5cc6c7c(c5)Oc5ccccc5B7c5ccccc5O6)c4c32)cc1 ; c1ccc(-n2c3ccccc3c3c2ccc2c4ccccc4n(-c4cc5c6c(c4)Oc4ccccc4B6c4ccccc4O5)c23)cc1]

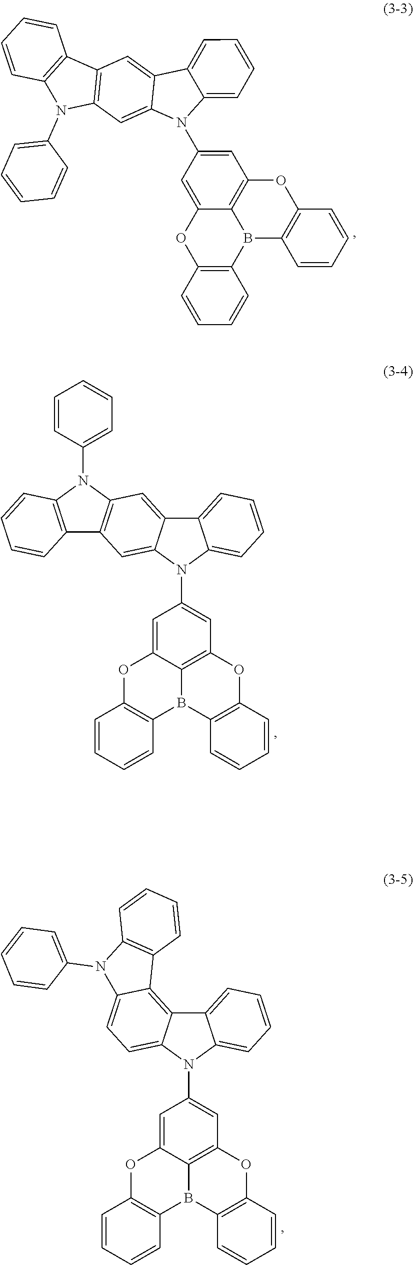 [SMILES: c1ccc(-n2c3ccccc3c3cc4c5ccccc5n(-c5cc6c7c(c5)Oc5ccccc5B7c5ccccc5O6)c4cc32)cc1 ; c1ccc(-n2c3ccccc3c3cc4c(cc32)c2ccccc2n4-c2cc3c4c(c2)Oc2ccccc2B4c2ccccc2O3)cc1 ; c1ccc(-n2c3ccccc3c3c4c5ccccc5n(-c5cc6c7c(c5)Oc5ccccc5B7c5ccccc5O6)c4ccc32)cc1]

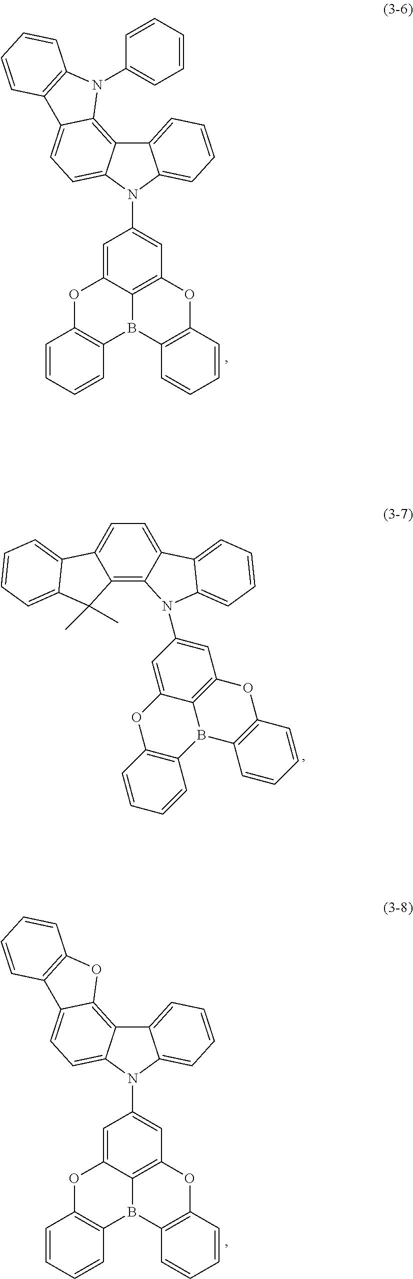 [SMILES: c1ccc(-n2c3ccccc3c3ccc4c(c5ccccc5n4-c4cc5c6c(c4)Oc4ccccc4B6c4ccccc4O5)c32)cc1 ; CC1(C)c2ccccc2-c2ccc3c4ccccc4n(-c4cc5c6c(c4)Oc4ccccc4B6c4ccccc4O5)c3c21 ; c1ccc2c(c1)Oc1cc(-n3c4ccccc4c4c5oc6ccccc6c5ccc43)cc3c1B2c1ccccc1O3]

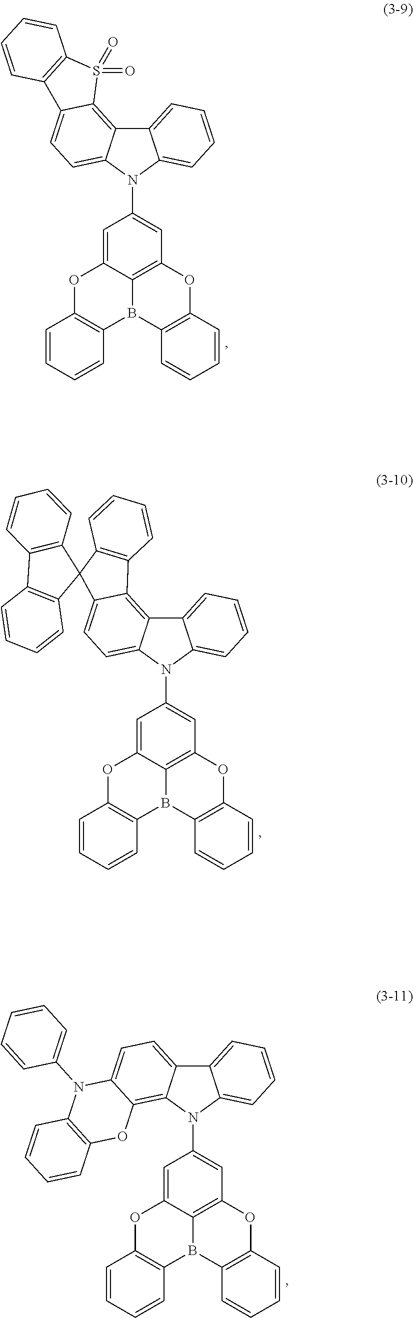 [SMILES: O=S1(=O)c2ccccc2-c2ccc3c(c21)c1ccccc1n3-c1cc2c3c(c1)Oc1ccccc1B3c1ccccc1O2 ; c1ccc2c(c1)Oc1cc(-n3c4ccccc4c4c5c(ccc43)C3(c4ccccc4-c4ccccc43)c3ccccc3-5)cc3c1B2c1ccccc1O3 ; c1ccc(N2c3ccccc3Oc3c2ccc2c4ccccc4n(-c4cc5c6c(c4)Oc4ccccc4B6c4ccccc4O5)c32)cc1]

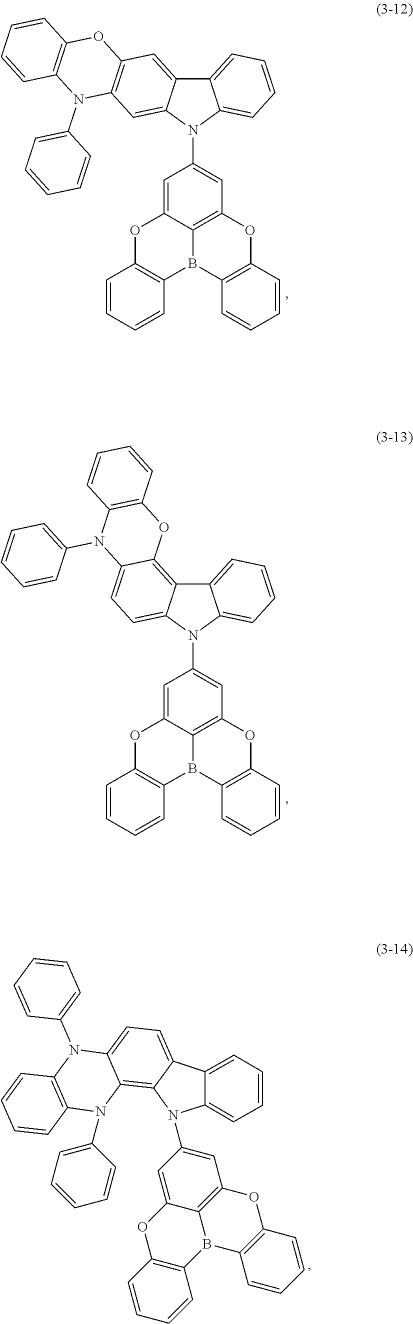 [SMILES: c1ccc(N2c3ccccc3Oc3cc4c5ccccc5n(-c5cc6c7c(c5)Oc5ccccc5B7c5ccccc5O6)c4cc32)cc1 ; c1ccc(N2c3ccccc3Oc3c2ccc2c3c3ccccc3n2-c2cc3c4c(c2)Oc2ccccc2B4c2ccccc2O3)cc1 ; c1ccc(N2c3ccccc3N(c3ccccc3)c3c2ccc2c4ccccc4n(-c4cc5c6c(c4)Oc4ccccc4B6c4ccccc4O5)c32)cc1]

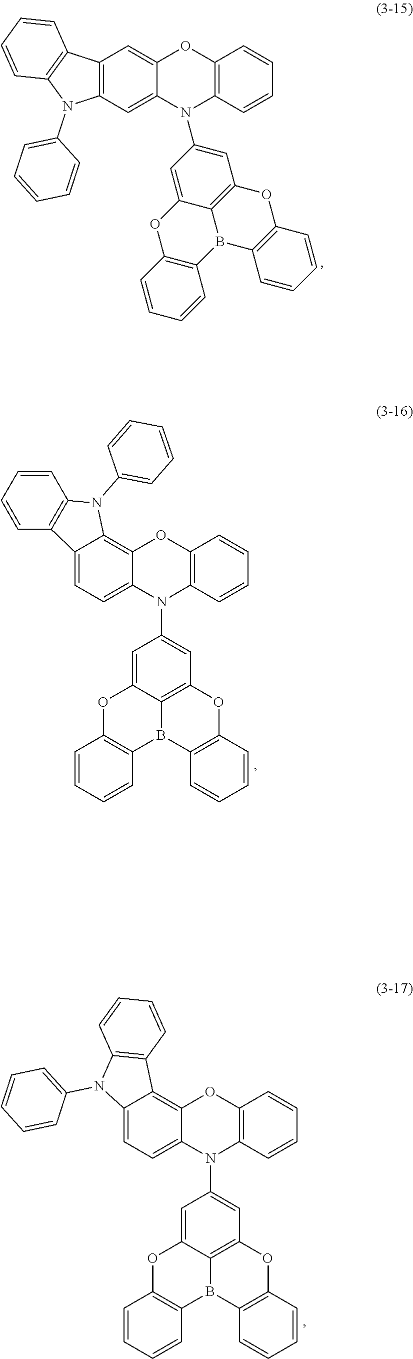 [SMILES: c1ccc(-n2c3ccccc3c3cc4c(cc32)N(c2cc3c5c(c2)Oc2ccccc2B5c2ccccc2O3)c2ccccc2O4)cc1 ; c1ccc(-n2c3ccccc3c3ccc4c(c32)Oc2ccccc2N4c2cc3c4c(c2)Oc2ccccc2B4c2ccccc2O3)cc1 ; c1ccc(-n2c3ccccc3c3c4c(ccc32)N(c2cc3c5c(c2)Oc2ccccc2B5c2ccccc2O3)c2ccccc2O4)cc1]

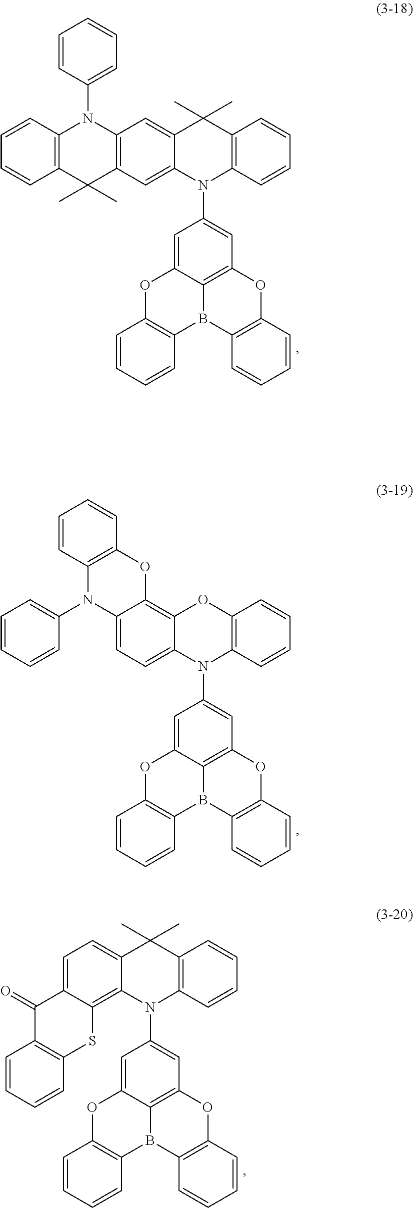 [SMILES: CC1(C)c2ccccc2N(c2ccccc2)c2cc3c(cc21)N(c1cc2c4c(c1)Oc1ccccc1B4c1ccccc1O2)c1ccccc1C3(C)C ; c1ccc(-n2c3ccccc3oc3c4oc5ccccc5n(-c5cc6c7c(c5)Oc5ccccc5B7c5ccccc5O6)c4ccc32)cc1 ; CC1(C)c2ccccc2N(c2cc3c4c(c2)Oc2ccccc2B4c2ccccc2O3)c2c1ccc1c(=O)c3ccccc3sc21]

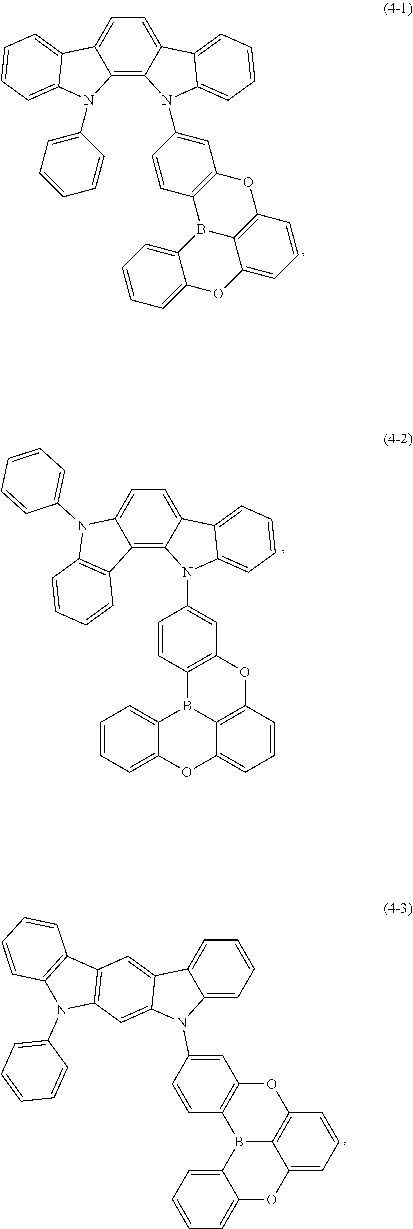 [SMILES: c1ccc(-n2c3ccccc3c3ccc4c5ccccc5n(-c5ccc6c(c5)Oc5cccc7c5B6c5ccccc5O7)c4c32)cc1 ; c1ccc(-n2c3ccccc3c3c2ccc2c4ccccc4n(-c4ccc5c(c4)Oc4cccc6c4B5c4ccccc4O6)c23)cc1 ; c1ccc(-n2c3ccccc3c3cc4c5ccccc5n(-c5ccc6c(c5)Oc5cccc7c5B6c5ccccc5O7)c4cc32)cc1]

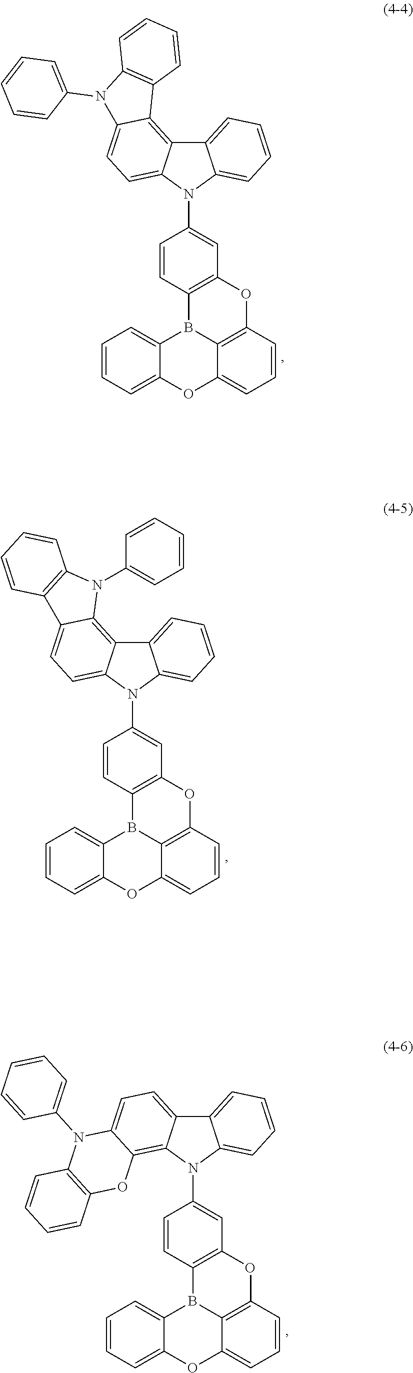 [SMILES: c1ccc(-n2c3ccccc3c3c4c5ccccc5n(-c5ccc6c(c5)Oc5cccc7c5B6c5ccccc5O7)c4ccc32)cc1 ; c1ccc(-n2c3ccccc3c3ccc4c(c5ccccc5n4-c4ccc5c(c4)Oc4cccc6c4B5c4ccccc4O6)c32)cc1 ; c1ccc(N2c3ccccc3Oc3c2ccc2c4ccccc4n(-c4ccc5c(c4)Oc4cccc6c4B5c4ccccc4O6)c32)cc1]

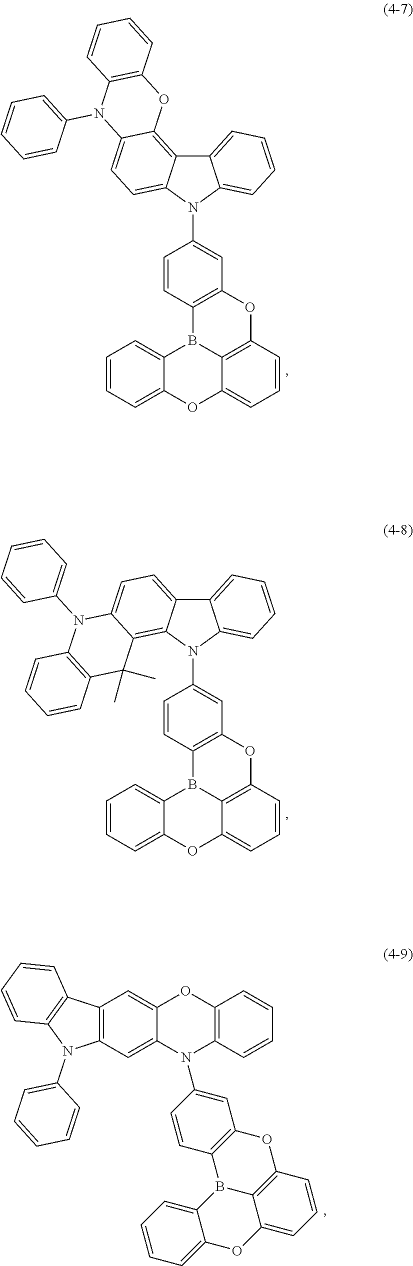 [SMILES: c1ccc(N2c3ccccc3Oc3c2ccc2c3c3ccccc3n2-c2ccc3c(c2)Oc2cccc4c2B3c2ccccc2O4)cc1 ; CC1(C)c2ccccc2N(c2ccccc2)c2ccc3c4ccccc4n(-c4ccc5c(c4)Oc4cccc6c4B5c4ccccc4O6)c3c21 ; c1ccc(-n2c3ccccc3c3cc4c(cc32)N(c2ccc3c(c2)Oc2cccc5c2B3c2ccccc2O5)c2ccccc2O4)cc1]

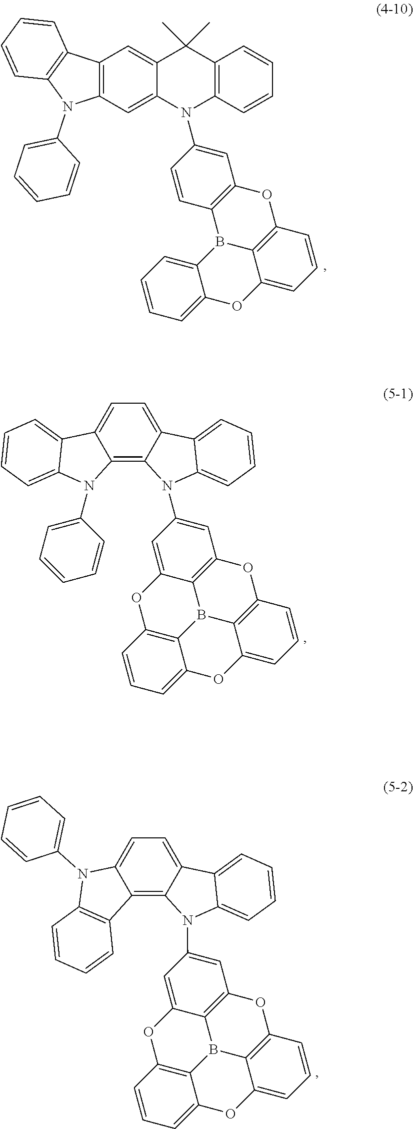 [SMILES: CC1(C)c2ccccc2N(c2ccc3c(c2)Oc2cccc4c2B3c2ccccc2O4)c2cc3c(cc21)c1ccccc1n3-c1ccccc1 ; c1ccc(-n2c3ccccc3c3ccc4c5ccccc5n(-c5cc6c7c(c5)Oc5cccc8c5B7c5c(cccc5O6)O8)c4c32)cc1 ; c1ccc(-n2c3ccccc3c3c2ccc2c4ccccc4n(-c4cc5c6c(c4)Oc4cccc7c4B6c4c(cccc4O5)O7)c23)cc1]

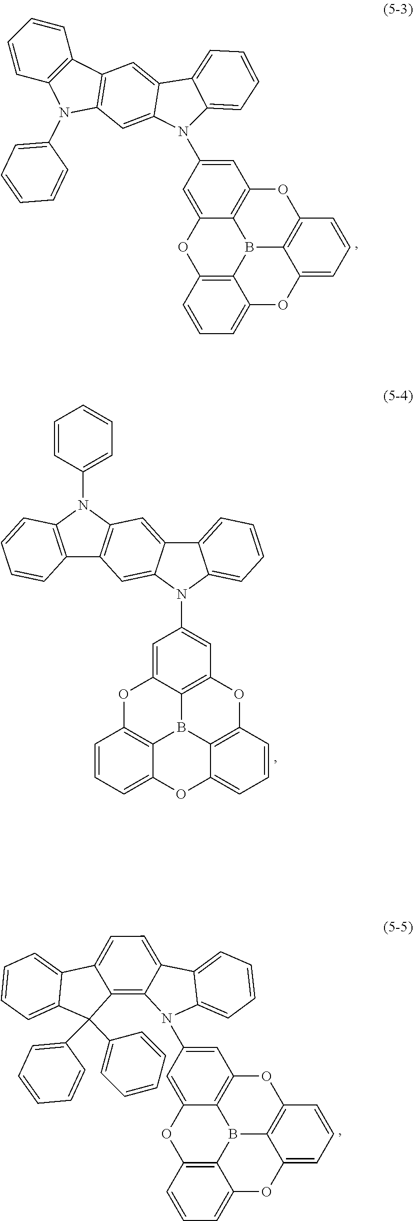 [SMILES: c1ccc(-n2c3ccccc3c3cc4c5ccccc5n(-c5cc6c7c(c5)Oc5cccc8c5B7c5c(cccc5O6)O8)c4cc32)cc1 ; c1ccc(-n2c3ccccc3c3cc4c(cc32)c2ccccc2n4-c2cc3c4c(c2)Oc2cccc5c2B4c2c(cccc2O3)O5)cc1 ; c1ccc(C2(c3ccccc3)c3ccccc3-c3ccc4c5ccccc5n(-c5cc6c7c(c5)Oc5cccc8c5B7c5c(cccc5O6)O8)c4c32)cc1]

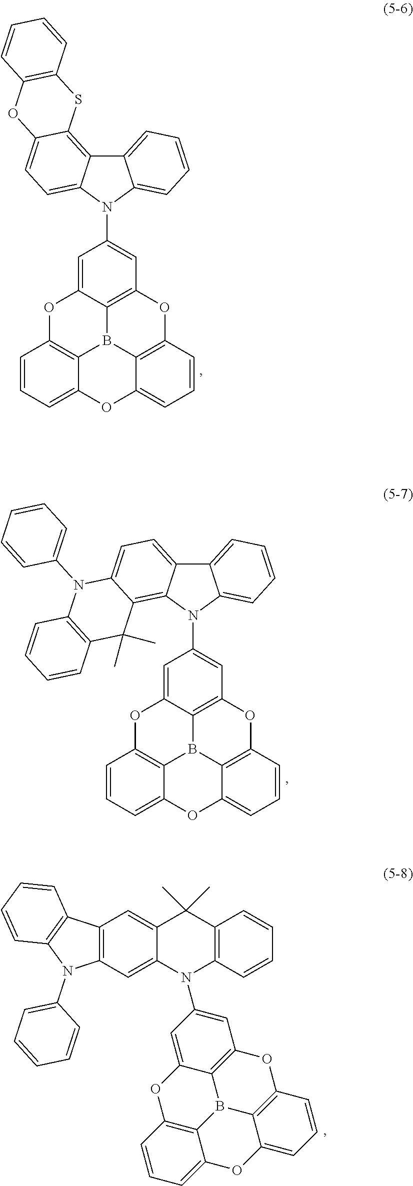 [SMILES: c1ccc2c(c1)Oc1ccc3c(c1S2)c1ccccc1n3-c1cc2c3c(c1)Oc1cccc4c1B3c1c(cccc1O2)O4 ; CC1(C)c2ccccc2N(c2ccccc2)c2ccc3c4ccccc4n(-c4cc5c6c(c4)Oc4cccc7c4B6c4c(cccc4O5)O7)c3c21 ; CC1(C)c2ccccc2N(c2cc3c4c(c2)Oc2cccc5c2B4c2c(cccc2O3)O5)c2cc3c(cc21)c1ccccc1n3-c1ccccc1]

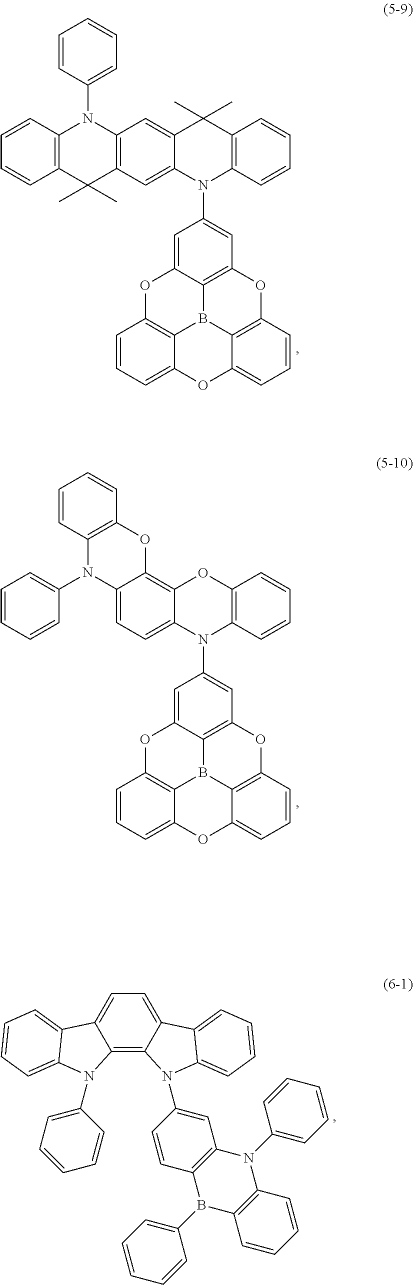 [SMILES: CC1(C)c2ccccc2N(c2ccccc2)c2cc3c(cc21)N(c1cc2c4c(c1)Oc1cccc5c1B4c1c(cccc1O2)O5)c1ccccc1C3(C)C ; c1ccc(-n2c3ccccc3oc3c4oc5ccccc5n(-c5cc6c7c(c5)Oc5cccc8c5B7c5c(cccc5O6)O8)c4ccc32)cc1 ; c1ccc(B2c3ccccc3N(c3ccccc3)c3cc(-n4c5ccccc5c5ccc6c7ccccc7n(-c7ccccc7)c6c54)ccc32)cc1]

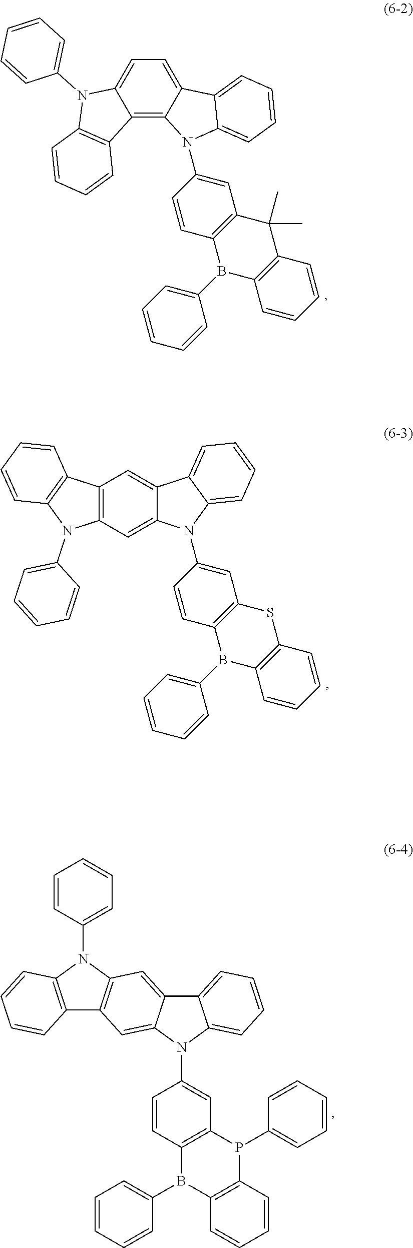 [SMILES: CC1(C)c2ccccc2B(c2ccccc2)c2ccc(-n3c4ccccc4c4ccc5c(c6ccccc6n5-c5ccccc5)c43)cc21 ; c1ccc(B2c3ccccc3Sc3cc(-n4c5ccccc5c5cc6c7ccccc7n(-c7ccccc7)c6cc54)ccc32)cc1 ; c1ccc(B2c3ccccc3P(c3ccccc3)c3cc(-n4c5ccccc5c5cc6c(cc54)c4ccccc4n6-c4ccccc4)ccc32)cc1]

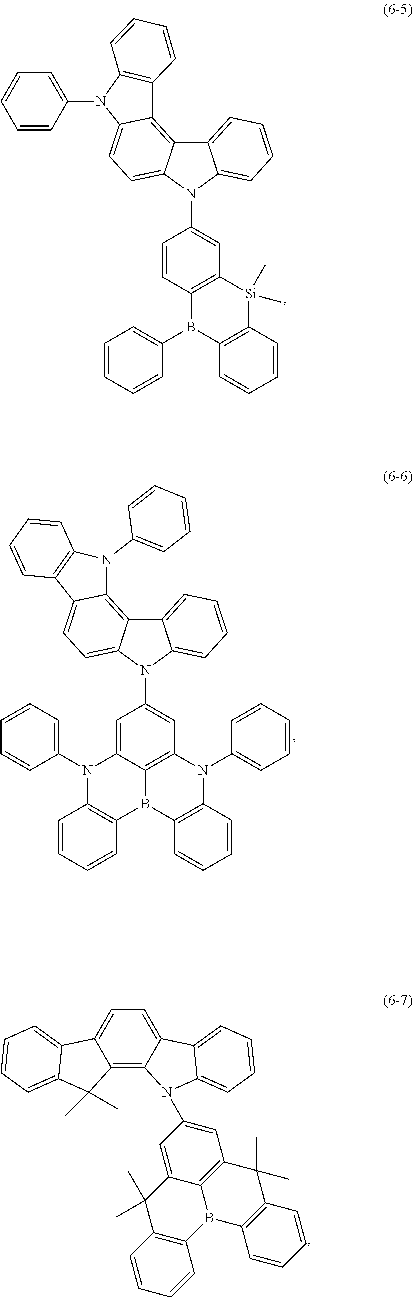 [SMILES: C[Si]1(C)c2ccccc2B(c2ccccc2)c2ccc(-n3c4ccccc4c4c5c6ccccc6n(-c6ccccc6)c5ccc43)cc21 ; c1ccc(N2c3ccccc3B3c4ccccc4N(c4ccccc4)c4cc(-n5c6ccccc6c6c5ccc5c7ccccc7n(-c7ccccc7)c56)cc2c43)cc1 ; CC1(C)c2ccccc2B2c3ccccc3C(C)(C)c3cc(-n4c5ccccc5c5ccc6c(c54)C(C)(C)c4ccccc4-6)cc1c32]

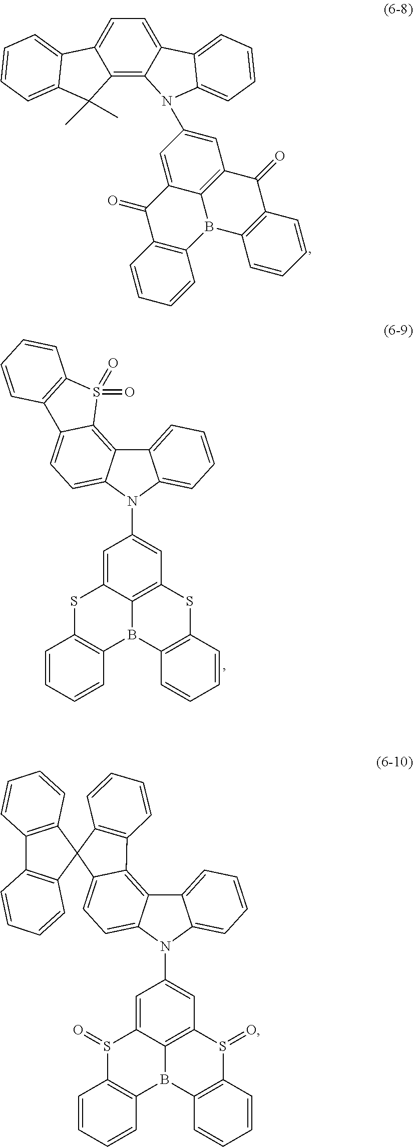 [SMILES: CC1(C)c2ccccc2-c2ccc3c4ccccc4n(-c4cc5c6c(c4)C(=O)c4ccccc4B6c4ccccc4C5=O)c3c21 ; O=S1(=O)c2ccccc2-c2ccc3c(c21)c1ccccc1n3-c1cc2c3c(c1)Sc1ccccc1B3c1ccccc1S2 ; O=S1c2ccccc2B2c3ccccc3S(=O)c3cc(-n4c5ccccc5c5c6c(ccc54)C4(c5ccccc5-c5ccccc54)c4ccccc4-6)cc1c32]

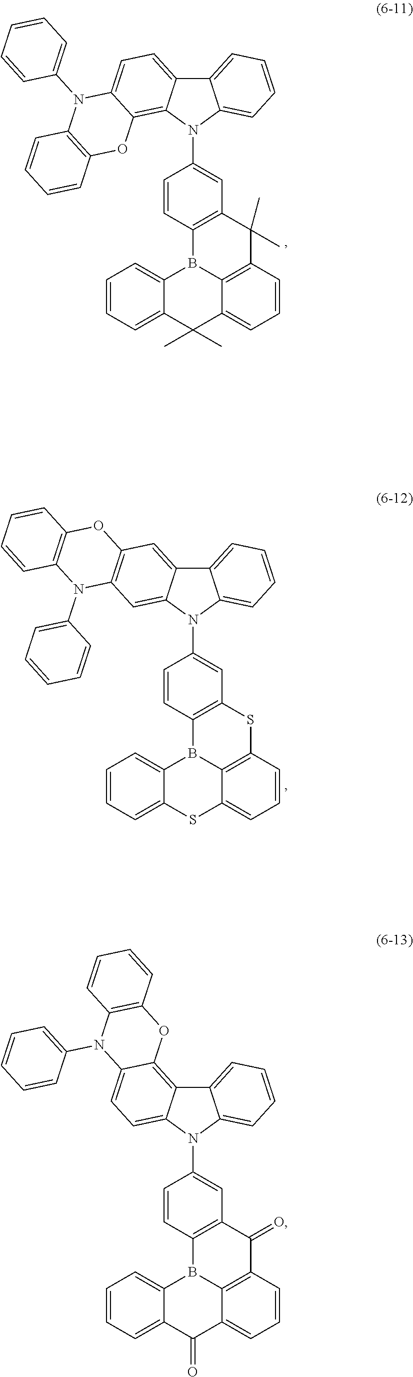 [SMILES: CC1(C)c2ccccc2B2c3ccc(-n4c5ccccc5c5ccc6c(c54)Oc4ccccc4N6c4ccccc4)cc3C(C)(C)c3cccc1c32 ; c1ccc(N2c3ccccc3Oc3cc4c5ccccc5n(-c5ccc6c(c5)Sc5cccc7c5B6c5ccccc5S7)c4cc32)cc1 ; O=C1c2ccccc2B2c3ccc(-n4c5ccccc5c5c6c(ccc54)N(c4ccccc4)c4ccccc4O6)cc3C(=O)c3cccc1c32]

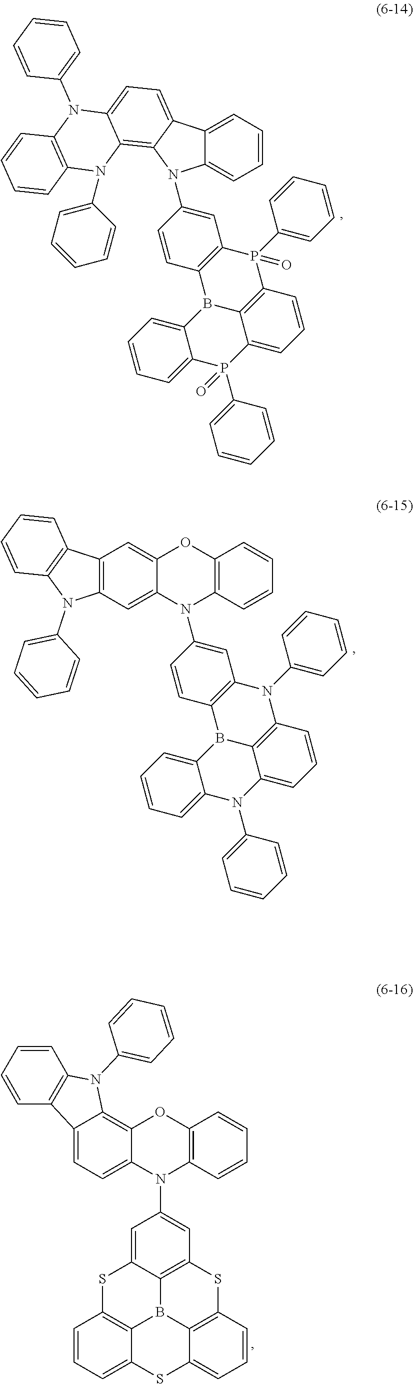 [SMILES: O=P1(c2ccccc2)c2ccccc2B2c3ccc(-n4c5ccccc5c5ccc6c(c54)N(c4ccccc4)c4ccccc4N6c4ccccc4)cc3P(=O)(c3ccccc3)c3cccc1c32 ; c1ccc(N2c3ccccc3B3c4ccc(N5c6ccccc6Oc6cc7c8ccccc8n(-c8ccccc8)c7cc65)cc4N(c4ccccc4)c4cccc2c43)cc1 ; c1ccc(-n2c3ccccc3c3ccc4c(c32)Oc2ccccc2N4c2cc3c4c(c2)Sc2cccc5c2B4c2c(cccc2S3)S5)cc1]

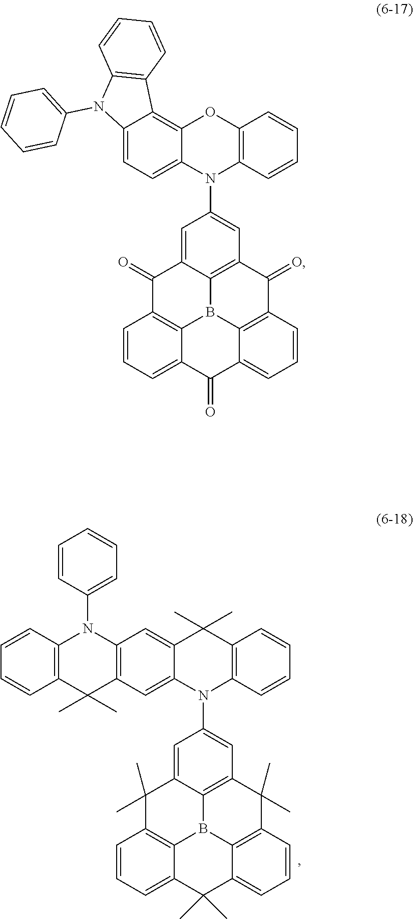 [SMILES: O=C1c2cccc3c2B2c4c1cccc4C(=O)c1cc(N4c5ccccc5Oc5c4ccc4c5c5ccccc5n4-c4ccccc4)cc(c12)C3=O ; CC1(C)c2ccccc2N(c2ccccc2)c2cc3c(cc21)N(c1cc2c4c(c1)C(C)(C)c1cccc5c1B4c1c(cccc1C2(C)C)C5(C)C)c1ccccc1C3(C)C]

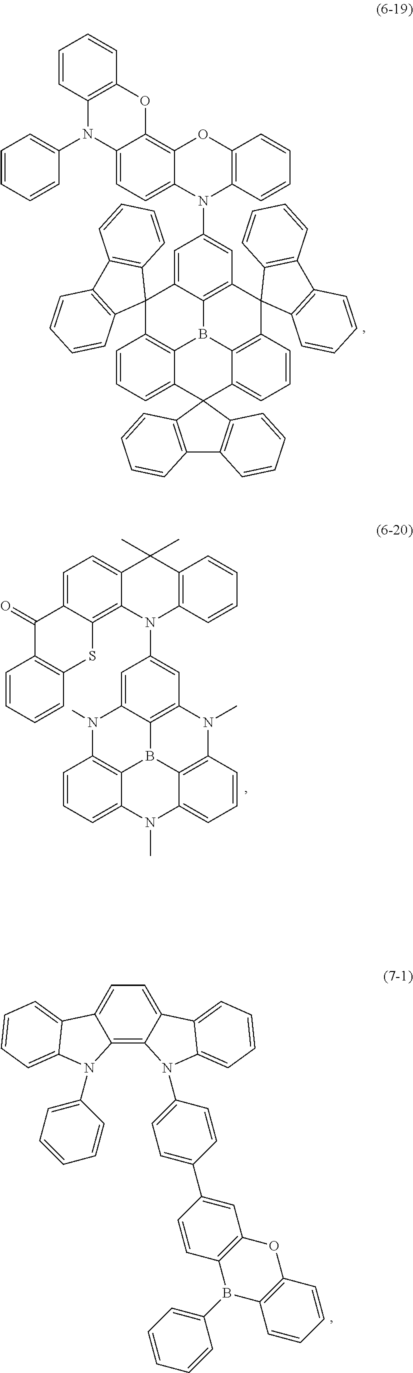 [SMILES: c1ccc(-n2c3ccccc3oc3c4oc5ccccc5n(-c5cc6c7c(c5)C5(c8ccccc8-c8ccccc85)c5cccc8c5B7c5c(cccc5C65c6ccccc6-c6ccccc65)C85c6ccccc6-c6ccccc65)c4ccc32)cc1 ; CN1c2cccc3c2B2c4c1cccc4N(C)c1cc(N4c5ccccc5C(C)(C)c5ccc6c(=O)c7ccccc7sc6c54)cc(c12)N3C ; c1ccc(B2c3ccccc3Oc3cc(-c4ccc(-n5c6ccccc6c6ccc7c8ccccc8n(-c8ccccc8)c7c65)cc4)ccc32)cc1]

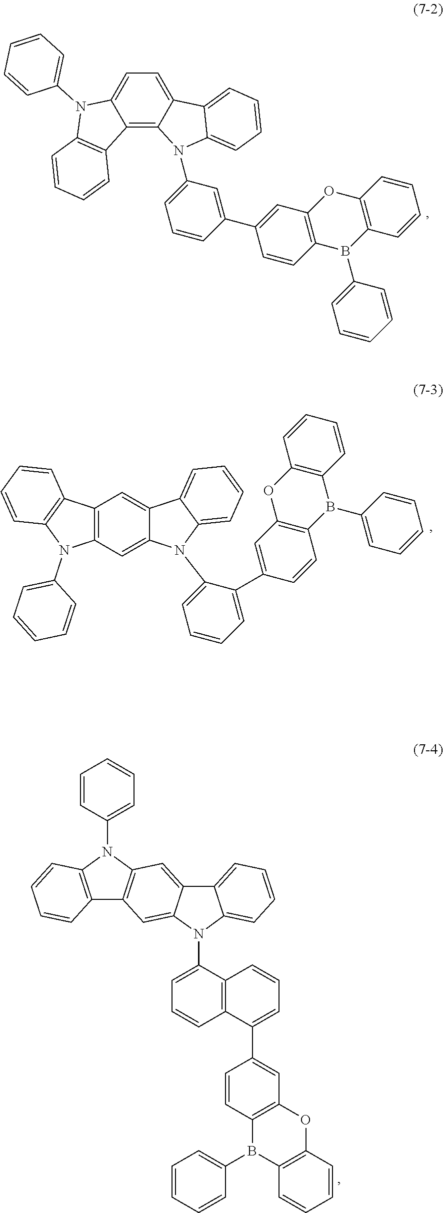 [SMILES: c1ccc(B2c3ccccc3Oc3cc(-c4cccc(-n5c6ccccc6c6ccc7c(c8ccccc8n7-c7ccccc7)c65)c4)ccc32)cc1 ; c1ccc(B2c3ccccc3Oc3cc(-c4ccccc4-n4c5ccccc5c5cc6c7ccccc7n(-c7ccccc7)c6cc54)ccc32)cc1 ; c1ccc(B2c3ccccc3Oc3cc(-c4cccc5c(-n6c7ccccc7c7cc8c(cc76)c6ccccc6n8-c6ccccc6)cccc45)ccc32)cc1]

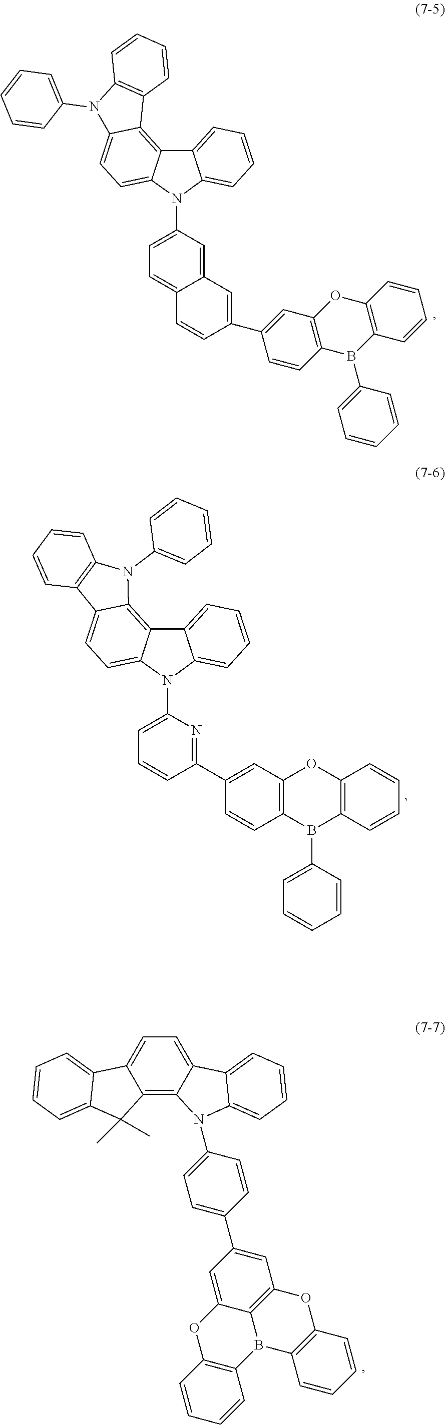 [SMILES: c1ccc(B2c3ccccc3Oc3cc(-c4ccc5ccc(-n6c7ccccc7c7c8c9ccccc9n(-c9ccccc9)c8ccc76)cc5c4)ccc32)cc1 ; c1ccc(B2c3ccccc3Oc3cc(-c4cccc(-n5c6ccccc6c6c5ccc5c7ccccc7n(-c7ccccc7)c56)n4)ccc32)cc1 ; CC1(C)c2ccccc2-c2ccc3c4ccccc4n(-c4ccc(-c5cc6c7c(c5)Oc5ccccc5B7c5ccccc5O6)cc4)c3c21]

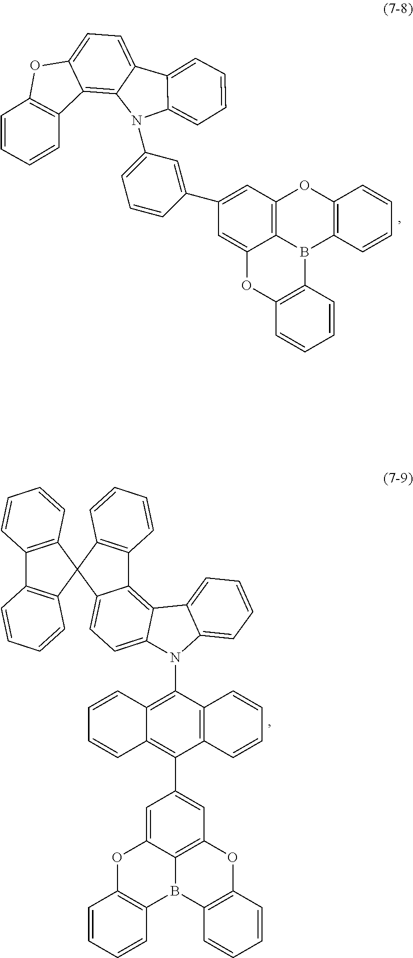 [SMILES: c1cc(-c2cc3c4c(c2)Oc2ccccc2B4c2ccccc2O3)cc(-n2c3ccccc3c3ccc4oc5ccccc5c4c32)c1 ; c1ccc2c(c1)Oc1cc(-c3c4ccccc4c(-n4c5ccccc5c5c6c(ccc54)C4(c5ccccc5-c5ccccc54)c4ccccc4-6)c4ccccc34)cc3c1B2c1ccccc1O3]

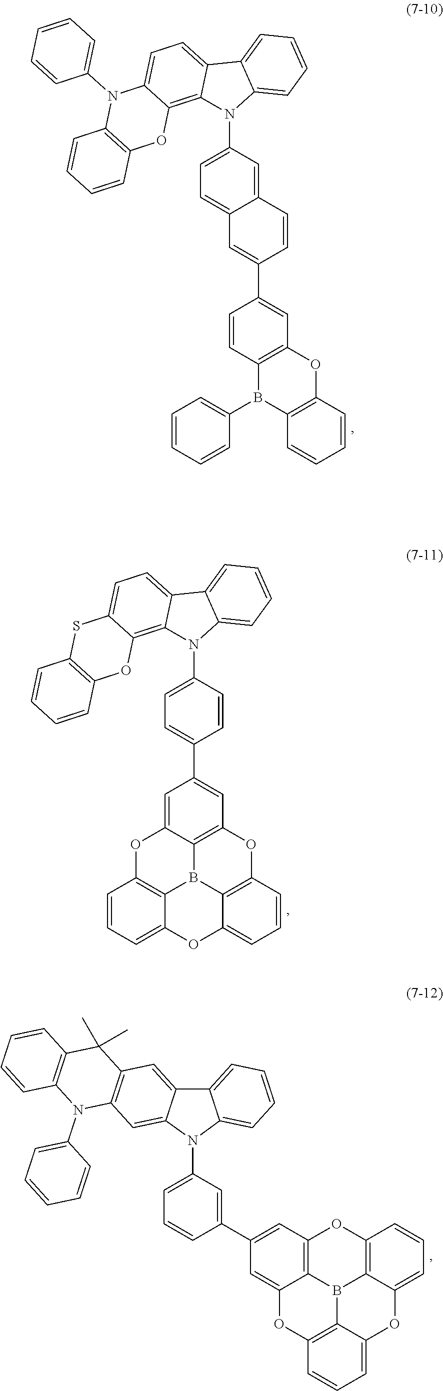 [SMILES: c1ccc(B2c3ccccc3Oc3cc(-c4ccc5cc(-n6c7ccccc7c7ccc8c(c76)Oc6ccccc6N8c6ccccc6)ccc5c4)ccc32)cc1 ; c1ccc2c(c1)Oc1c(ccc3c4ccccc4n(-c4ccc(-c5cc6c7c(c5)Oc5cccc8c5B7c5c(cccc5O6)O8)cc4)c13)S2 ; CC1(C)c2ccccc2N(c2ccccc2)c2cc3c(cc21)c1ccccc1n3-c1cccc(-c2cc3c4c(c2)Oc2cccc5c2B4c2c(cccc2O3)O5)c1]

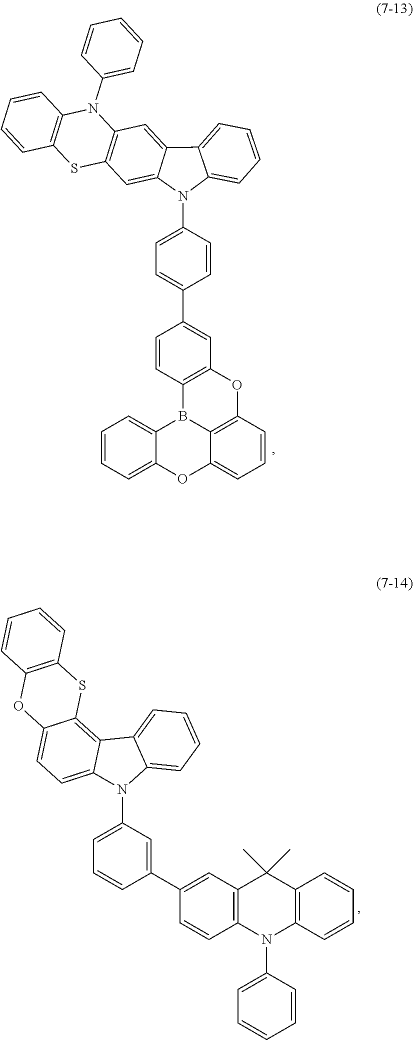 [SMILES: c1ccc(N2c3ccccc3Sc3cc4c(cc32)c2ccccc2n4-c2ccc(-c3ccc4c(c3)Oc3cccc5c3B4c3ccccc3O5)cc2)cc1 ; CC1(C)c2ccccc2N(c2ccccc2)c2ccc(-c3cccc(-n4c5ccccc5c5c6c(ccc54)Oc4ccccc4S6)c3)cc21]

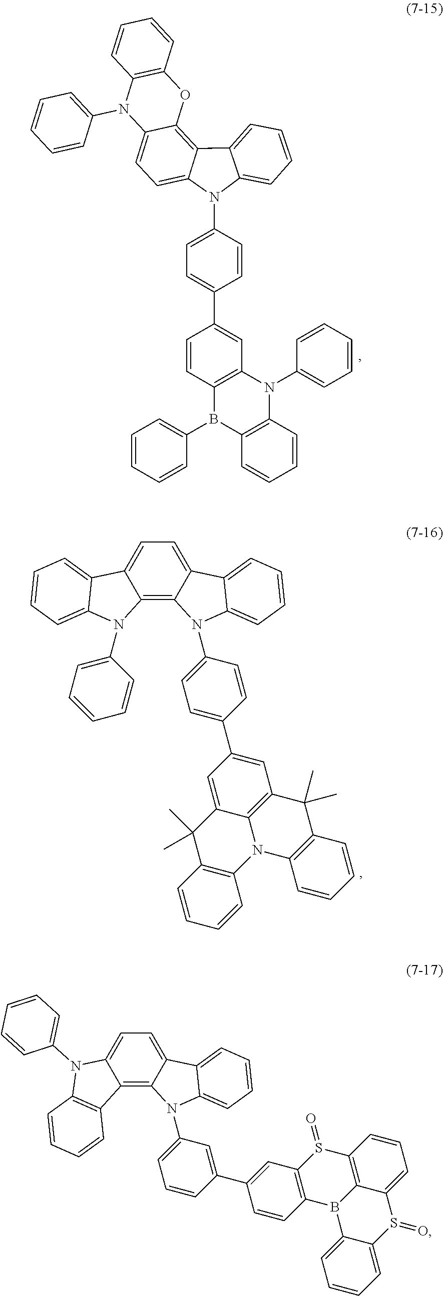 [SMILES: c1ccc(B2c3ccccc3N(c3ccccc3)c3cc(-c4ccc(-n5c6ccccc6c6c7c(ccc65)N(c5ccccc5)c5ccccc5O7)cc4)ccc32)cc1 ; CC1(C)c2ccccc2N2c3ccccc3C(C)(C)c3cc(-c4ccc(-n5c6ccccc6c6ccc7c8ccccc8n(-c8ccccc8)c7c65)cc4)cc1c32 ; O=S1c2ccccc2B2c3ccc(-c4cccc(-n5c6ccccc6c6ccc7c(c8ccccc8n7-c7ccccc7)c65)c4)cc3S(=O)c3cccc1c32]

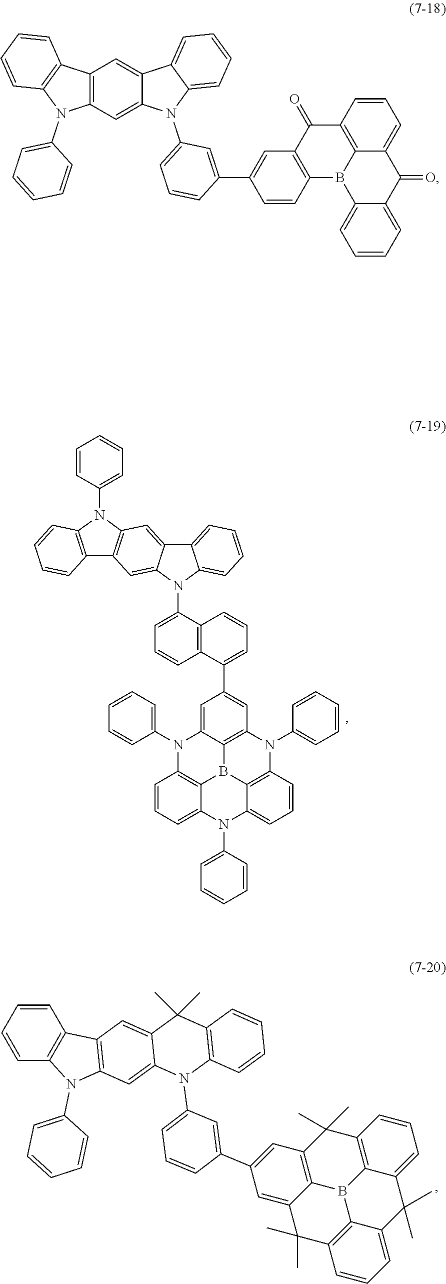 [SMILES: O=C1c2ccccc2B2c3ccc(-c4cccc(-n5c6ccccc6c6cc7c8ccccc8n(-c8ccccc8)c7cc65)c4)cc3C(=O)c3cccc1c32 ; c1ccc(N2c3cccc4c3B3c5c2cccc5N(c2ccccc2)c2cc(-c5cccc6c(-n7c8ccccc8c8cc9c(cc87)c7ccccc7n9-c7ccccc7)cccc56)cc(c23)N4c2ccccc2)cc1 ; CC1(C)c2ccccc2N(c2cccc(-c3cc4c5c(c3)C(C)(C)c3cccc6c3B5c3c(cccc3C4(C)C)C6(C)C)c2)c2cc3c(cc21)c1ccccc1n3-c1ccccc1]

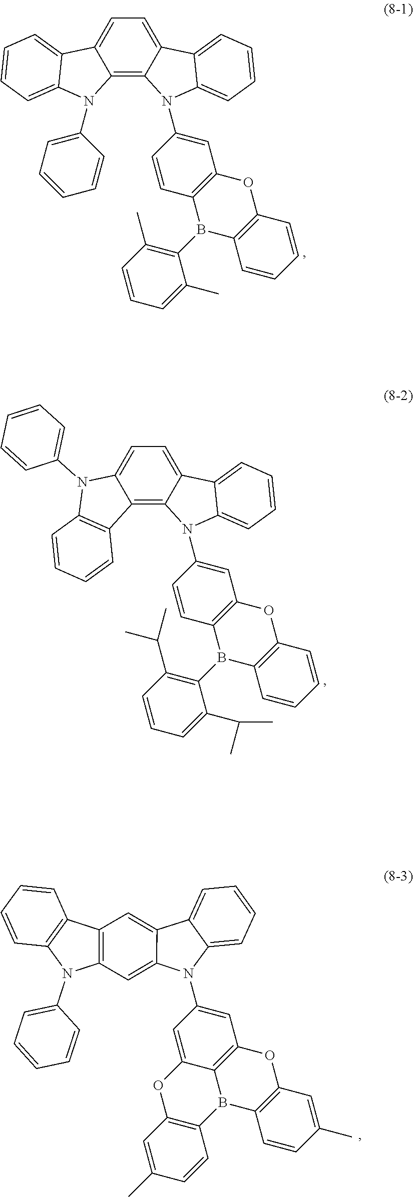 [SMILES: Cc1cccc(C)c1B1c2ccccc2Oc2cc(-n3c4ccccc4c4ccc5c6ccccc6n(-c6ccccc6)c5c43)ccc21 ; CC(C)c1cccc(C(C)C)c1B1c2ccccc2Oc2cc(-n3c4ccccc4c4ccc5c(c6ccccc6n5-c5ccccc5)c43)ccc21 ; Cc1ccc2c(c1)Oc1cc(-n3c4ccccc4c4cc5c6ccccc6n(-c6ccccc6)c5cc43)cc3c1B2c1ccc(C)cc1O3]

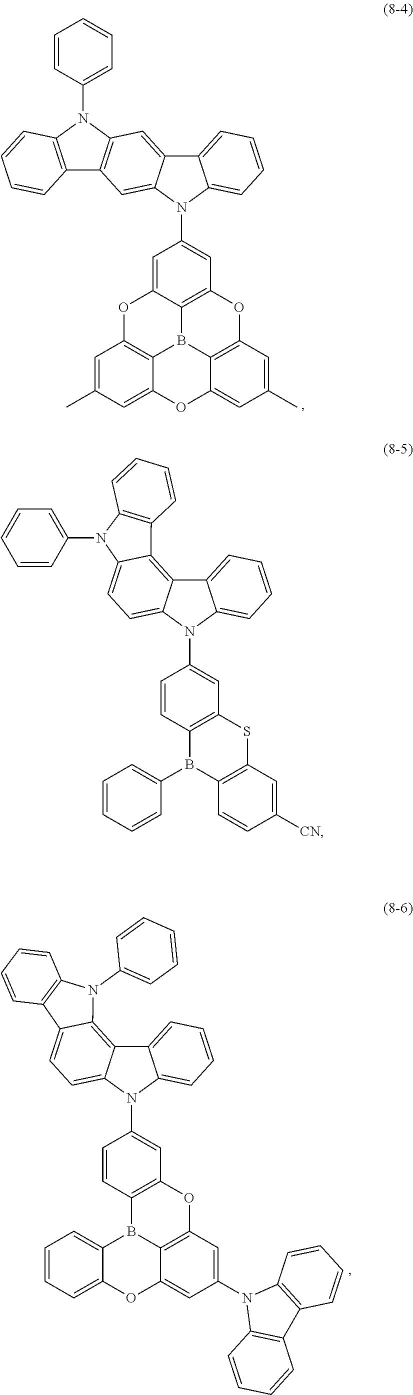 [SMILES: Cc1cc2c3c(c1)Oc1cc(-n4c5ccccc5c5cc6c(cc54)c4ccccc4n6-c4ccccc4)cc4c1B3c1c(cc(C)cc1O4)O2 ; N#Cc1ccc2c(c1)Sc1cc(-n3c4ccccc4c4c5c6ccccc6n(-c6ccccc6)c5ccc43)ccc1B2c1ccccc1 ; c1ccc(-n2c3ccccc3c3ccc4c(c5ccccc5n4-c4ccc5c(c4)Oc4cc(-n6c7ccccc7c7ccccc76)cc6c4B5c4ccccc4O6)c32)cc1]

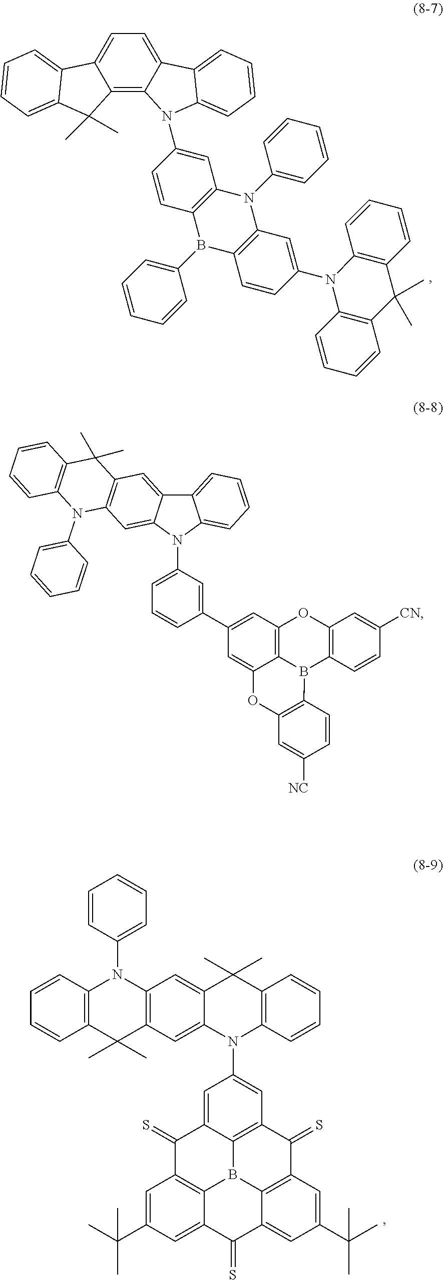 [SMILES: CC1(C)c2ccccc2N(c2ccc3c(c2)N(c2ccccc2)c2cc(-n4c5ccccc5c5ccc6c(c54)C(C)(C)c4ccccc4-6)ccc2B3c2ccccc2)c2ccccc21 ; CC1(C)c2ccccc2N(c2ccccc2)c2cc3c(cc21)c1ccccc1n3-c1cccc(-c2cc3c4c(c2)Oc2cc(C#N)ccc2B4c2ccc(C#N)cc2O3)c1 ; CC(C)(C)c1cc2c3c(c1)C(=S)c1cc(C(C)(C)C)cc4c1B3c1c(cc(N3c5ccccc5C(C)(C)c5cc6c(cc53)C(C)(C)c3ccccc3N6c3ccccc3)cc1C4=S)C2=S]

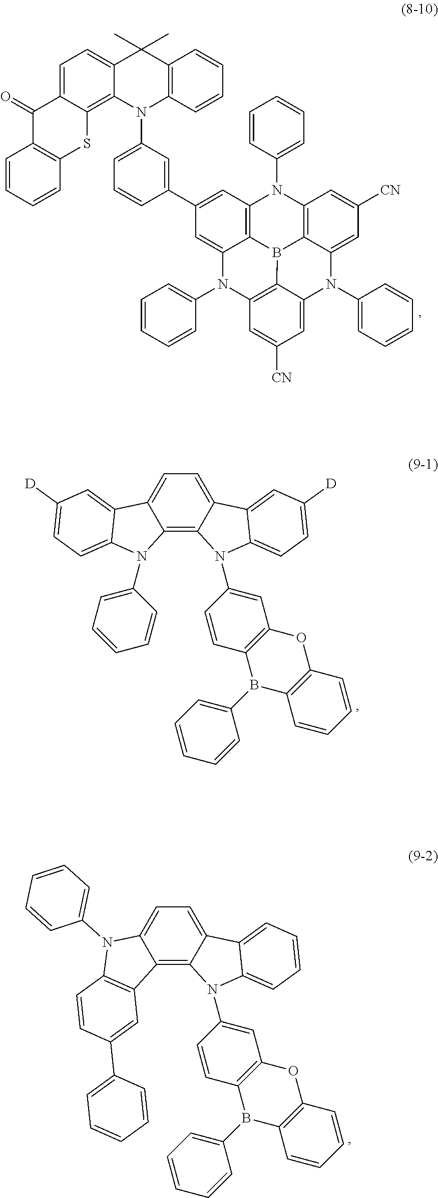 [SMILES: CC1(C)c2ccccc2N(c2cccc(-c3cc4c5c(c3)N(c3ccccc3)c3cc(C#N)cc6c3B5c3c(cc(C#N)cc3N4c3ccccc3)N6c3ccccc3)c2)c2c1ccc1c(=O)c3ccccc3sc21 ; [2H]c1ccc2c(c1)c1ccc3c4cc([2H])ccc4n(-c4ccc5c(c4)Oc4ccccc4B5c4ccccc4)c3c1n2-c1ccccc1 ; c1ccc(B2c3ccccc3Oc3cc(-n4c5ccccc5c5ccc6c(c7cc(-c8ccccc8)ccc7n6-c6ccccc6)c54)ccc32)cc1]

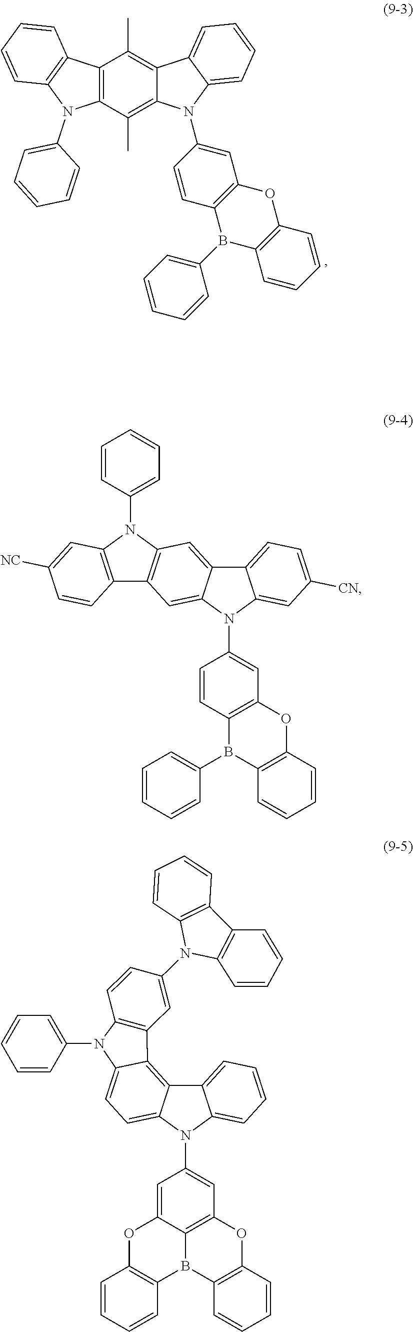

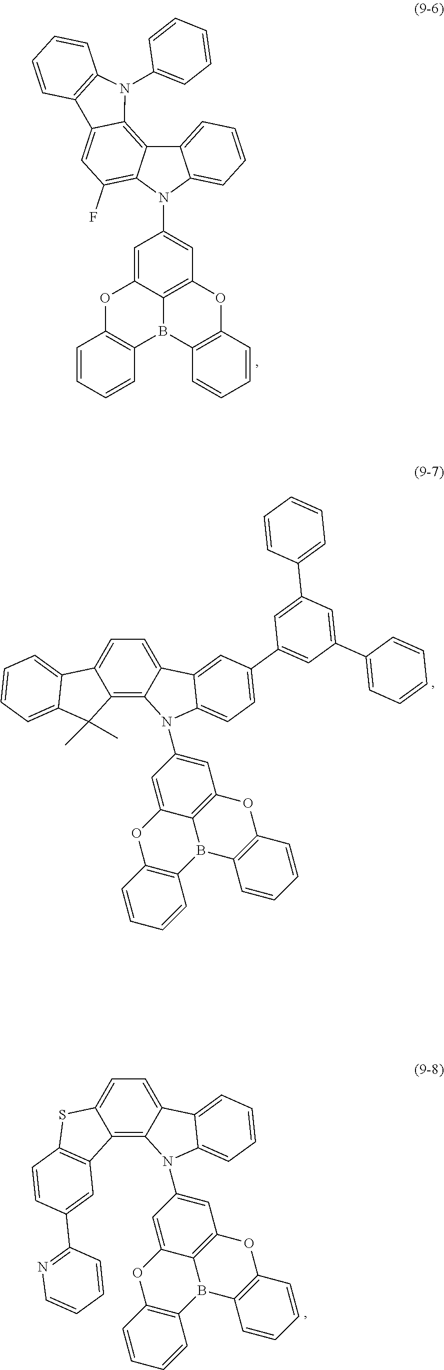 [SMILES: Fc1cc2c3ccccc3n(-c3ccccc3)c2c2c3ccccc3n(-c3cc4c5c(c3)Oc3ccccc3B5c3ccccc3O4)c12 ; CC1(C)c2ccccc2-c2ccc3c4cc(-c5cc(-c6ccccc6)cc(-c6ccccc6)c5)ccc4n(-c4cc5c6c(c4)Oc4ccccc4B6c4ccccc4O5)c3c21 ; c1ccc(-c2ccc3sc4ccc5c6ccccc6n(-c6cc7c8c(c6)Oc6ccccc6B8c6ccccc6O7)c5c4c3c2)nc1]

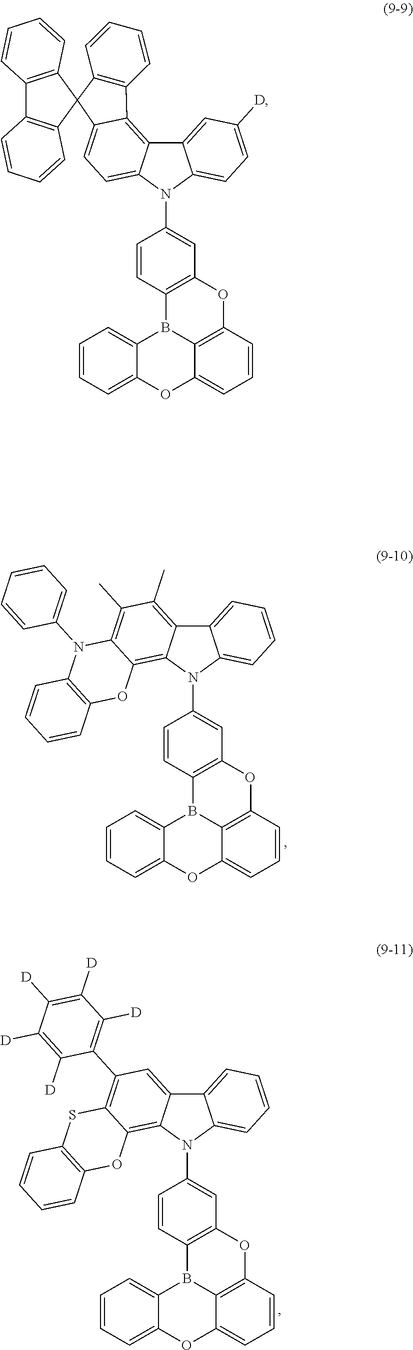

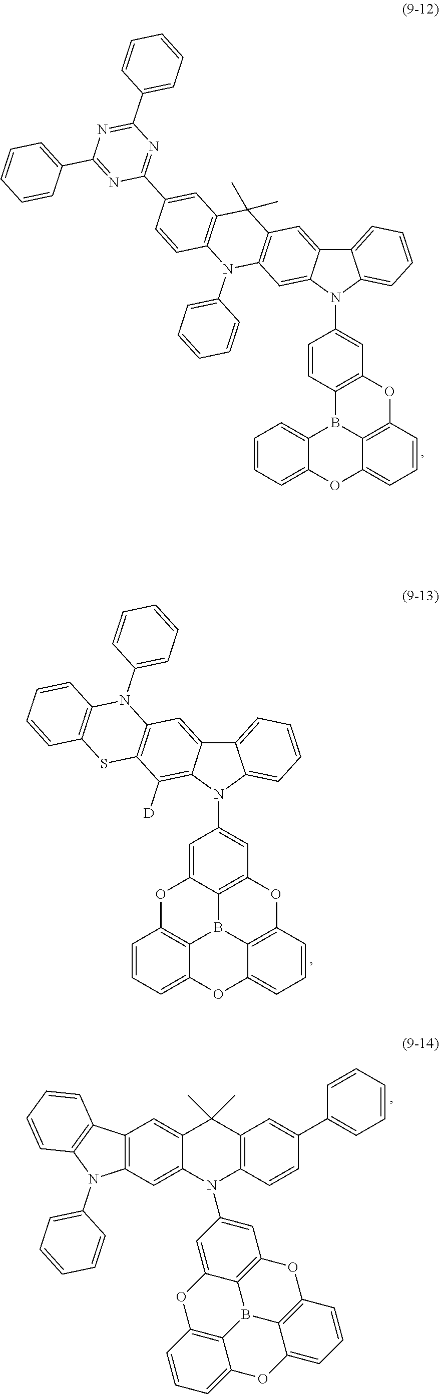 [SMILES: CC1(C)c2cc(-c3nc(-c4ccccc4)nc(-c4ccccc4)n3)ccc2N(c2ccccc2)c2cc3c(cc21)c1ccccc1n3-c1ccc2c(c1)Oc1cccc3c1B2c1ccccc1O3 ; [2H]c1c2c(cc3c4ccccc4n(-c4cc5c6c(c4)Oc4cccc7c4B6c4c(cccc4O5)O7)c13)N(c1ccccc1)c1ccccc1S2 ; CC1(C)c2cc(-c3ccccc3)ccc2N(c2cc3c4c(c2)Oc2cccc5c2B4c2c(cccc2O3)O5)c2cc3c(cc21)c1ccccc1n3-c1ccccc1]

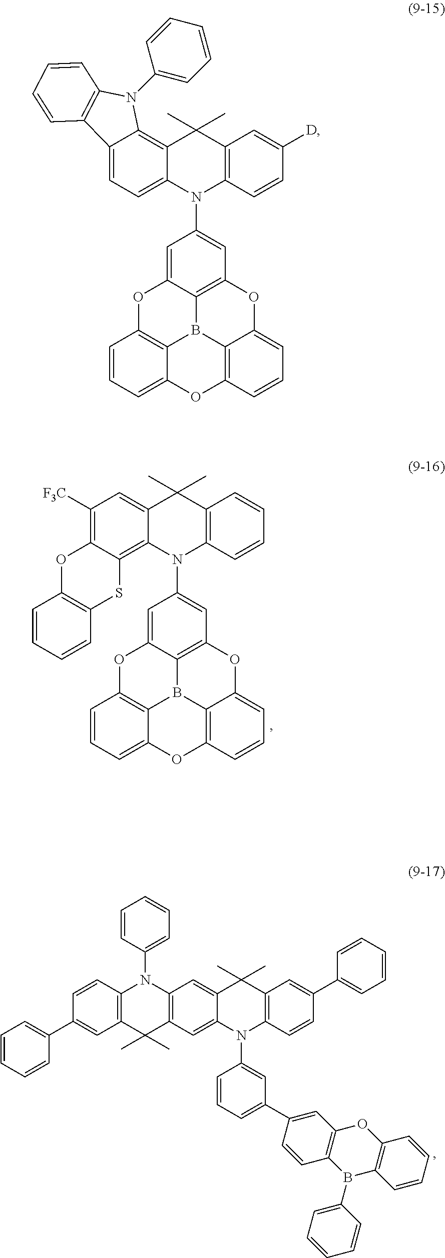

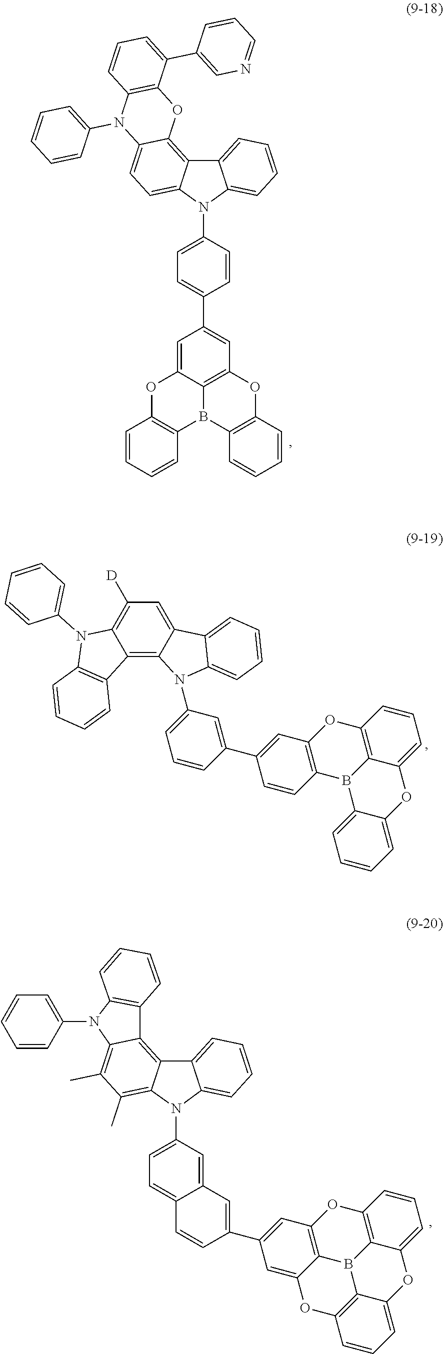 [SMILES: c1ccc(N2c3cccc(-c4cccnc4)c3Oc3c2ccc2c3c3ccccc3n2-c2ccc(-c3cc4c5c(c3)Oc3ccccc3B5c3ccccc3O4)cc2)cc1 ; [2H]c1cc2c3ccccc3n(-c3cccc(-c4ccc5c(c4)Oc4cccc6c4B5c4ccccc4O6)c3)c2c2c3ccccc3n(-c3ccccc3)c12 ; Cc1c(C)c2c(c3ccccc3n2-c2ccc3ccc(-c4cc5c6c(c4)Oc4cccc7c4B6c4c(cccc4O5)O7)cc3c2)c2c3ccccc3n(-c3ccccc3)c12]

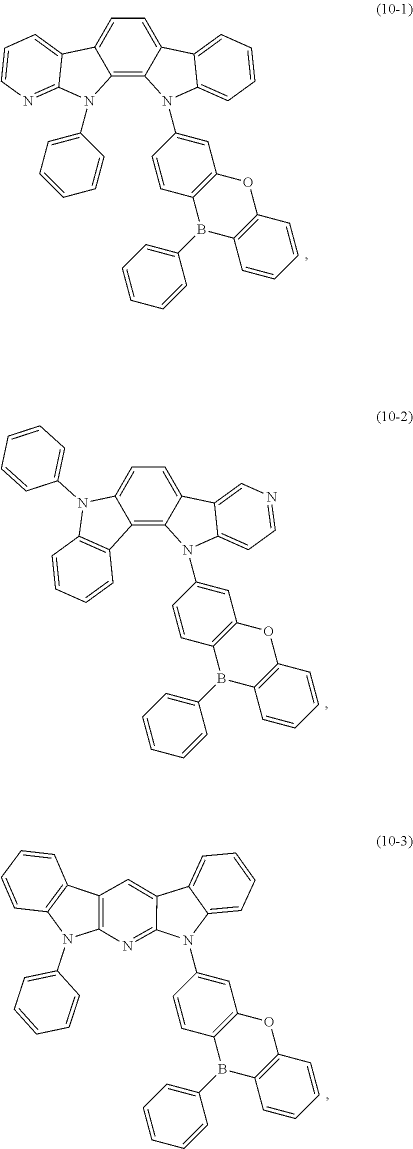 [SMILES: c1ccc(B2c3ccccc3Oc3cc(-n4c5ccccc5c5ccc6c7cccnc7n(-c7ccccc7)c6c54)ccc32)cc1 ; c1ccc(B2c3ccccc3Oc3cc(-n4c5ccncc5c5ccc6c(c7ccccc7n6-c6ccccc6)c54)ccc32)cc1 ; c1ccc(B2c3ccccc3Oc3cc(-n4c5ccccc5c5cc6c7ccccc7n(-c7ccccc7)c6nc54)ccc32)cc1]

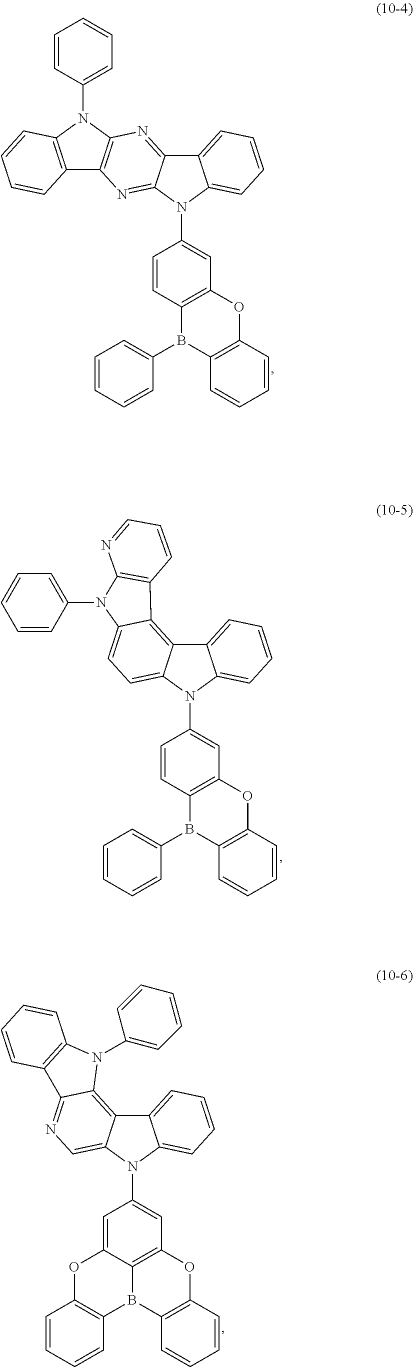 [SMILES: c1ccc(B2c3ccccc3Oc3cc(-n4c5ccccc5c5nc6c(nc54)c4ccccc4n6-c4ccccc4)ccc32)cc1 ; c1ccc(B2c3ccccc3Oc3cc(-n4c5ccccc5c5c6c7cccnc7n(-c7ccccc7)c6ccc54)ccc32)cc1 ; c1ccc(-n2c3ccccc3c3ncc4c(c5ccccc5n4-c4cc5c6c(c4)Oc4ccccc4B6c4ccccc4O5)c32)cc1]

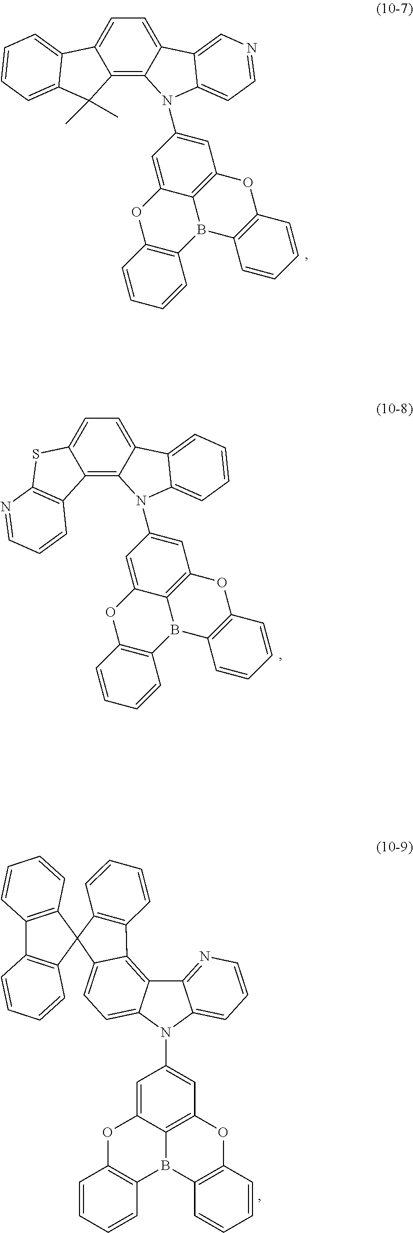 [SMILES: CC1(C)c2ccccc2-c2ccc3c4cnccc4n(-c4cc5c6c(c4)Oc4ccccc4B6c4ccccc4O5)c3c21 ; c1ccc2c(c1)Oc1cc(-n3c4ccccc4c4ccc5sc6ncccc6c5c43)cc3c1B2c1ccccc1O3 ; c1ccc2c(c1)Oc1cc(-n3c4cccnc4c4c5c(ccc43)C3(c4ccccc4-c4ccccc43)c3ccccc3-5)cc3c1B2c1ccccc1O3]

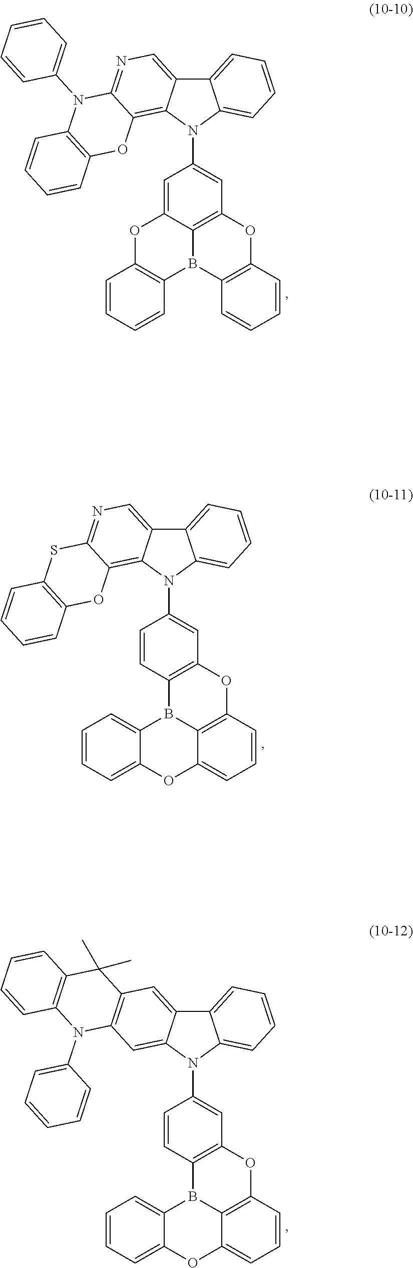 [SMILES: c1ccc(N2c3ccccc3Oc3c2ncc2c4ccccc4n(-c4cc5c6c(c4)Oc4ccccc4B6c4ccccc4O5)c32)cc1 ; c1ccc2c(c1)Oc1c(ncc3c4ccccc4n(-c4ccc5c(c4)Oc4cccc6c4B5c4ccccc4O6)c13)S2 ; CC1(C)c2ccccc2N(c2ccccc2)c2cc3c(cc21)c1ccccc1n3-c1ccc2c(c1)Oc1cccc3c1B2c1ccccc1O3]

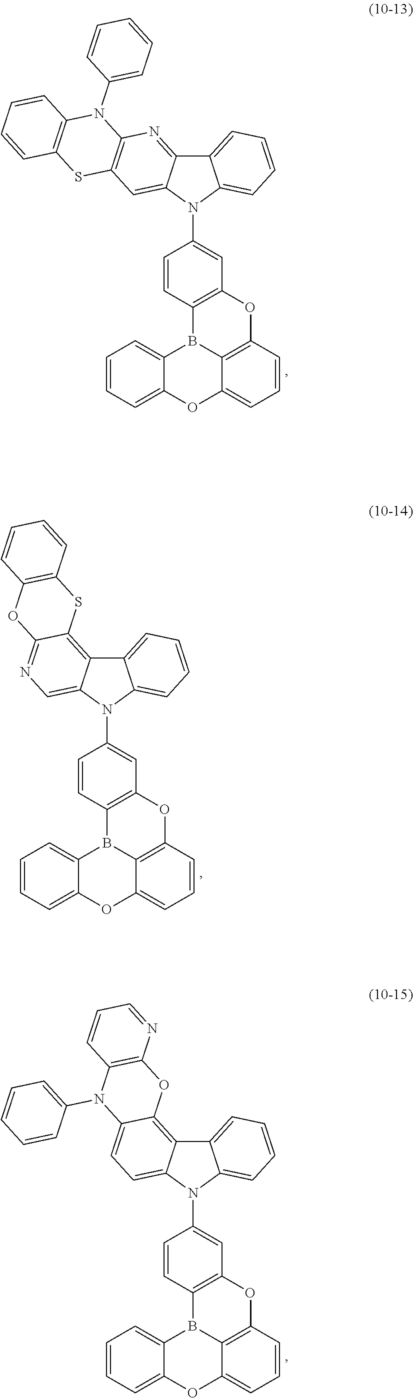 [SMILES: c1ccc(N2c3ccccc3Sc3cc4c(nc32)c2ccccc2n4-c2ccc3c(c2)Oc2cccc4c2B3c2ccccc2O4)cc1 ; c1ccc2c(c1)Oc1ncc3c(c1S2)c1ccccc1n3-c1ccc2c(c1)Oc1cccc3c1B2c1ccccc1O3 ; c1ccc(N2c3cccnc3Oc3c2ccc2c3c3ccccc3n2-c2ccc3c(c2)Oc2cccc4c2B3c2ccccc2O4)cc1]

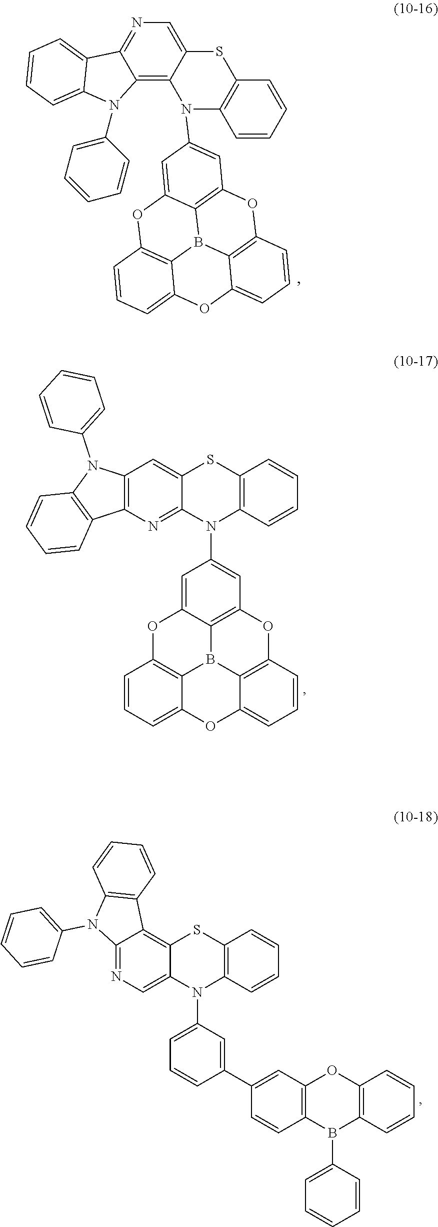 [SMILES: c1ccc(-n2c3ccccc3c3ncc4c(c32)N(c2cc3c5c(c2)Oc2cccc6c2B5c2c(cccc2O3)O6)c2ccccc2S4)cc1 ; c1ccc(-n2c3ccccc3c3nc4c(cc32)Sc2ccccc2N4c2cc3c4c(c2)Oc2cccc5c2B4c2c(cccc2O3)O5)cc1 ; c1ccc(B2c3ccccc3Oc3cc(-c4cccc(N5c6ccccc6Sc6c5cnc5c6c6ccccc6n5-c5ccccc5)c4)ccc32)cc1]

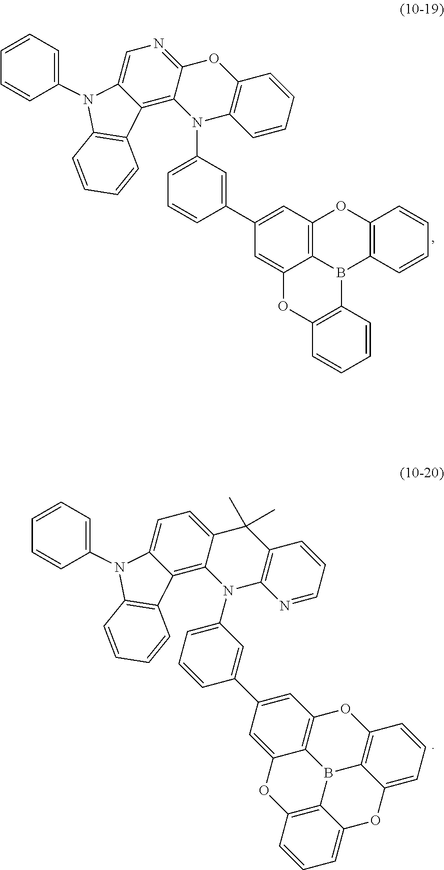 [SMILES: c1ccc(-n2c3ccccc3c3c4c(ncc32)Oc2ccccc2N4c2cccc(-c3cc4c5c(c3)Oc3ccccc3B5c3ccccc3O4)c2)cc1 ; CC1(C)c2cccnc2N(c2cccc(-c3cc4c5c(c3)Oc3cccc6c3B5c3c(cccc3O4)O6)c2)c2c1ccc1c2c2ccccc2n1-c1ccccc1]

In one embodiment, the D-A type compound according to the present disclosure is a small molecule material.

The term “small molecule” as defined herein refers to a molecule that is not a polymer, oligomer, dendrimer, or blend. In particular, there are no repeating structures in small molecules. The molecular weight of the small molecule is no greater than 3000 g/mole in one embodiment, no greater than 2000 g/mole in another embodiment, and no greater than 1500 g/mole in a particular embodiment.

The present disclosure also relates to a polymer comprising a repeating unit which comprises at least one structural unit shown in general formula (1). In some embodiments, the polymer is a non-conjugated polymer, wherein the structural unit shown in general formula (1) is on the side chain. In another embodiment, the polymer is a conjugated polymer.

Polymer includes homopolymer, copolymer, and block copolymer. In addition, in the present disclosure, the polymer also includes dendrimer. The synthesis and application of dendrimers are described in Dendrimers and Dendrons, Wiley-VCH Verlag GmbH & Co. KGaA, 2002, Ed. George R. Newkome, Charles N. Moorefield, Fritz Vogtle.

Conjugated polymer is a polymer whose backbone is primarily consisted of the sp2 hybrid orbital of carbon (C) atom. Some known examples are polyacetylene and poly (phenylene vinylene), on the backbone of which the C atom can also be optionally substituted by other non-C atoms, and which is still considered to be a conjugated polymer when the sp2 hybridization on the backbone is interrupted by some natural defects. In addition, the conjugated polymer in the present disclosure may also comprise aryl amine, aryl phosphine and other heteroaromatics, organometallic complexes, and the like on the backbone. In addition, the present disclosure further relates to a mixture comprising at least one organic compound or polymer according to the present disclosure, and at least one other organic functional material.

The organic functional material described herein includes: a hole (also called electron hole) injection or transport material (HIM/HTM), a hole blocking material (HBM), an electron injection or transport material (EIM/ETM), an electron blocking material (EBM), an organic host material (Host), a singlet emitter (fluorescent emitter), a triplet emitter (phosphorescent emitter), in particular, organic emitting metal complexes, and organic dyes. Various organic functional materials are described in detail in, for example, WO2010135519A1, US20090134784A1, and WO2011110277A1, the entire contents of which are hereby incorporated by reference.

The organic functional materials may be small molecules or polymer materials.

In certain embodiments, according to the mixture of the present disclosure, the content of the D-A type compound or the polymer formed from the D-A type compound in the mixture is 50 wt % to 99.9 wt %, furthermore 60 wt % to 97 wt % in other embodiments, still furthermore 70 wt % to 95 wt % in other embodiments, still furthermore 70 wt % to 90 wt % in other embodiments.

In one embodiment, the mixture according to the disclosure comprises a compound or a polymer according to the disclosure and a phosphorescent emitting material.

In another embodiment, the mixture according to the disclosure comprises a compound or polymer according to the disclosure and a TADF material.

In another embodiment, the mixture according to the disclosure comprises a compound or polymer according to the disclosure, a phosphorescent emitting material and a TADF material.

In certain embodiments, the mixture according to the present disclosure comprises a compound or polymer according to the present disclosure and a fluorescent emitting material.

Specifically, the singlet emitter, phosphorescent emitting material or triplet emitter and TADF material which are comprised in the mixture, may adopt any of the above materials commonly used in the art unless otherwise specified.

The fluorescent emitting material or singlet emitter, phosphorescent emitting material or triplet emitter, and TADF material are described in more detail below (but not limited thereto).

1. Singlet Emitter

The singlet emitter tends to have a longer conjugate 7-electron system. To date, there have been many examples, such as, but not limited to, styrylamine and derivatives thereof disclosed in JP2913116B and WO2001021729A1, and indenofluorene and derivatives thereof disclosed in WO2008/006449 and WO2007/140847.

In one embodiment, the singlet emitter can be selected from the group consisting of mono-styrylamine, di-styrylamine, tri-styrylamine, tetra-styrylamine, styrene phosphine, styrene ether, and arylamine.

A mono-styrylamine is a compound comprising an unsubstituted or substituted styryl group and at least one amine, for example an aromatic amine. A di-styrylamine is a compound comprising two unsubstituted or substituted styryl groups and at least one amine, for example an aromatic amine. A tri-styrylamine is a compound comprising three unsubstituted or substituted styryl groups and at least one amine, for example an aromatic amine. A tetra-styrylamine is a compound comprising four unsubstituted or substituted styryl groups and at least one amine, for example an aromatic amine. A styrene in one embodiment is stilbene, which may be further substituted. The definitions of the corresponding phosphines and ethers are similar to those of amines. An aryl amine or aromatic amine refers to a compound comprising three unsubstituted or optionally substituted aromatic cyclic or heterocyclic systems directly attached to nitrogen. At least one of these aromatic cyclic or heterocyclic systems is selected from fused ring systems in one embodiment and has at least 14 aromatic ring atoms in a particular embodiment. Among the examples are aromatic anthramine, aromatic anthradiamine, aromatic pyrene amines, aromatic pyrene diamines, aromatic chrysene amines and aromatic chrysene diamine. An aromatic anthramine refers to a compound in which a diarylamino group is directly attached to anthracene, at position 9 in a particular embodiment. An aromatic anthradiamine refers to a compound in which two diarylamino groups are directly attached to anthracene, at positions 9, 10 in a particular embodiment. An aromatic pyrene amines, aromatic pyrene diamines, aromatic chrysene amines and aromatic chrysene diamine are similarly defined, wherein the diarylarylamino group is attached to position 1 or 1 and 6 of pyrene in a particular embodiment.

Examples of singlet emitter based on vinylamine and arylamine are also preferred examples which may be found in the following patent documents: WO 2006/000388, WO 2006/058737, WO 2006/000389, WO 2007/065549, WO 2007/115610, U.S. Pat. No. 7,250,532 B2, DE 102005058557 A1, CN 1583691 A, JP 08053397 A, U.S. Pat. No. 6,251,531 B1, US 2006/210830 A, EP 1957606 A1, and US 2008/0113101 A1, the whole contents of which are incorporated herein by reference.

The examples of singlet emitters based on distyrylbenzene and derivatives thereof can be found in U.S. Pat. No. 5,121,029.

In some embodiments, the singlet emitters may be selected from the group consisting of: indenofluorene-amine and indenofluorene-diamine such as disclosed in WO 2006/122630, 50 benzoindenofluorene-amine and benzoindenofluorene-diamine such as disclosed in WO 2008/006449, dibenzoindenofluorene-amine and dibenzoindenofluorene-diamine such as disclosed in WO2007/140847.

Other materials useful as singlet emitters include, but not limited to, polycyclic aromatic compounds, especially any one selected from the derivatives of the following compounds: anthracenes such as 9,10-di(2-naphthylanthracene), naphthalene, tetraphenyl, oxyanthene, phenanthrene, perylene (such as 2,5,8,11-tetra-t-butylatedylene), indenoperylene, phenylenes (such as 4,4′-(bis (9-ethyl-3-carbazovinylene)-1,1′-biphenyl), periflanthene, decacyclene, coronene, fluorene, spirobifluorene, arylpyren (e.g., US20060222886), arylenevinylene (e.g., U.S. Pat. No. 5,121,029, U.S. Pat. No. 5,130,603), cyclopentadiene such as tetraphenylcyclopentadiene, rubrene, coumarine, rhodamine, quinacridone, pyrane such as 4 (dicyanoethylene)-6-(4-dimethylaminostyryl-2-methyl)-4H-pyrane (DCM), thiapyran, bis (azinyl) imine-boron compounds (US 2007/0092753 A1), bis (azinyl) methene compounds, carbostyryl compounds, oxazone, benzoxazole, benzothiazole, benzimidazole, and diketopyrrolopyrrole. Examples of some singlet emitter materials may be found in the following patent documents: US 20070252517 A1, U.S. Pat. No. 4,769,292, U.S. Pat. No. 6,020,078, US 2007/0252517 A1, US 2007/0252517 A1, the whole contents of which are incorporated herein by reference.

Examples of suitable singlet emitters are listed below:

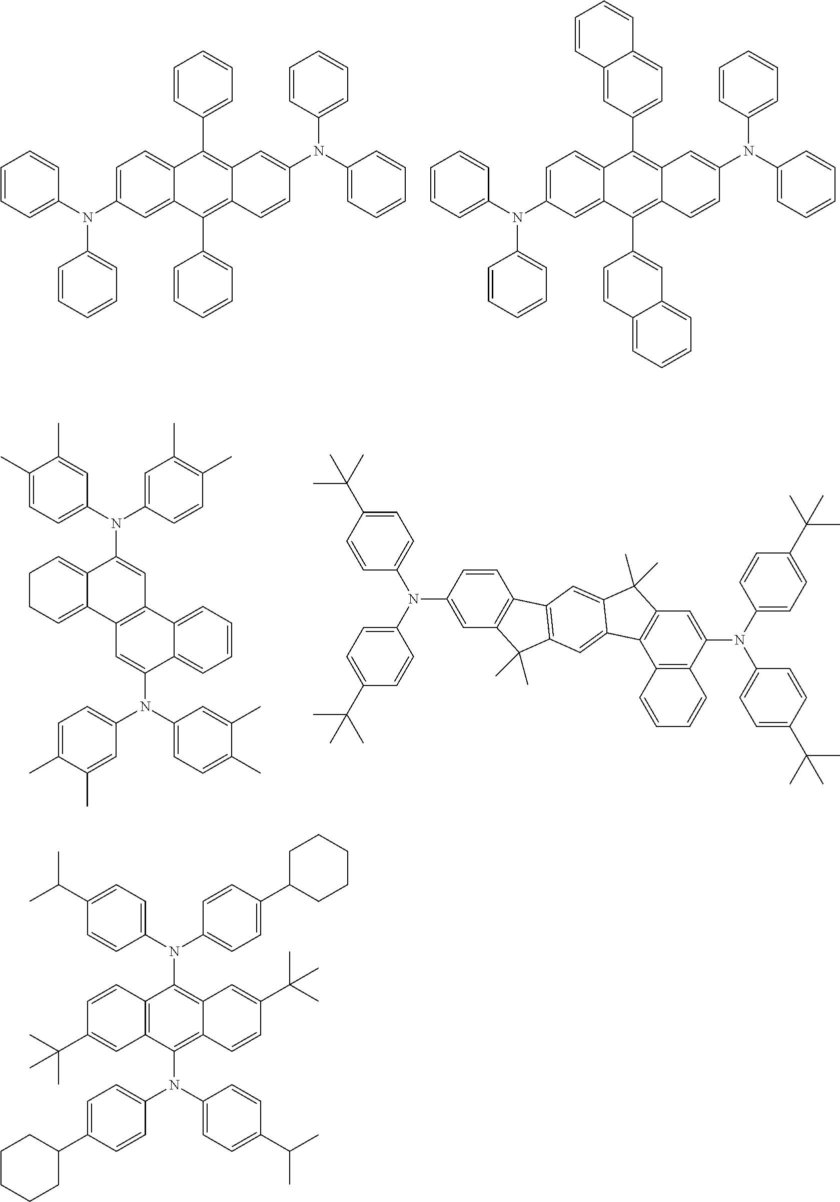

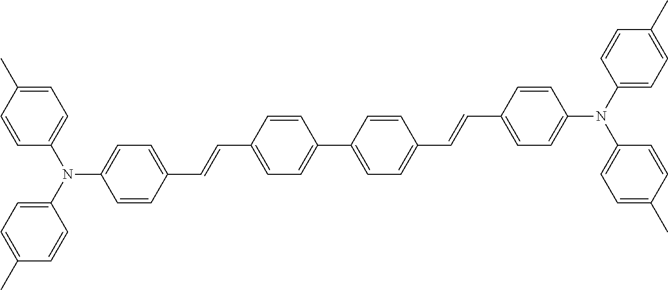 [SMILES: Cc1ccc(N(c2ccc(C)cc2)c2ccc(/C=C/c3ccc(-c4ccc(/C=C/c5ccc(N(c6ccc(C)cc6)c6ccc(C)cc6)cc5)cc4)cc3)cc2)cc1]

2. Thermally Activated Delayed Fluorescent Materials (TADF):

Traditional organic fluorescent materials can only emit light using 25% singlet excitonic luminescence formed by electrical excitation, and the devices have relatively low internal quantum efficiency (up to 25%). The phosphorescent material enhances the intersystem crossing due to the strong spin-orbit coupling of the heavy atom center, the singlet exciton and the triplet exciton luminescence formed by the electric excitation can be effectively utilized, so that the internal quantum efficiency of the device can reach 100%. However, the phosphor materials are expensive, the material stability is poor, and the device efficiency roll-off is a serious problem, which limit its application in OLED. Thermally-activated delayed fluorescent materials are the third generation of organic light-emitting materials developed after organic fluorescent materials and organic phosphorescent materials. This type of material generally has a small singlet-triplet energy level difference (AEst), and triplet excitons can be converted to singlet excitons by intersystem crossing. This can make full use of the singlet excitons and triplet excitons formed under electric excitation. The device can achieve 100% quantum efficiency.

The TADF material needs to have a small singlet-triplet energy level difference, typically ΔEst<0.3 eV in one emdodiment, ΔEst<0.2 eV in another embodiment, ΔEst<0.1 eV in another embodiment, and ΔEst<0.05 eV in a particular embodiment. In one embodiment, TADF has good fluorescence quantum efficiency. Some TADF emitting materials can be found in the following patent documents: CN103483332(A), TW201309696(A), TW201309778(A), TW201343874(A), TW201350558(A), US20120217869(A1), WO2013133359(A1), WO2013154064 (A1), Adachi, et.al. Adv. Mater., 21, 2009, 4802, Adachi, et.al. Appl. Phys. Lett., 98, 2011, 083302, Adachi, et.al. Appl. Phys. Lett., 101, 2012, 093306, Adachi, et.al. Chem. Commun., 48, 2012, 11392, Adachi, et.al. Nature Photonics, 6, 2012, 253, Adachi, et.al. Nature, 492, 2012, 234, Adachi, et.al. J. Am. Chem. Soc, 134, 2012, 14706, Adachi, et.al. Angew. Chem. Int. Ed, 51, 2012, 11311, Adachi, et.al. Chem. Commun., 48, 2012, 9580, Adachi, et.al. Chem. Commun., 48, 2013, 10385, Adachi, et.al. Adv. Mater., 25, 2013, 3319, Adachi, et.al. Adv. Mater., 25, 2013, 3707, Adachi, et.al. Chem. Mater., 25, 2013, 3038, Adachi, et.al. Chem. Mater., 25, 2013, 3766, Adachi, et. Al. J. Mater. Chem. C., 1, 2013, 4599, Adachi, et.al. J. Phys. Chem. A., 117, 2013, 5607. The entire contents of the above listed patent or literature documents are hereby incorporated by reference.

Some examples of suitable TADF light-emitting materials are listed in the following table:

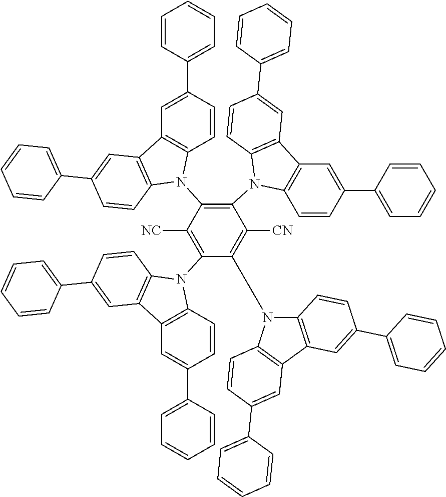 [SMILES: N#Cc1c(-n2c3ccc(-c4ccccc4)cc3c3cc(-c4ccccc4)ccc32)c(-n2c3ccc(-c4ccccc4)cc3c3cc(-c4ccccc4)ccc32)c(C#N)c(-n2c3ccc(-c4ccccc4)cc3c3cc(-c4ccccc4)ccc32)c1-n1c2ccc(-c3ccccc3)cc2c2cc(-c3ccccc3)ccc21]

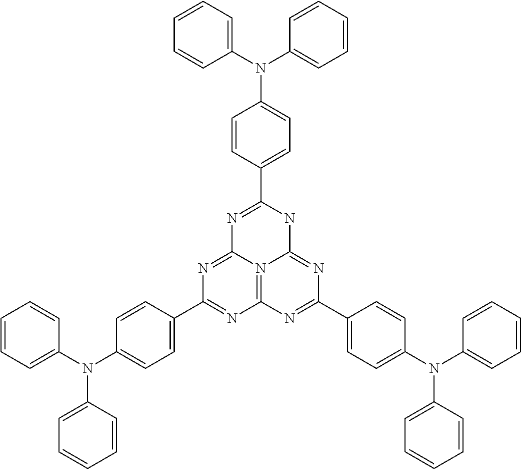

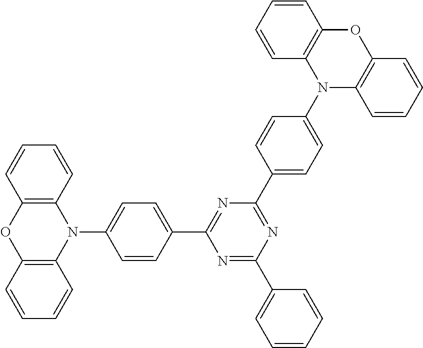 [SMILES: c1ccc(-c2nc(-c3ccc(N4c5ccccc5Oc5ccccc54)cc3)nc(-c3ccc(N4c5ccccc5Oc5ccccc54)cc3)n2)cc1]

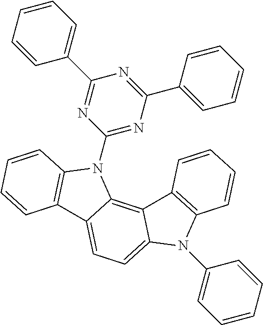 [SMILES: c1ccc(-c2nc(-c3ccccc3)nc(-n3c4ccccc4c4ccc5c(c6ccccc6n5-c5ccccc5)c43)n2)cc1]

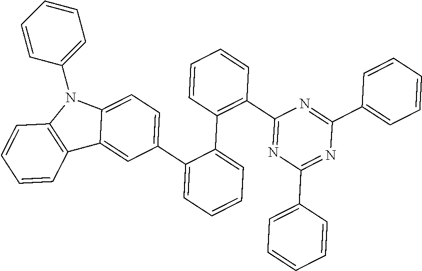 [SMILES: c1ccc(-c2nc(-c3ccccc3)nc(-c3ccccc3-c3ccccc3-c3ccc4c(c3)c3ccccc3n4-c3ccccc3)n2)cc1]

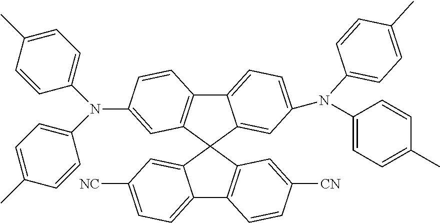

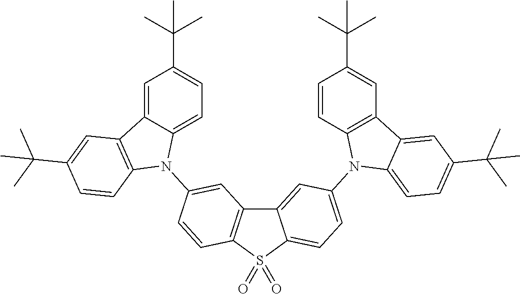 [SMILES: CC(C)(C)c1ccc2c(c1)c1cc(C(C)(C)C)ccc1n2-c1ccc2c(c1)-c1cc(-n3c4ccc(C(C)(C)C)cc4c4cc(C(C)(C)C)ccc43)ccc1S2(=O)=O]

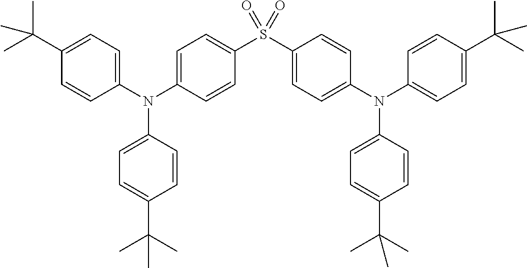 [SMILES: CC(C)(C)c1ccc(N(c2ccc(C(C)(C)C)cc2)c2ccc(S(=O)(=O)c3ccc(N(c4ccc(C(C)(C)C)cc4)c4ccc(C(C)(C)C)cc4)cc3)cc2)cc1]

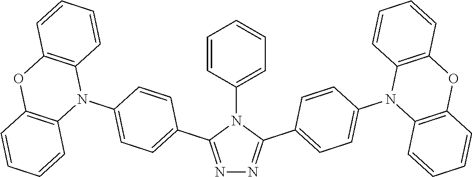 [SMILES: c1ccc(-n2c(-c3ccc(N4c5ccccc5Oc5ccccc54)cc3)nnc2-c2ccc(N3c4ccccc4Oc4ccccc43)cc2)cc1]

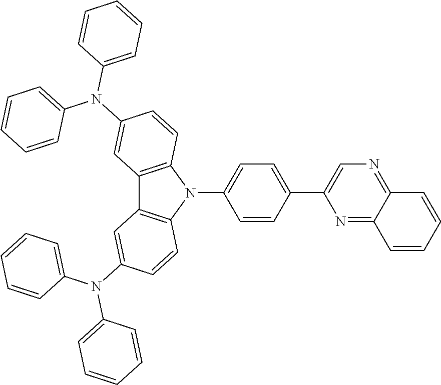 [SMILES: c1ccc(N(c2ccccc2)c2ccc3c(c2)c2cc(N(c4ccccc4)c4ccccc4)ccc2n3-c2ccc(-c3cnc4ccccc4n3)cc2)cc1]

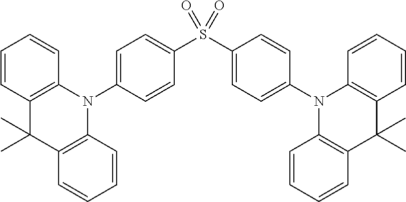 [SMILES: CC1(C)c2ccccc2N(c2ccc(S(=O)(=O)c3ccc(N4c5ccccc5C(C)(C)c5ccccc54)cc3)cc2)c2ccccc21]

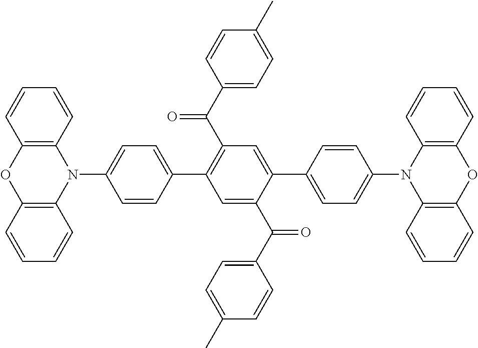 [SMILES: Cc1ccc(C(=O)c2cc(-c3ccc(N4c5ccccc5Oc5ccccc54)cc3)c(C(=O)c3ccc(C)cc3)cc2-c2ccc(N3c4ccccc4Oc4ccccc43)cc2)cc1]

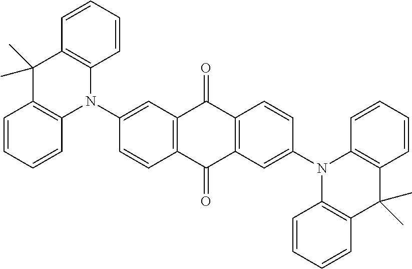

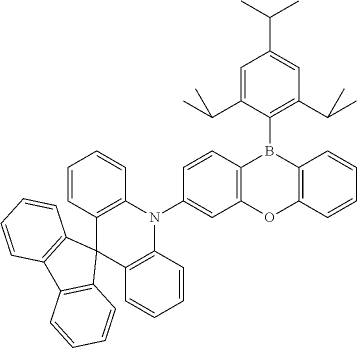 [SMILES: CC(C)c1cc(C(C)C)c(B2c3ccccc3Oc3cc(N4c5ccccc5C5(c6ccccc6-c6ccccc65)c5ccccc54)ccc32)c(C(C)C)c1]

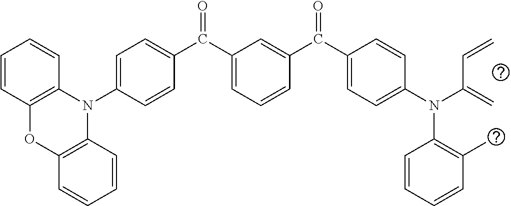 [SMILES: C=CC(=C)N(c1ccc(C(=O)c2cccc(C(=O)c3ccc(N4c5ccccc5Oc5ccccc54)cc3)c2)cc1)c1ccccc1C]

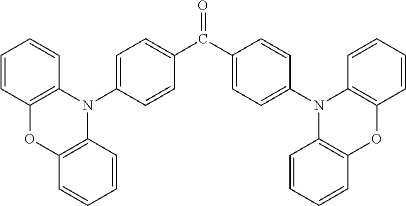 [SMILES: O=C(c1ccc(N2c3ccccc3Oc3ccccc32)cc1)c1ccc(N2c3ccccc3Oc3ccccc32)cc1]

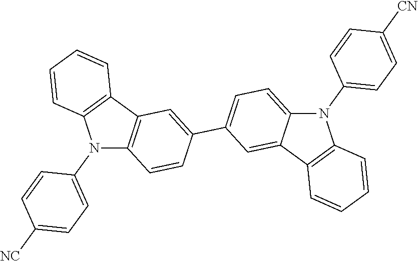 [SMILES: N#Cc1ccc(-n2c3ccccc3c3cc(-c4ccc5c(c4)c4ccccc4n5-c4ccc(C#N)cc4)ccc32)cc1]

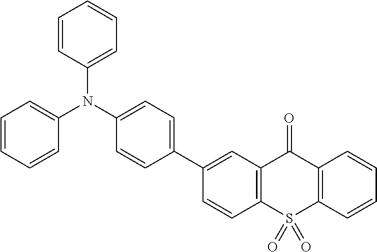 [SMILES: O=C1c2ccccc2S(=O)(=O)c2ccc(-c3ccc(N(c4ccccc4)c4ccccc4)cc3)cc21]

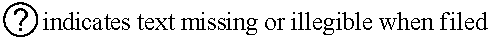

3. Triplet Emitter

Triplet emitters are also called phosphorescent emitters. In one embodiment, the triplet emitter is a metal complex with general formula M(L)ₙ, wherein M is a metal atom, and each occurrence of L may be the same or different and is an organic ligand which is bonded or coordinated to the metal atom M through one or more positions; n is an integer greater than 1, for example 1,2,3,4,5 or 6. Optionally, these metal complexes are attached to a polymer through one or more positions, for example through organic ligands.

In one embodiment, the metal atom M is selected from a transition metal element or a lanthanide element or a lanthanoid element. In one embodiment, the metal atom M is selected from the group consisting of Ir, Pt, Pd, Au, Rh, Ru, Os, Sm, Eu, Gd, Tb, Dy, Re, Cu and Ag. In another embodiment, the metal atom M is selected from the group consisting of Os, Ir, Ru, Rh, Re, Pd and Pt.

In one embodiment, the triplet emitter comprises chelating ligands, i.e. ligands, coordinated with the metal via at least two binding sites. In another embodiment, the triplet emitter comprises two or three identical or different bidentate or multidentate ligands. The chelating ligands are helpful to improve the stability of the metal complexes.

Examples of the organic ligands may be selected from the group consisting of phenylpyridine derivatives, 7,8-benzoquinoline derivatives, 2 (2-thienyl) pyridine derivatives, 2 (1-naphthyl) pyridine derivatives, and 2 phenylquinoline derivatives. All of these organic ligands may be substituted, for example, substituted by fluoromethyl or trifluoromethyl. Auxiliary ligands may be selected from acetylacetone or picric acid in one embodiment.

In one embodiment, the metal complexes that can be used as triplet emitters have the following form:

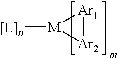

wherein M is a metal and selected from transition metal elements, lanthanoid elements, or lanthanoid elements;

Each occurrence of Ar₁ may be the same or different, wherein Ar₁ is a cyclic group and comprises at least one donor atom (i.e., an atom having one lone pair of electrons, such as nitrogen or phosphorus) through which the cyclic group is coordinately coupled with metal; Each occurrence of Ar₂ may be the same or different, wherein Ar₂ is a cyclic group and comprises at least one carbon atom through which the cyclic group is coupled with metal; Ar₁ and Ar₂ are covalently bonded together, and each of them may carry one or more substituents, and they may be coupled together by substituents again; Each occurrence of L may be the same or different, wherein L is an auxiliary ligand, such as a bidentate chelating ligand. In one embodiment, L is a monoanionic bidentate chelating ligand; m is 1, 2 or 3, such as 2 or 3. In one embodiment, m is 3; n is 0, 1 or 2, such as 0 or 1. In one embodiment, n is 0;

Some examples of triplet emitter materials and examples of applications thereof can be found in the following patent documents and references: WO 200070655, WO 200141512, WO 200202714, WO 200215645, EP 1191613, EP 1191612, EP 1191614, WO 2005033244, WO 2005019373, US 2005/0258742, WO 2009146770, WO 2010015307, WO 2010031485, WO 2010054731, WO 2010054728, WO 2010086089, WO 2010099852, WO 2010102709, US 20070087219 A1, US 20090061681 A1, US 20010053462 A1, Baldo, Thompson et al. Nature 403, (2000), 750-753, US 20090061681 A1, US 20090061681 A1, Adachi et al. Appl. Phys. Lett. 78 (2001), 1622-1624, J. Kido et al. Appl. Phys. Lett. 65 (1994), 2124, Kido et al. Chem. Lett. 657, 1990, US 2007/0252517 A1, Johnson et al., JACS 105, 1983, 1795, Wrighton, JACS 96, 1974, 998, Ma et al., Synth. Metals 94, 1998, 245, U.S. Pat. No. 6,824,895, U.S. Pat. No. 7,029,766, U.S. Pat. No. 6,835,469, U.S. Pat. No. 6,830,828, US 20010053462 A1, WO 2007095118 A1, US 2012004407A1, WO 2012007088A1, WO2012007087A1, WO 2012007086A1, US 2008027220A1, WO 2011157339A1, CN 102282150A, WO 2009118087A1. The entire contents of the above listed patent documents and literatures are hereby incorporated by reference.

Some suitable examples of triplet emitters are listed in the following table:

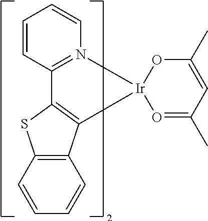

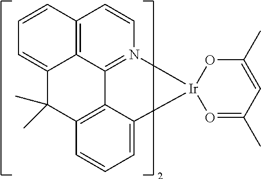

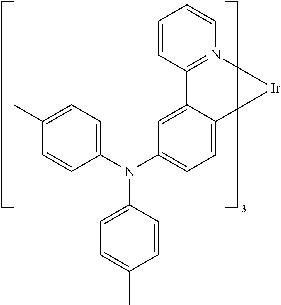

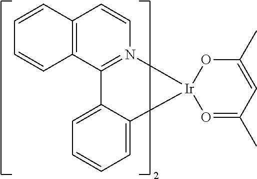

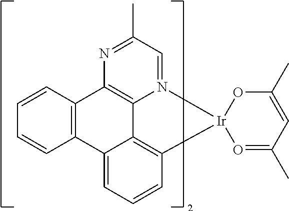

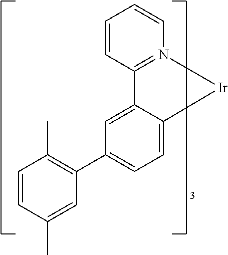

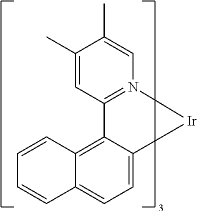

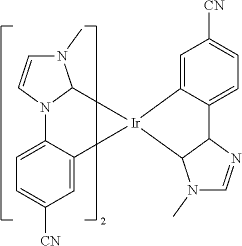

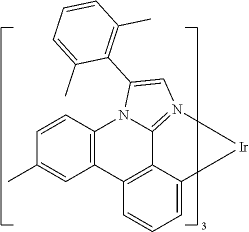

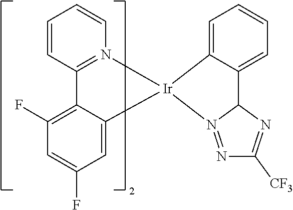

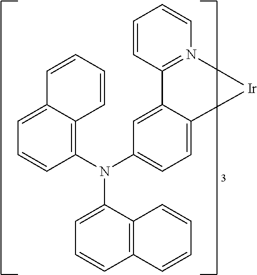

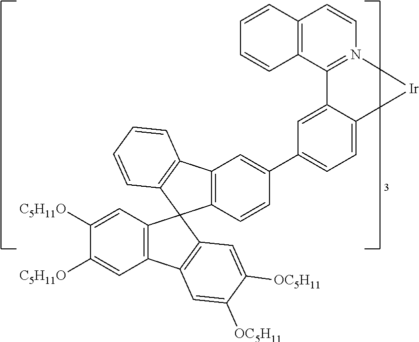

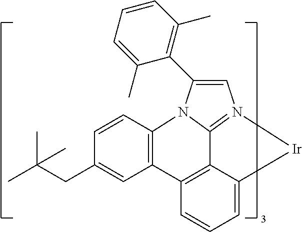

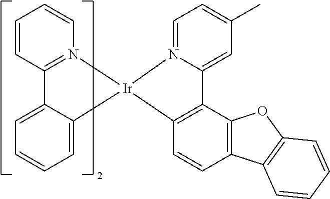

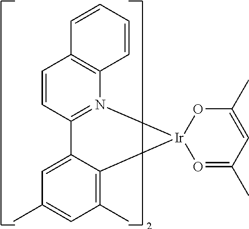

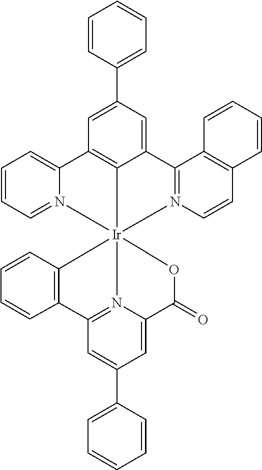

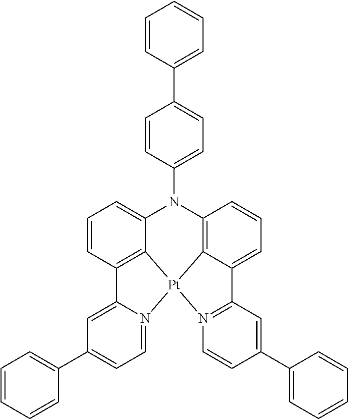

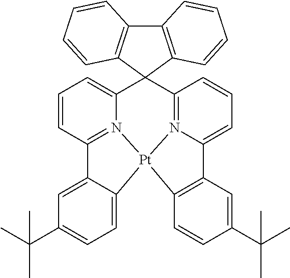

In addition, the present disclosure further relates to a formulation or printing ink comprising a compound or polymer or mixture as described above, and at least one organic solvent. Specifically, the formulation includes at least one D-A type compound of any of the above embodiments and at least one organic solvent; Alternatively, the formulation includes at least one polymer of any of the above embodiments and at least one organic solvent; Alternatively, the formulation includes at least one mixture of any of the above embodiments and at least one organic solvent.

The present disclosure further provides a film comprising the compound or polymer according to the present disclosure prepared by a solution.

The viscosity and surface tension of ink are important parameters when the ink is used in the printing process. The suitable surface tension parameters of ink are suitable for a specific substrate and a specific printing method.

In one embodiment, the surface tension of the ink according to the present disclosure at working temperature or at 25° C. is in the range of about 19 dyne/cm to 50 dyne/cm. In another embodiment, the surface tension of the ink according to the present disclosure at working temperature or at 25° C. is in the range of 22 dyne/cm to 35 dyne/cm. In another embodiment, the surface tension of the ink according to the present disclosure at working temperature or at 25° C. is in the range of 25 dyne/cm to 33 dyne/cm.

In another embodiment, the viscosity of the ink according to the present disclosure at the working temperature or at 25° C. is in the range of about 1 cps to 100 cps. In another embodiment, the viscosity of the ink according to the present disclosure at the working temperature or at 25° C. is in the range of 1 cps to 50 cps. In another embodiment, the viscosity of the ink according to the present disclosure at the working temperature or at 25° C. is in the range of 1.5 cps to 20 cps. In another embodiment, the viscosity of the ink according to the present disclosure at the working temperature or at 25° C. is in the range of 4.0 cps to 20 cps. The formulation so formulated will be suitable for inkjet printing.

The viscosity can be adjusted by different methods, such as by proper solvent selection and the concentration of functional materials in the ink. The ink according to the present disclosure comprising the compound or polymer can facilitate the adjustment of the printing ink in an appropriate range according to the printing method used. In general, the weight ratio of the functional material contained in the formulation according to the disclosure is in the range of 0.3 wt % to 30 wt %. In one embodiment, the weight ratio of the functional material contained in the formulation according to the disclosure is in the range of 0.5 wt % to 20 wt %. In another embodiment, the weight ratio of the functional material contained in the formulation according to the disclosure is 0.5 wt % to 15 wt %. In another embodiment, the weight ratio of the functional material contained in the formulation according to the disclosure is in the range of 0.5 wt % to 10 wt %. In another embodiment, the weight ratio of the functional material contained in the formulation according to the disclosure is in the range of 1 wt % to 5 wt %.

In some embodiments, according to the ink of the present disclosure, the at least one organic solvent is selected from solvents based on aromatics or heteroaromatics, especially aliphatic chain/ring substituted aromatic solvents, or aromatic ketone solvents, or aromatic ether solvents.

Examples suitable for solvents of the present disclosure include, but not limited to, the solvents based on aromatics or heteroaromatics: p-diisopropylbenzene, pentylbenzene, tetrahydronaphthalene, cyclohexyl benzene, chloronaphthalene, 1,4-dimethylnaphthalene, 3-isopropylbiphenyl, p-cymene, dipentylbenzene, tripentylbenzene, pentyltoluene, o-xylene, m-xylene, p-xylene, o-diethylbenzene, m-diethylbenzene, p-diethylbenzene, 1,2,3,4-tetramethylbenzene, 1,2,3,5-tetramethylbenzene, 1,2,4,5-tetramethylbenzene, butylbenzene, dodecylbenzene, dihexylbenzene, dibutylbenzene, p-diisopropylbenzene, 1-methoxynaphthalene, cyclohexylbenzene, dimethylnaphthalene, 3-isopropylbiphenyl, p-cymene, 1-methylnaphthalene, 1,2,4-trichlorobenzene, 1,3-dipropoxybenzene, 4,4-difluorodiphenylmethane, 1,2-dimethoxy-4-(1-propenyl)benzene, diphenylmethane, 2-phenylpyridine, 3-phenylpyridine, N-methyldiphenylamine 4-isopropylbiphenyl, α,α-dichlorodiphenylmethane, 4-(3-phenylpropyl)pyridine, benzylbenzoate, 1,1-di(3,4-dimethylphenyl)ethane, 2-isopropylnaphthalene, dibenzylether, and the like; solvents based on ketones: 1-tetralone, 2-tetralone, 2-(phenylepoxy)tetralone, 6-(methoxyl)tetralone, acetophenone, phenylacetone, benzophenone, and derivatives thereof, such as 4-methylacetophenone, 3-methylacetophenone, 2-methylacetophenone, 4-methylphenylacetone, 3-methylphenylacetone, 2-methylphenylacetone, isophorone, 2,6,8-trimethyl-4-nonanone, fenchone, 2-nonanone, 3-nonanone, 5-nonanone, 2-demayone, 2,5-hexanedione, phorone, di-n-amyl ketone; aromatic ether solvents: 3-phenoxytoluene, butoxybenzene, benzylbutylbenzene, p-anisaldehyde dimethyl acetal, tetrahydro-2-phenoxy-2H-pyran, 1,2-dimethoxy 4-(1-propenyl)benzene, 1,4-benzodioxane, 1,3-dipropylbenzene, 2,5-dimethoxytoluene, 4-ethylphenetole, 1,2,4-trimethoxybenzene, 4-(1-propenyl)-1,2-dimethoxybenzene, 1,3-dimethoxybenzene, glycidyl phenyl ether, dibenzyl ether, 4-tert-butylanisole, trans-p-propenylanisole, 1,2-dimethoxybenzene, 1-methoxynaphthalene, diphenyl ether, 2-phenoxymethyl ether, 2-phenoxytetrahydrofuran, ethyl-2-naphthyl ether, pentyl ether, hexyl ether, dioctyl ether, ethylene glycol dibutyl ether, diethylene glycol diethyl ether, diethylene glycol butyl methyl ether, diethylene glycol dibutyl ether, triethylene glycol dimethyl ether, triethylene glycol ethyl methyl ether, triethylene glycol butyl methyl ether, tripropylene glycol dimethyl ether, tetraethylene glycol dimethyl ether; and ester solvents: alkyl octoate, alkyl sebacate, alkyl stearate, alkyl benzoate, alkyl phenylacetate, alkyl cinnamate, alkyl oxalate, alkyl maleate, alkyl lactone, alkyl oleate, and the like.

Furthermore, according to the ink of the present disclosure, the at least one solvent can be selected from the group consisting of aliphatic ketones, such as 2-nonanone, 3-nonanone, 5-nonanone, 2-demayone, 2,5-hexanedione, 2,6,8-trimethyl-4-demayone, phorone, di-n-pentyl ketone, and the like; or aliphatic ethers, such as amyl ether, hexyl ether, dioctyl ether, ethylene glycol dibutyl ether, diethylene glycol diethyl ether, diethylene glycol butyl methyl ether, diethylene glycol dibutyl ether, triethylene glycol dimethyl ether, triethyl ether alcohol ethyl methyl ether, triethylene glycol butyl methyl ether, tripropylene glycol dimethyl ether, tetraethylene glycol dimethyl ether, and the like.

In other embodiments, the printing ink further comprises another organic solvent. Examples of another organic solvent comprise, but not limited to, methanol, ethanol, 2-methoxyethanol, dichloromethane, trichloromethane, chlorobenzene, o-dichlorobenzene, tetrahydrofuran, anisole, morpholine, toluene, o-xylene, m-xylene, p-xylene, 1,4-dioxane, acetone, methyl ethyl ketone, 1,2-dichloroethane, 3-phenoxy toluene, 1,1,1-trichloroethane, 1,1,2,2-tetrachloroethane, ethyl acetate, butyl acetate, dimethylformamide, dimethylacetamide, dimethyl sulfoxide, tetrahydronaphthalene, decalin, indene, and/or mixtures thereof.

In one embodiment, the formulation according to the disclosure is a solution.

In another embodiment, the formulation according to the disclosure is a suspension.

The present disclosure further relates to the application of the formulation as the printing ink to make an organic electron device, especially by a printing method or a coating method.

The appropriate printing technology or coating technology includes, but is not limited to inkjet printing, nozzle printing, typography, screen printing, dip coating, spin coating, blade coating, roller printing, twist roller printing, lithography, flexography, rotary printing, spray coating, brush coating or transfer printing, nozzle printing, slot die coating, and the like. The first preference is inkjet printing, slot die coating, nozzle printing, and typography. The solution or the suspension liquid may further includes one or more components, such as a surfactant compound, a lubricant, a wetting agent, a dispersant, a hydrophobic agent, a binder, to adjust the viscosity and the film forming property and to improve the adhesion property. The detailed information relevant to the printing technology and requirements of the printing technology to the solution, such as solvent, concentration, and viscosity, may be referred to Handbook of Print Media: Technologies and Production Methods, Helmut Kipphan, ISBN 3-540-67326-1.

Based on the above organic compound, the present disclosure also provides an application of the above compound or polymer in organic electronic devices. The organic electronic devices may be selected from, but not limited to, an organic light-emitting diode (OLED), an organic photovoltaic cell (OPV), an organic light-emitting electrochemical cell (OLEEC), an organic field effect transistor (OFET), an organic light-emitting field effect transistor, an organic laser, an organic spintronic 50 device, organic sensor, and an organic plasmon emitting diode, and the like, specially OLED. In an embodiment of the present disclosure, the organic compound is used in the light-emitting layer of the OLED device.

The present disclosure further relates to an organic electronic device comprising at least one compound or polymer as described above. Generally, such organic electronic device comprises at least one cathode, one anode, and at least one functional layer located between the cathode and the anode, wherein the functional layer comprises at least one compound or polymer as described above. The organic electronic devices may be selected from, but not limited to, an organic light-emitting diode (OLED), an organic photovoltaic cell (OPV), an organic light-emitting electrochemical cell (OLEEC), an organic field effect transistor (OFET), an organic light-emitting field effect transistor, an organic laser, an organic spintronic device, an organic sensor, and an organic plasmon emitting diode.

In one embodiment, the organic electronic device is an electroluminescent device, in particular an OLED, comprising a substrate, an anode, a cathode, and at least one light-emitting layer located between the anode and the cathode, and optionally comprising a hole transport layer and/or an electron transport layer. In some embodiments, the hole transport layer comprises a compound or polymer according to the present disclosure. In other embodiments, the electron transport layer comprises a compound or polymer according to the present disclosure. In one embodiment, the light-emitting layer comprises a compound or a polymer according to the present disclosure, more specifically, the light-emitting layer comprises a compound or a polymer according to the present disclosure and at least one light-emitting material which may be selected from fluorescent emitter, phosphorescent emitter, TADF material or light-emitting quantum dot.

The structure of the electroluminescent device is described below, but it is not limited.

The substrate may be opaque or transparent. The transparent substrate may be used to make the transparent luminescent device, which may be referred to, for example, Bulovic et al., Nature, 1996, 380, page 29 and Gu et al., Appl. Phys. Lett., 1996, 68, page 2606. The substrate may be rigid or elastic. The substrate may be plastic, metal, a semiconductor wafer, or glass. In one embodiment, the substrate has a smooth surface. The substrate without any surface defects is the particular ideal selection. In one embodiment, the substrate is flexible and may be selected from a polymer thin film or a plastic which have the glass transition temperature Tg larger than 150° C., larger than 200° C. in one embodiment, larger than 250° C. in another embodiment, larger than 300° C. in a particular embodiment. Suitable examples of the flexible substrate are polyethylene terephthalate (PET) and polyethylene 2,6-naphthalate (PEN).

The anode may include a conductive metal, metallic oxide, or a conductive polymer. The anode can inject holes easily into the hole injection layer (HIL), the hole transport layer (HTL), or the light-emitting layer. In one embodiment, the absolute value of the difference between the work function of the anode and the HOMO energy level or the valence band energy level of the emitter in the light-emitting layer or of the p-type semiconductor material of the HIL or HTL or the electron blocking layer (EBL) is smaller than 0.5 eV in one embodiment, smaller than 0.3 eV in another embodiment, smaller than 0.2 eV in a particular embodiment. Examples of the anode material include, but are not limited to Al, Cu, Au, Ag, Mg, Fe, Co, Ni, Mn, Pd, Pt, ITO, aluminum-doped zinc oxide (AZO), and the like. Other suitable anode materials are known and may be easily selected by one of ordinary skilled in the art. The anode material may be deposited by any suitable technologies, such as the suitable physical vapor deposition method which includes a radio frequency magnetron sputtering, a vacuum thermal evaporation, an electron beam, and the like. In some embodiments, the anode is patterned and structured. A patterned ITO conductive substrate may be purchased from market to prepare the device according to the present disclosure.

The cathode may include a conductive metal or metal oxide. The cathode can inject electrons easily into the electron injection layer (EIL) or the electron transport layer (ETL), or directly injected into the light-emitting layer. In one embodiment, the absolute value of the difference between the work function of the cathode and the LUMO energy level or the valence band energy level of the emitter in the light-emitting layer or of the n type semiconductor material as the electron injection 50 layer (EIL) or the electron transport layer (ETL) or the hole blocking layer (HBL) is smaller than 0.5 eV in one embodiment, smaller than 0.3 eV in another embodiment, smaller than 0.2 eV in another embodiment. In principle, all materials capable of using as the cathode of the OLED may be used as the cathode material of the device of the present disclosure. Examples of the cathode material include, but are not limited to, Al, Au, Ag, Ca, Ba, Mg, LiF/Al, MgAg alloy, BaF₂/Al, Cu, Fe, Co, Ni, Mn, Pd, Pt, ITO, and the like. The cathode material may be deposited by any suitable technologies, such as the suitable physical vapor deposition method which includes a radio frequency magnetron sputtering, a vacuum thermal evaporation, an electron beam, and the like.

The OLED can also comprise other functional layers such as a hole injection layer (HIL), a hole transport layer (HTL), an electron blocking layer (EBL), an electron injection layer (EIL), an electron transport layer (ETL), and a hole blocking layer (HBL). The materials suitable for use in such functional layers are described in detail above.

In one embodiment, in the light-emitting device according to the present disclosure, the light-emitting layer comprises the organometallic complex or polymer of the present disclosure and is prepared by a solution processing method.

The light-emitting wavelength of the light-emitting device according to the present disclosure is between 300 and 1000 nm. In one embodiment, the light-emitting wavelength of the light-emitting device according to the present disclosure is between 350 and 900 nm. In another embodiment, the light-emitting wavelength of the light-emitting device according to the present disclosure is between 400 and 800 nm.

The present disclosure also relates to the application of the organic electronic device according to the present disclosure in various electronic equipment, including, but not limited to display equipments, lighting equipments, light sources, and sensors, and the like.

The present disclosure will be described below with reference to the preferred embodiments, but the present disclosure is not limited to the following embodiments. It should be understood that the appended claims summarized the scope of the present disclosure. Those skilled in the art should realize that certain changes to the embodiments of the present disclosure that are made under the guidance of the concept of the present disclosure will be covered by the spirit and scope of the claims of the present disclosure.

### DETAILED EXAMPLES

### 1. Synthesis of Compounds

### Example 1

### Synthesis of Compound (2-2)

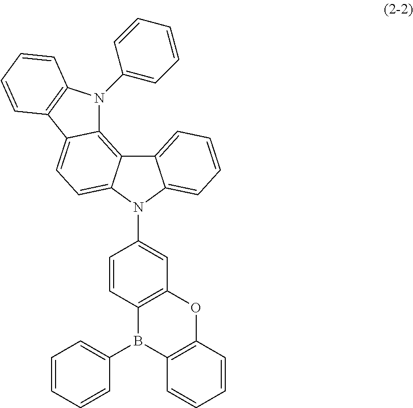 [SMILES: c1ccc(B2c3ccccc3Oc3cc(-n4c5ccccc5c5c4ccc4c6ccccc6n(-c6ccccc6)c45)ccc32)cc1]

1)

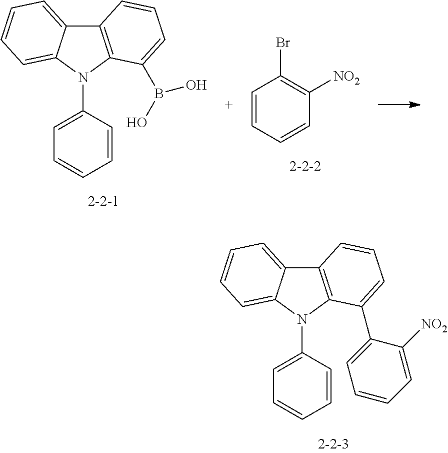 [SMILES: OB(O)c1cccc2c3ccccc3n(-c3ccccc3)c12 ; O=[N+]([O-])c1ccccc1Br ; O=[N+]([O-])c1ccccc1-c1cccc2c3ccccc3n(-c3ccccc3)c12]

1-boronic acid-9-phenylcarbazole (28.7 g, 100 mmol), 2-bromonitrobenzene (20.2 g, 100 mmol), tetrakis(triphenylphosphine)palladium (3.5 g, 3 mmol), tetrabutylammonium bromide (3.3 g, 10 mmol), sodium hydroxide (8 g, 200 mmol), water (10 mL) and toluene (100 mL) were added to a 250 mL three-necked flask under nitrogen atmosphere, and the mixture was heated to 80° C. and reacted under stirring for 12 hours, and then the reaction was ended. The reaction solution was rotary evaporated to remove most of the solvent, and then dissolved with dichloromethane and washed with water for 3 times. The organic solution was collected, mixed with silica gel, and then purified by column chromatography, with a yield of 80%.

2)

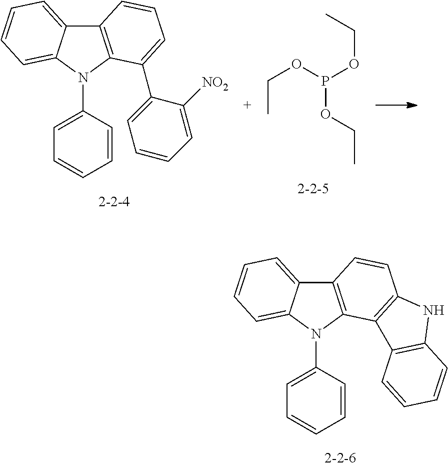

Compound 2-2-4 (18.2 g, 50 mmol) and triethylphosphine (20.2 g, 200 mmol) were added to a 150 mL two-necked flask under nitrogen atmosphere, and the mixture was heated to 190° C. and reacted under stirring for 12 hours, and then the reaction was ended. The reaction solution was distilled under reduced pressure to remove most of the solvent, and then dissolved with dichloromethane and washed with water for 3 times. The organic solution was collected, mixed with silica gel, and purified by column chromatography, with a yield of 85%.

3)

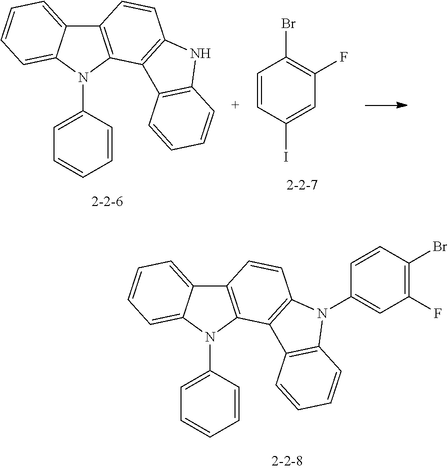

Compound 2-2-6 (6.6 g, 20 mmol) obtained in the previous step and compound (6 g, 20 mmol) 2-2-7, copper powder (0.13 g, 2 mmol), potassium carbonate (5.5 g, 40 mmol) and 18-crown-6 (0.53 g, 1 mmol) and o-dichlorobenzene (50 mL) were added to a 100 mL two-necked flask under nitrogen atmosphere, and the mixture was heated to 150° C. and reacted under stirring for 24 hours, and then the reaction was ended. The reaction solution was distilled under reduced pressure to remove most of the solvent, and then dissolved with dichloromethane and washed with water for 3 times. The organic solution was collected, mixed with silica gel, and purified by column chromatography, with a yield of 60%.

4)

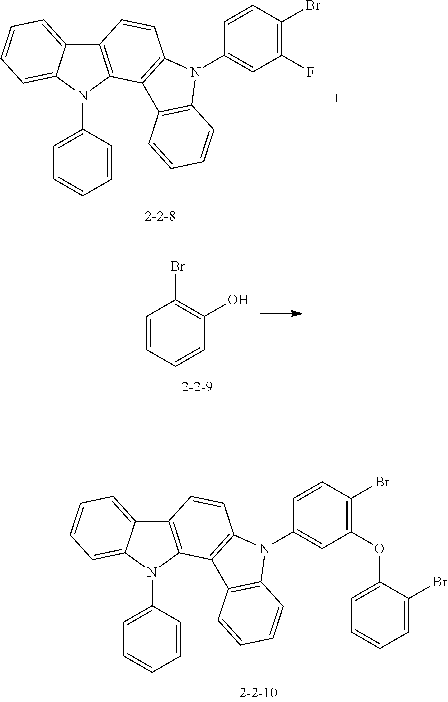 [SMILES: Fc1cc(-n2c3ccccc3c3c2ccc2c4ccccc4n(-c4ccccc4)c23)ccc1Br ; Oc1ccccc1Br ; Brc1ccccc1Oc1cc(-n2c3ccccc3c3c2ccc2c4ccccc4n(-c4ccccc4)c23)ccc1Br]

Compound 2-2-8 (5 g, 10 mmol), compound 2-2-9 (1.7 g, 10 mmol), potassium carbonate (2.7 g, 20 mmol), and 30 mL of N,N-dimethylformamide (DMF) were added into a 100 mL two-necked flask, and the mixture was heated to 100° C. and reacted under stirring for 12 hours, and then the reaction was ended. The reaction solution was added to 400 mL of water and filtered with suction. The filter residue was recrystallized with a mixture solution of dichloromethane and ethanol, with a yield of 90%.

5)

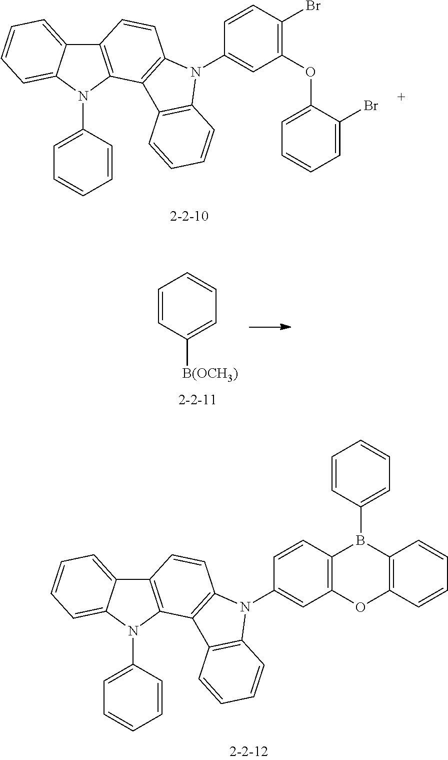

Compound 2-2-10 (4 g, 6 mmol) and 20 mL of anhydrous tetrahydrofuran were added to a 50 mL two-necked flask under nitrogen atmosphere, and 15 mmol of n-butyllithium was added dropwise at −78° C. The mixture was reacted under stirring for 1.5 hours, then the tetrahydrofuran solution of compound 2-2-11 (7.2 g, 6 mmol) was added, and the reaction solution was slowly heated to room temperature and reacted for 12 hours, and then the reaction was ended. The reaction was quenched by addition of water, and the reaction solution was rotary evaporated to remove most of the solvent, and then dissolved with dichloromethane and washed with water for 3 times. The organic solution was collected, mixed with silica gel, and purified by column chromatography, with a yield of 70%.

### Example 2

### Synthesis of Compound (3-2):

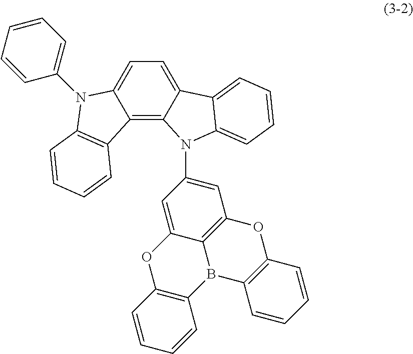 [SMILES: c1ccc(-n2c3ccccc3c3c2ccc2c4ccccc4n(-c4cc5c6c(c4)Oc4ccccc4B6c4ccccc4O5)c23)cc1]

1)

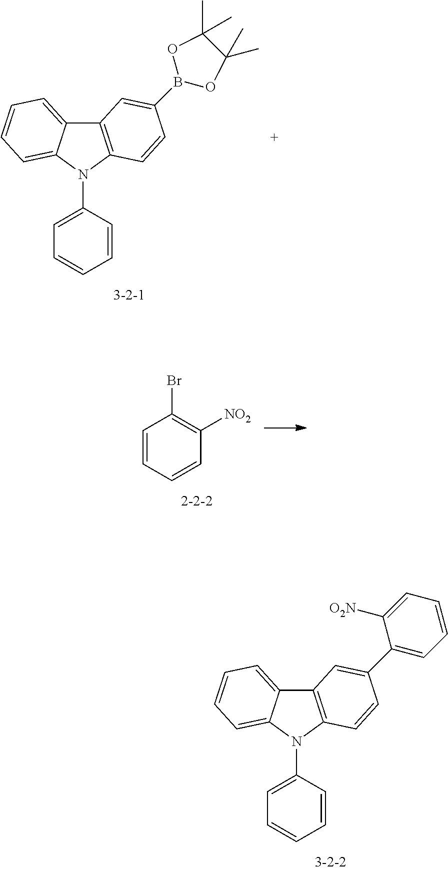 [SMILES: CC1(C)OB(c2ccc3c(c2)c2ccccc2n3-c2ccccc2)OC1(C)C ; O=[N+]([O-])c1ccccc1Br ; O=[N+]([O-])c1ccccc1-c1ccc2c(c1)c1ccccc1n2-c1ccccc1]

Compound 3-2-1 (36.9 g, 100 mmol) and 2-bromonitrobenzene (20.2 g, 100 mmol), tetrakis(triphenylphosphine)palladium (3.5 g, 3 mmol), tetrabutylammonium bromide (3.3 g, 10 mmol), sodium hydroxide (8 g, 200 mmol), water (10 mL) and toluene (100 mL) were added to a 250 mL three-necked flask under nitrogen atmosphere, and the mixture was heated to 80° C. and reacted under stirring for 12 hours, and then the reaction was ended. The reaction solution was rotary evaporated to remove most of the solvent, and then dissolved with dichloromethane and washed with water for 3 times. The organic solution was collected, mixed with silica gel, and then purified by column chromatography, with a yield of 75%.

2)

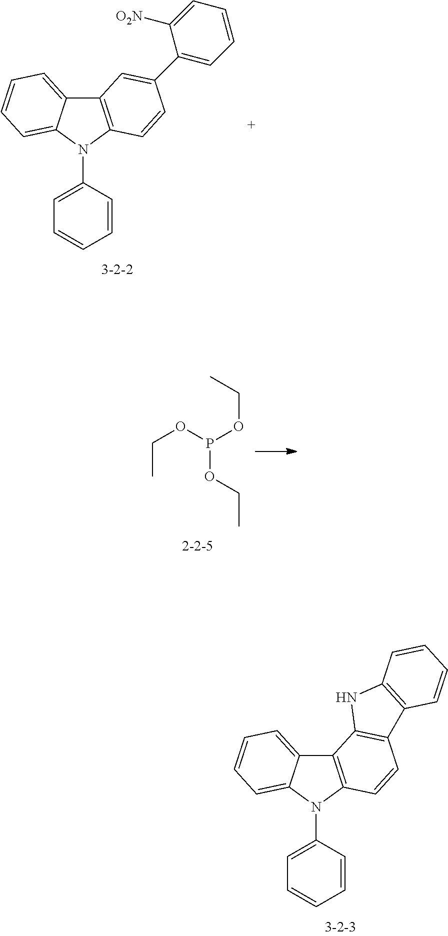

Compound 3-2-2 (18.2 g, 50 mmol) and triethylphosphine (20.2 g, 200 mmol) were added to a 150 mL two-necked flask under nitrogen atmosphere, and the mixture was heated to 190° C. and reacted under stirring for 12 hours, and then the reaction was ended. The reaction solution was distilled under reduced pressure to remove most of the solvent, and then dissolved with dichloromethane and washed with water for 3 times. The organic solution was collected, mixed with silica gel, and purified by column chromatography, with a yield of 80%.

3)

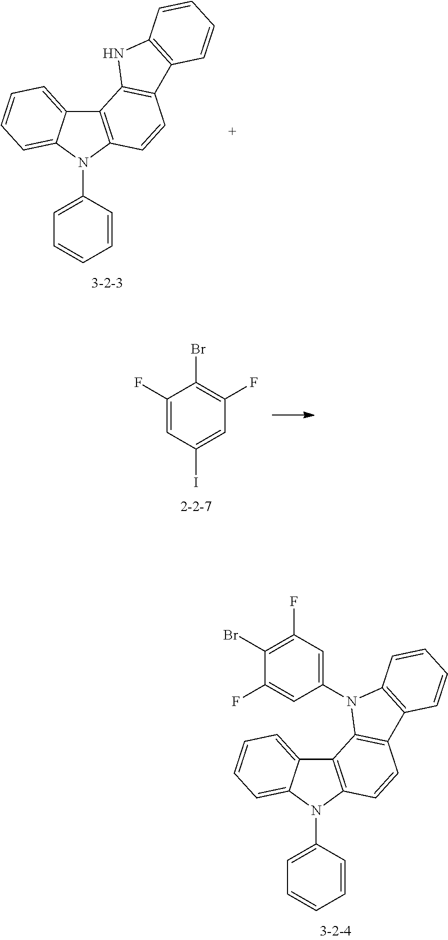 [SMILES: c1ccc(-n2c3ccccc3c3c4[nH]c5ccccc5c4ccc32)cc1 ; Fc1cc(I)cc(F)c1Br ; Fc1cc(-n2c3ccccc3c3ccc4c(c5ccccc5n4-c4ccccc4)c32)cc(F)c1Br]

Compound 3-2-3 (6.6 g, 20 mmol) obtained in the previous step and compound 2-2-7 (6.38 g, 20 mmol), copper powder (0.13 g, 2 mmol), potassium carbonate (5.5 g, 40 mmol) and 18-crown-6 (0.53 g, 1 mmol) and o-dichlorobenzene (50 mL) were added to a 100 mL two-necked flask under nitrogen atmosphere, and the mixture was heated to 150° C. and reacted under stirring for 24 hours, and then the reaction was ended. The reaction solution was distilled under reduced pressure to remove most of the solvent, and then dissolved with dichloromethane and washed with water for 3 times. The organic solution was collected and then mixed with silica gel, and purified by column chromatography, with a yield of 50%.

4)

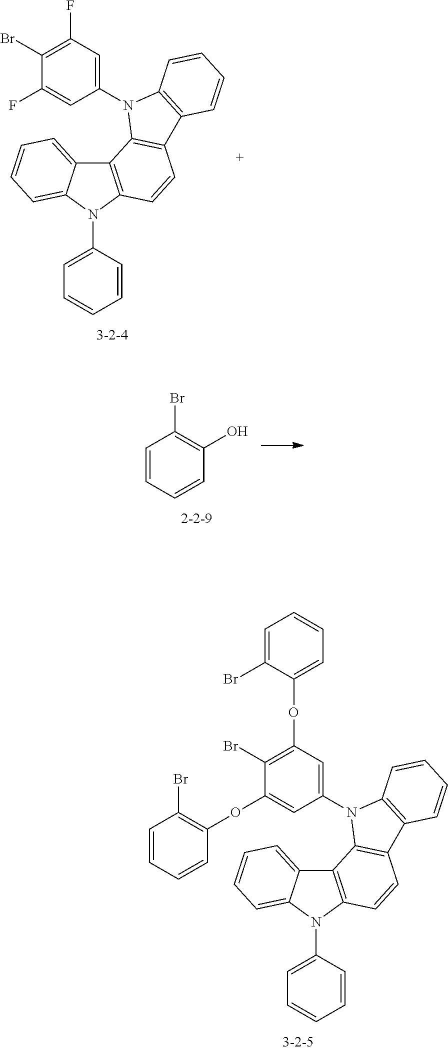 [SMILES: Fc1cc(-n2c3ccccc3c3ccc4c(c5ccccc5n4-c4ccccc4)c32)cc(F)c1Br ; Oc1ccccc1Br ; Brc1ccccc1Oc1cc(-n2c3ccccc3c3ccc4c(c5ccccc5n4-c4ccccc4)c32)cc(Oc2ccccc2Br)c1Br]

Compound 3-2-4 (5.23 g, 10 mmol), compound 2-2-9 (3.4 g, 20 mmol), potassium carbonate (2.7 g, 20 mmol), and 30 mL of N,N-dimethylformamide (DMF) were added into a 100 mL two-necked flask, and the mixture was heated to 100° C. and reacted under stirring for 12 hours, and then the reaction was ended. The reaction solution was added to 400 mL of water and filtered with suction. The filter residue was recrystallized with a mixture solution of dichloromethane and ethanol, with a yield of 85%.

5)

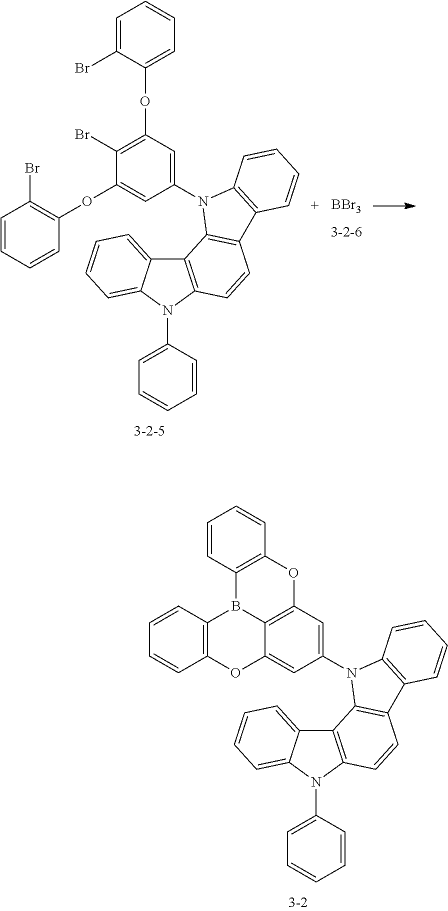

Compound 3-2-5 (5 g, 6 mmol) and 40 mL of anhydrous tetrahydrofuran were added to a 100 mL two-necked flask under nitrogen atmosphere, and 24 mmol of n-butyllithium was added dropwise at −78° C. The mixture was reacted under stirring for 1.5 hours, then the tetrahydrofuran solution of compound 3-2-6 (7.2 g, 6 mmol) was added, and the reaction solution was slowly heated to room temperature and reacted for 12 hours, and then the reaction was ended. The reaction was quenched by addition of water, and the reaction solution was rotary evaporated to remove most of the solvent, and then dissolved with dichloromethane and washed with water 3 times. The organic solution was collected, mixed with silica gel, and purified by column chromatography, with a yield of 65%.

### 2. Energy Structure of Organic Compounds

The energy levels of organic materials can be obtained by quantum calculations, such as using TD-DFT (Time Dependent-Density Functional Theory) by Gaussian03W (Gaussian Inc.), and the specific simulation methods can be found in WO2011141110. Firstly, the molecular geometry is optimized by semi-empirical method “Ground State/Semi-empirical/Default Spin/AM1” (Charge 0/Spin Singlet), and then the energy structure of organic molecules is calculated by TD-DFT (time-density functional theory) “TD-SCF/DFT/Default Spin/B3PW91” and the basis set “6-31G (d)” (Charge 0/Spin Singlet). The HOMO and LUMO levels are calculated according to the following calibration formulas, S1 and T1 are used directly.

HOMO(eV)=((HOMO(G)×27.212)−0.9899)/1.1206

LUMO(eV)=((LUMO(G)×27.212)−2.0041)/1.385

wherein HOMO(G) and LUMO(G) in the unit of Hartree are the direct calculation results of Gaussian 03W. The results were shown in Table 1.

TABLE 1

| Materials | HOMO [eV] | LUMO [eV] | T1 [eV] | S1 [eV] |
|---|---|---|---|---|
| HATCN | −9.04 | −5.08 | 2.32 | 3.17 |
| NPB | −6.72 | −2.85 | 2.97 | 3.46 |
| TCTA | −5.34 | −2.20 | 2.73 | 3.42 |
| 2-2 | −5.50 | −2.82 | 2.75 | 2.84 |
| 3-2 | −5.52 | −2.80 | 2.83 | 2.94 |
| Ir(ppy)₃ | −5.30 | −2.35 | 2.70 | 2.93 |
| B3PYMPM | −5.33 | −2.20 | 2.72 | 3.28 |

### 3. Preparation and Characterization of OLED Devices

In the present embodiment, compounds (2-2) and (3-2) were used as the host material, Ir(ppy)₃ as the light-emitting material, HATCN as the hole injection material, NPB and TCTA as the hole transport material, and B3PYMPM as the electron transport material, to make an electroluminescent device have a device structure of ITO/HATCN/NPB/TCTA/host material: Ir(ppy)₃(15%)/B3PYMPM/LiF/Al.

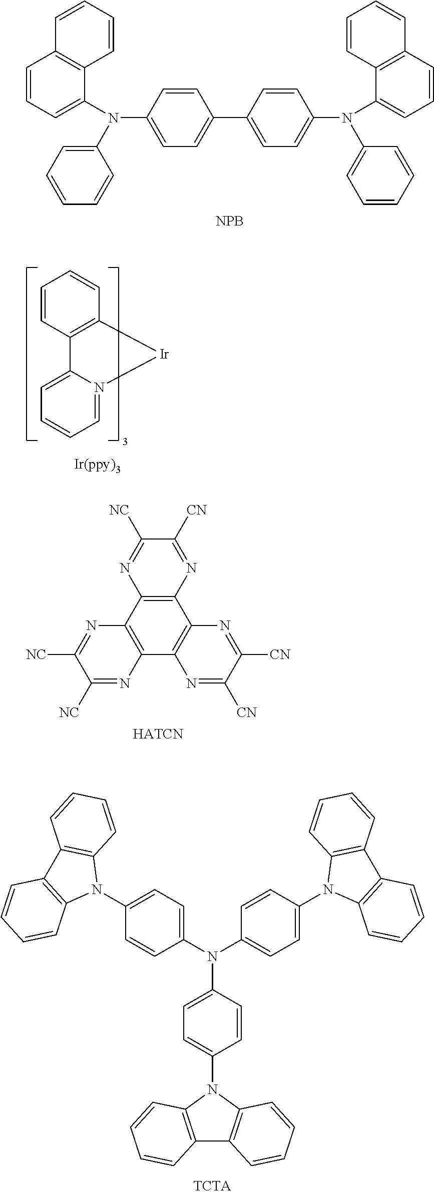

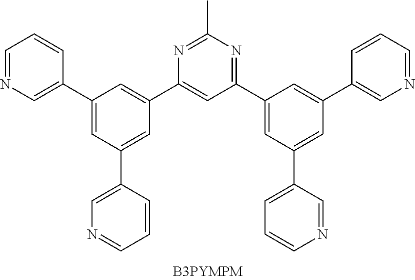 [SMILES: Cc1nc(-c2cc(-c3cccnc3)cc(-c3cccnc3)c2)cc(-c2cc(-c3cccnc3)cc(-c3cccnc3)c2)n1]

The above materials such as HATCN, NPB, TCTA, B3PYMPM, Ir(ppy)₃ are all commercially available, such as from Jilin OLED Material Tech Co., Ltd (www.jl-oled.com), or all the synthesis methods thereof are all known which can be found in the references of the art and will not be described here.

The preparation process of the above OLED device will be described in detail through a specific embodiment. The structure of the OLED device (as shown in Table 2) is: ITO/HATCN/NPB/TCTA/host material: Ir(ppy)₃/B3PYMPM/LiF/Al, and the preparation steps are as follows:

a. Cleaning of ITO (Indium Tin Oxide) conductive glass substrate: cleaning with a variety of solvents (such as one or more of chloroform, acetone or isopropanol), and then treating with ultraviolet and ozone;

b. Performing thermal evaporation in high vacuum (1×10⁻⁶ mbar), to form HATCN (5 nm), NPB (40 nm), TCTA (10 nm), host material: 15% Ir(ppy)₃ (15 nm), B3PYMPM (40 nm), LiF (1 nm), Al (100 nm));

c. Encapsulating: encapsulating the device with UV-curable resin in a nitrogen glove box.

TABLE 2

| OLED devices | Host materials |
|---|---|
| OLED1 | (2-2) |
| OLED2 | (3-2) |
| OLED3 | Ref1 |

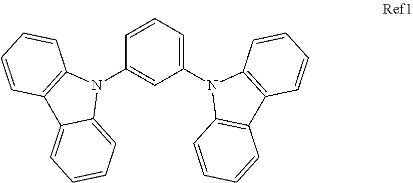 [SMILES: c1cc(-n2c3ccccc3c3ccccc32)cc(-n2c3ccccc3c3ccccc32)c1]

The current-voltage (J-V) characteristics of each OLED device are characterized by characterization equipment while important parameters such as efficiency, lifetime, and external quantum efficiency were recorded. As detected, OLED1, OLED2 and Ref OELD1 all emitted green light, and the external quantum efficiencies were 13.4%, 15.6% and 8.1%, respectively. At the same time, the lifetimes of OLED1 and OLED2 are 6.5 and 10.4 times that of Ref OELD1, respectively. It can be seen that the efficiency and lifetime of the OLED device prepared by using the organic compound of the present disclosure have been greatly improved.

1-18. (canceled)

19. A D-A type compound, which has the following general formula (1): 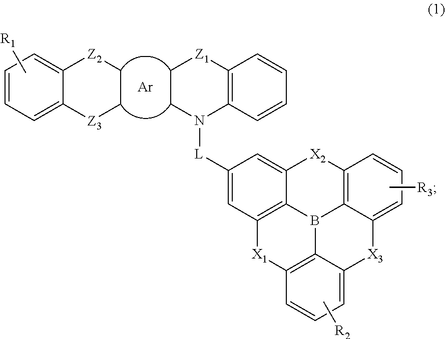
wherein L is a linking unit, -L- is selected from the group consisting of a single bond, a double bond, a triple bond, an aromatic group with a carbon atom number of 6 to 40, and a heteroaromatic group with a carbon atom number of 3 to 40;
Ar is an aromatic group with a carbon atom number of 6 to 20, or a heteroaromatic group with a carbon atom number of 3 to 20;
Z₁, Z₂ and Z₃ independently represent a single bond, N(R), B(R), C(R)₂, Si(R)₂, O, C═N(R), C═C(R)₂, P(R), P(═O)R, S, S═O or SO₂, respectively;
X₁, X₂ and X₃ independently optionally represent N(R), C(R)₂, Si(R)₂, O, C═N(R), C═C(R)₂, P(R), P(═O)R, S, S═O or SO₂, respectively;
R, R₁, R₂ and R₃ independently represent H, D, F, CN, aralkyl, alkenyl, alkynyl, nitrile, amine, nitro, acyl, alkoxy, carbonyl, sulfonyl, hydroxyl, alkyl with a carbon atom number of 1 to 30, cycloalkyl with a carbon atom number of 3 to 30, aromatic hydrocarbyl with a carbon atom number of 6 to 60, or aromatic heterocyclyl with a carbon atom number of 3 to 60, respectively.

20. The D-A type compound according to claim 19, wherein Ar of the general formula (1) is selected from the group consisting of: 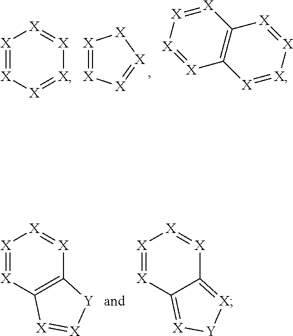
wherein,
X is CR¹ or N;
Y is selected from the group consisting of CR²R³, SiR²R³, NR², C(═O), S and O;
R¹, R², or R³ is H, or D, or linear alkyl containing 1 to 20 carbon atoms, linear alkoxy containing 1 to 20 carbon atoms or linear thioalkoxy groups containing 1 to 20 carbon atoms, or branched or cyclic alkyl containing 3 to 20 carbon atoms, branched or cyclic alkyl alkoxy containing 3 to 20 carbon atoms or branched or cyclic alkyl thioalkoxy group containing 3 to 20 carbon atoms or branched or cyclic alkyl silyl group containing 3 to 20 carbon atoms, or substituted keto group containing 1 to 20 carbon atoms, alkoxycarbonyl group containing 2 to 20 carbon atoms, aryloxycarbonyl groups containing 7 to 20 carbon atoms, cyano group (—CN), carbamoyl group (—C(═O)NH₂), haloformyl group (—C(═O)-A, wherein A represents halogen atom), formyl group (—C(═O)—H), isocyano group, isocyanate group, thiocyanate group, or isothiocyanate group, hydroxyl group, nitro group, CF₃ group, Cl, Br, F, crosslinkable group, or substituted or unsubstituted aromatic or heteroaromatic ring system containing 5 to 40 ring atoms, aryloxy or heteroaryloxy groups containing 5 to 40 ring atoms, or combination of these systems, wherein R¹, R², and R³ may form a monocyclic or polycyclic aliphatic or aromatic ring system with each other and/or with a ring bonded thereto.

21. The D-A type compound according to claim 19, wherein Ar in general formula (1) is selected from one of the following structural groups, or Ar is selected from the substituted groups obtained by substituting the following structural groups: 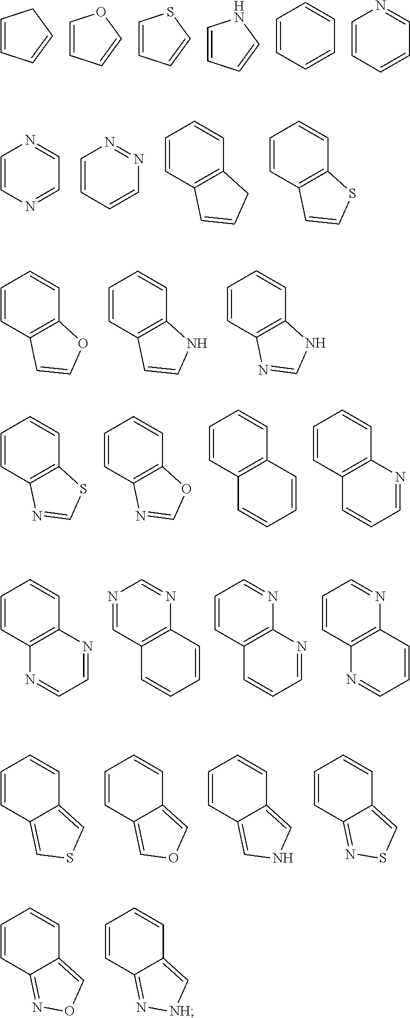
wherein, the linking position of Ar group may be on any adjacent carbon atom on the selected group.

22. The D-A type compound according to claim 19, wherein the structure of the D-A type compound is represented by any one of the following formulas (2) to (4): 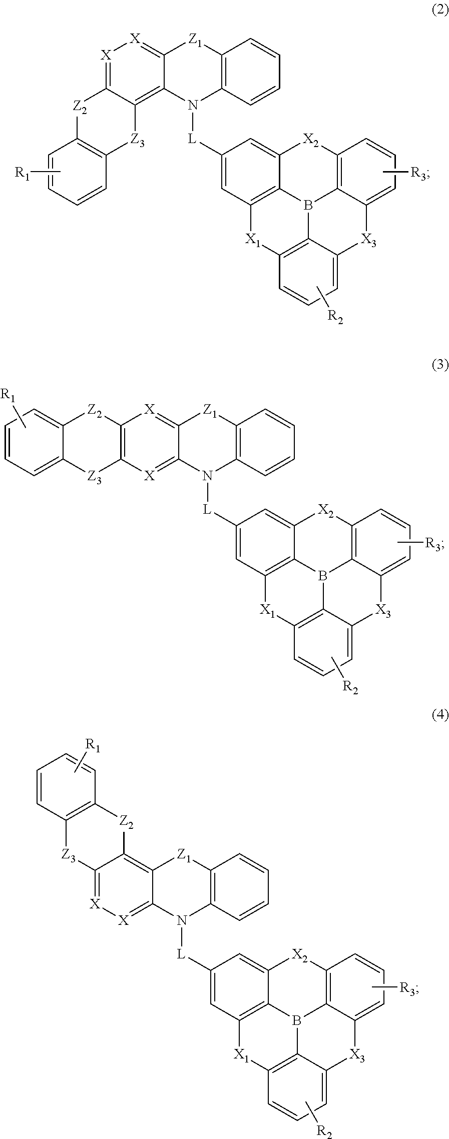
wherein L is a linking unit, L is selected from the group consisting of a single bond, a double bond, a triple bond, an aromatic group with a carbon atom number of 6 to 40, and a heteroaromatic group with a carbon atom number of 3 to 40;
Z₁, Z₂ and Z₃ independently represent a single bond, N(R), B(R), C(R)₂, Si(R)₂, O, C═N(R), C═C(R)₂, P(R), P(═O)R, S, S═O or SO₂, respectively;
X₁, X₂ and X₃ independently represent N(R), C(R)₂, Si(R)₂, O, C═N(R), C═C(R)₂, P(R), P(═O)R, S, S═O, SO₂ or absent, respectively, but at least one is not absent;
R, R₁, R₂ and R₃ independently represent H, D, F, CN, aralkyl, alkenyl, alkynyl, nitrile, amine, nitro, acyl, alkoxy, carbonyl, sulfonyl, hydroxyl, alkyl with a carbon atom number of 1 to 30, cycloalkyl with a carbon atom number of 3 to 30, aromatic hydrocarbyl with a carbon atom number of 6 to 60, or aromatic heterocyclyl with a carbon atom number of 3 to 60, respectively;
X is CR¹ or N, wherein R¹ is H, or D, or linear alkyl containing 1 to 20 carbon atoms, linear alkoxy containing 1 to 20 carbon atoms or linear thioalkoxy group containing 1 to 20 carbon atoms, or branched or cyclic alkyl containing 3 to 20 carbon atoms, branched or cyclic alkoxy containing 3 to 20 carbon atoms or branched or cyclic thioalkoxy group containing 3 to 20 carbon atoms or branched or cyclic silyl group containing 3 to 20 carbon atoms, or substituted keto group containing 1 to 20 carbon atoms, alkoxycarbonyl groups containing 2 to 20 carbon atoms, aryloxycarbonyl groups containing 7 to 20 carbon atoms, cyano group (—CN), carbamoyl group (—C(═O)NH₂), haloformyl group (—C(═O)-A, wherein A represents halogen atom), formyl group (—C(═O)—H), isocyano group, isocyanate group, thiocyanate group, or isothiocyanate group, hydroxyl group, nitro group, CF₃ group, Cl, Br, F, crosslinkable group, or substituted or unsubstituted aromatic or heteroaromatic ring system containing 5 to 40 ring atoms, aryloxy or heteroaryloxy group containing 5 to 40 ring atoms, or combination of these systems, wherein R¹, R², and R³ may form a monocyclic or polycyclic aliphatic or aromatic ring system with each other and/or with a ring bonded thereto.

23. The D-A type compound according to claim 19, wherein L is selected from the substituted groups obtained by substituting the following structural groups, 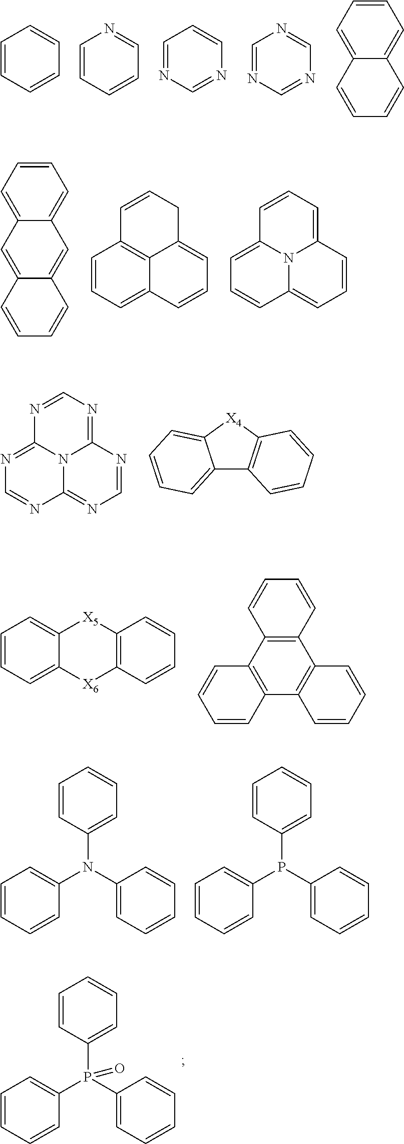
wherein X₄ represents N(R), C(R)₂, Si(R)₂, O, C═N(R), C═C(R)₂, P(R), P(═O)R, S, S═O or SO₂; X₅ and X₆ independently represent N(R), C(R)₂, Si(R)₂, O, C═N(R), C═C(R)₂, P(R), P(═O)R, S, S═O, SO₂ or absent, respectively, but at least one of X₅ and X₆ is not absent, R represents H, D, F, CN, aralkyl, alkenyl, alkynyl, nitrile, amine, nitro, acyl, alkoxy, carbonyl, sulfonyl, hydroxyl, alkyl with a carbon atom number of 1 to 30, cycloalkyl with a carbon atom number of 3 to 30, aromatic hydrocarbyl with a carbon atom number of 6 to 60, and aromatic heterocyclyl with a carbon atom number of 3 to 60, respectively.

24. The D-A type compound according to claim 22, which is selected from one of the following structural formulas: 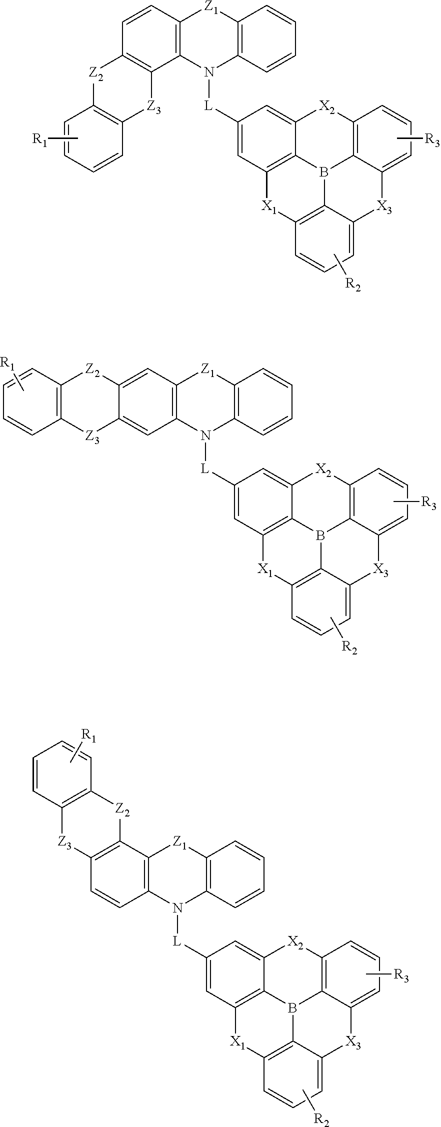 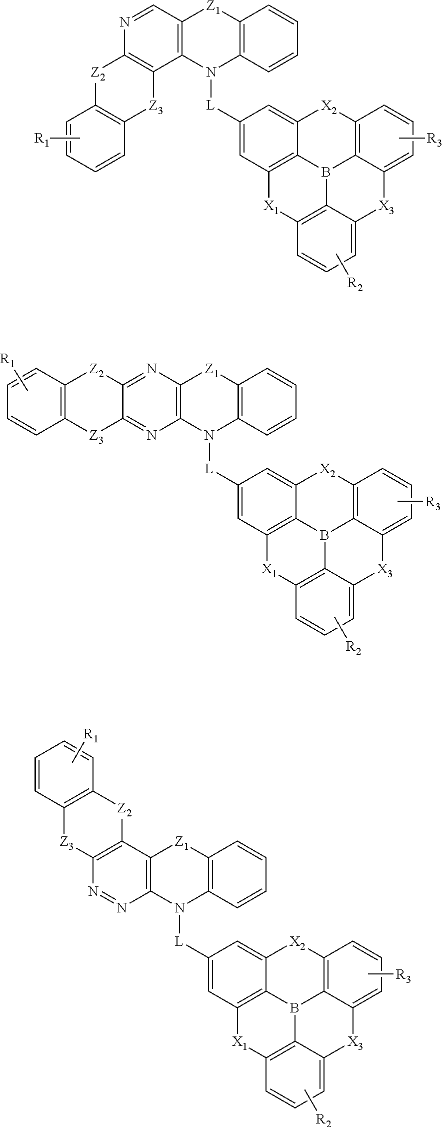 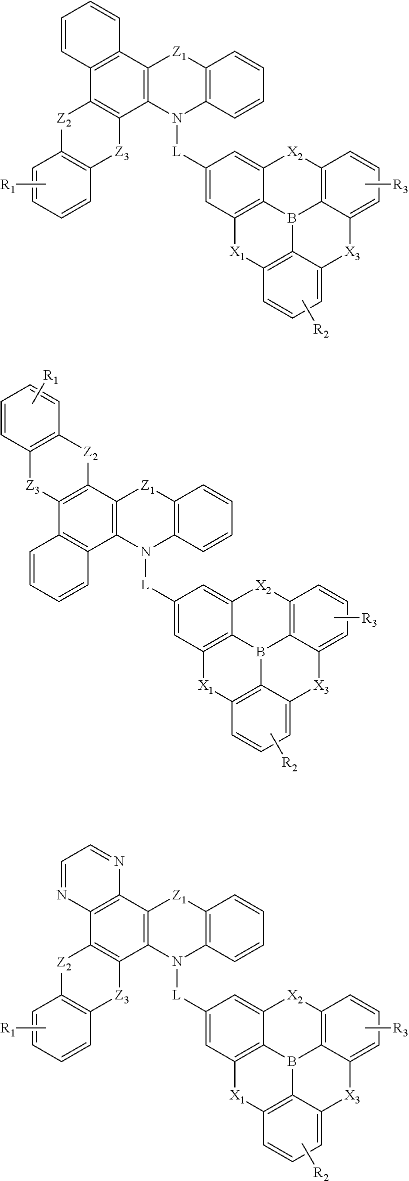 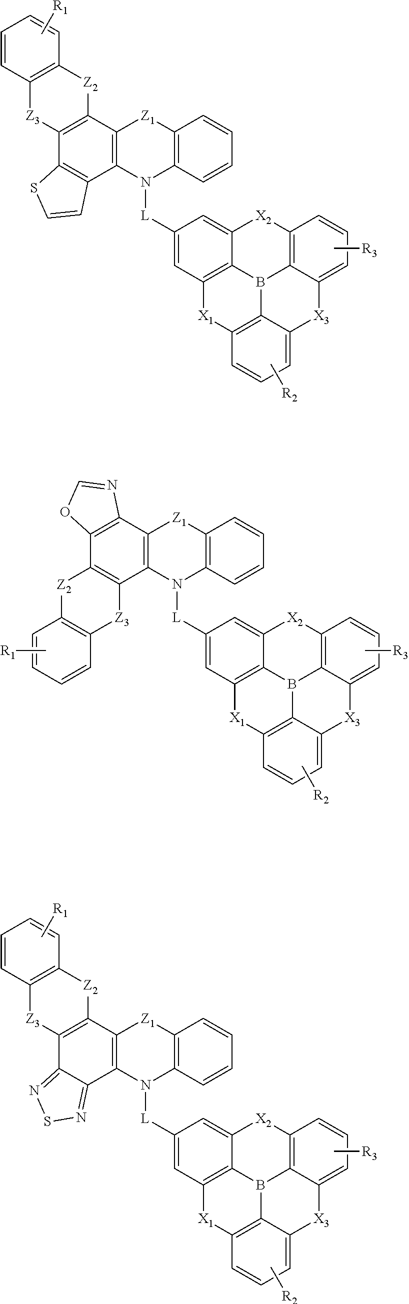 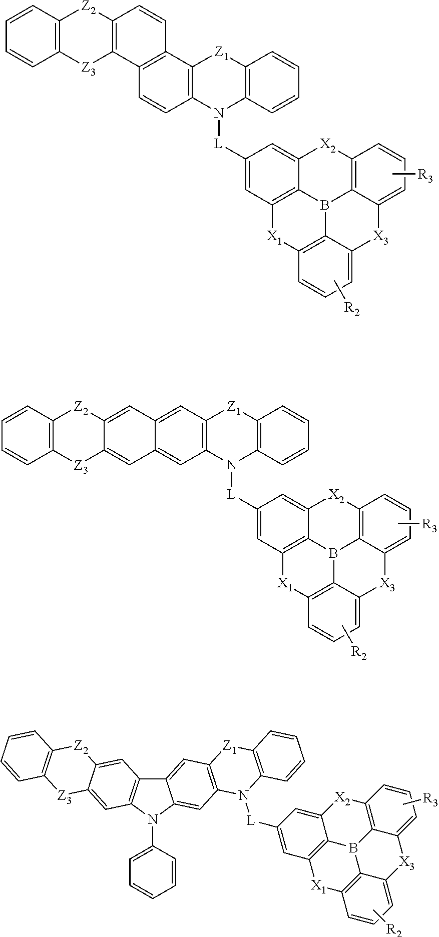 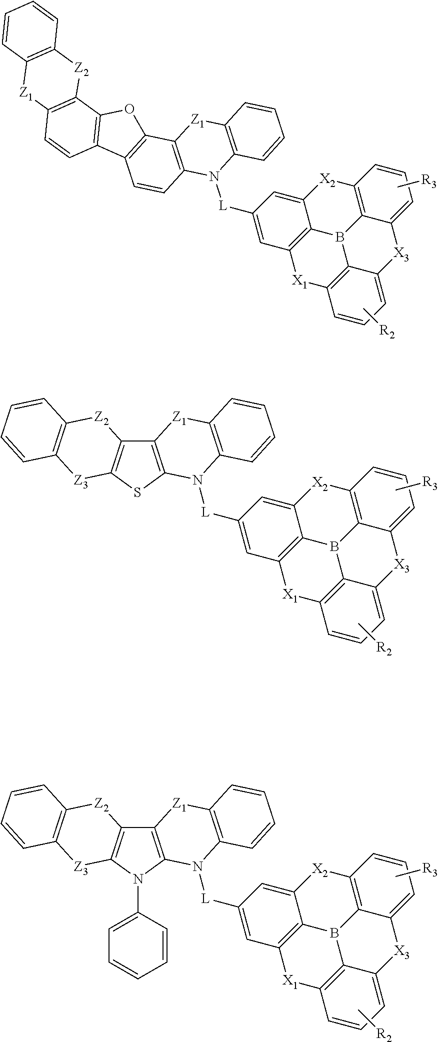 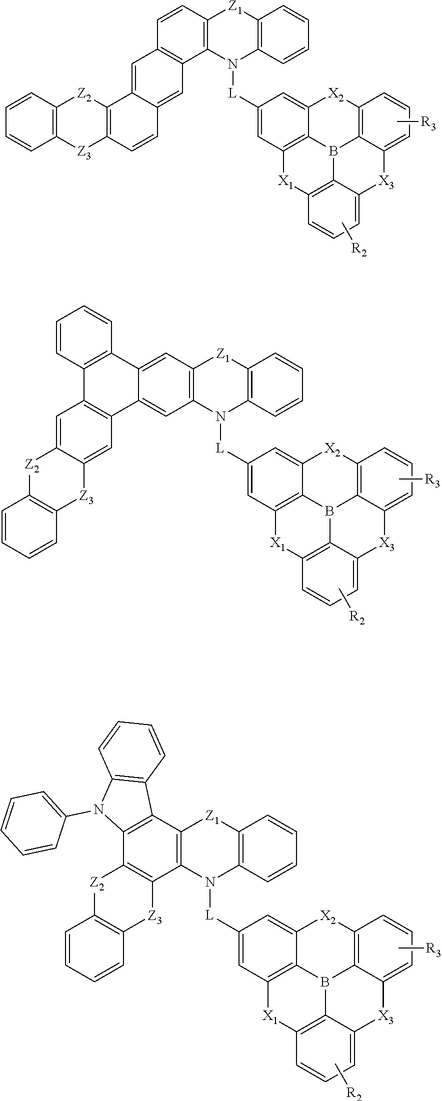
wherein, R₁, R₂, R₃, Z₁, Z₂, Z₃, X₁, X₂, and X₃ are as defined above.

25. The D-A type compound according to claim 22, which is selected from one of the following structural formulas: 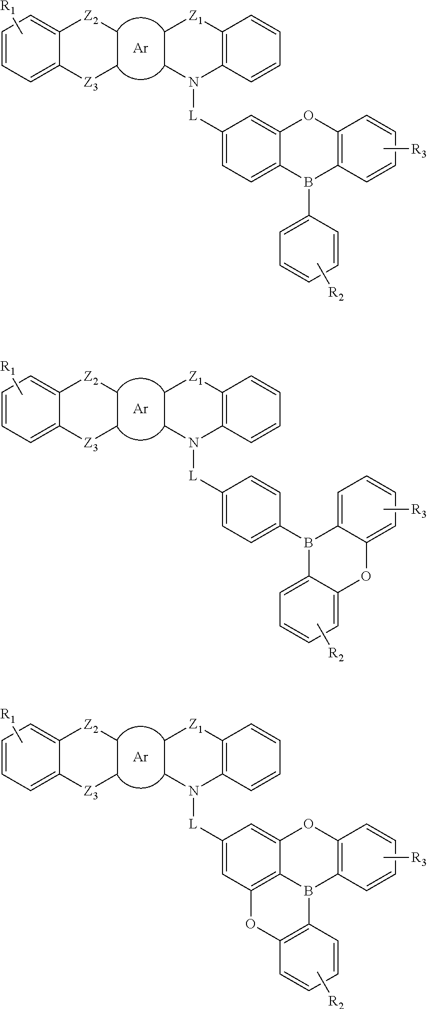 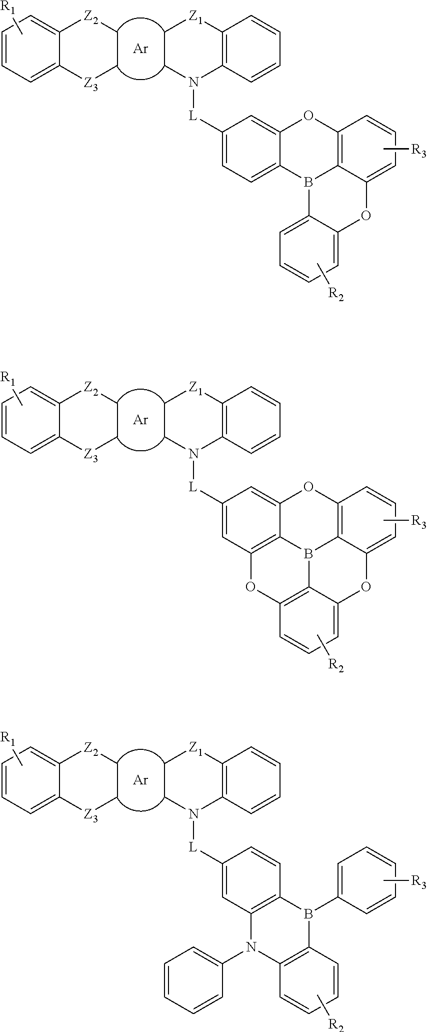 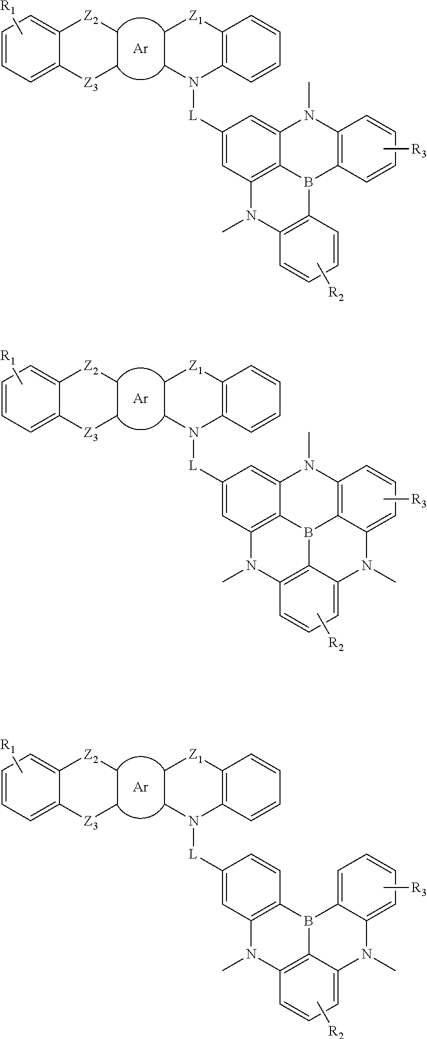 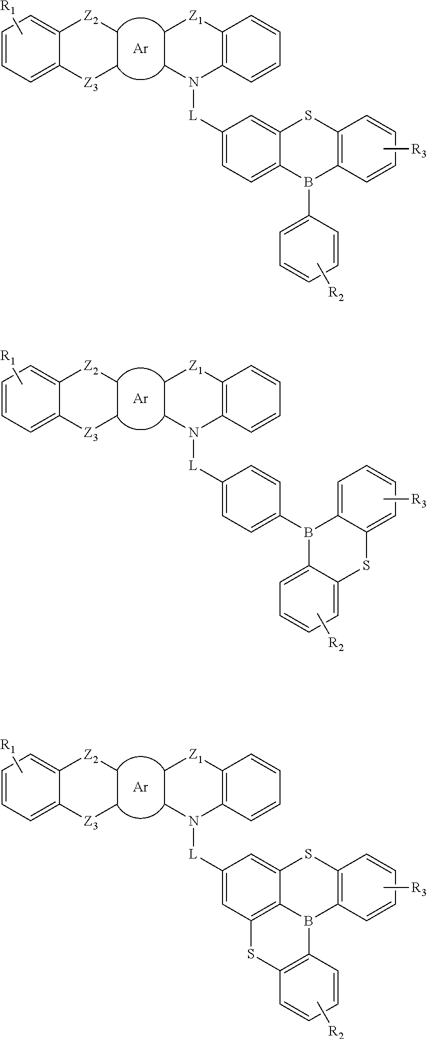 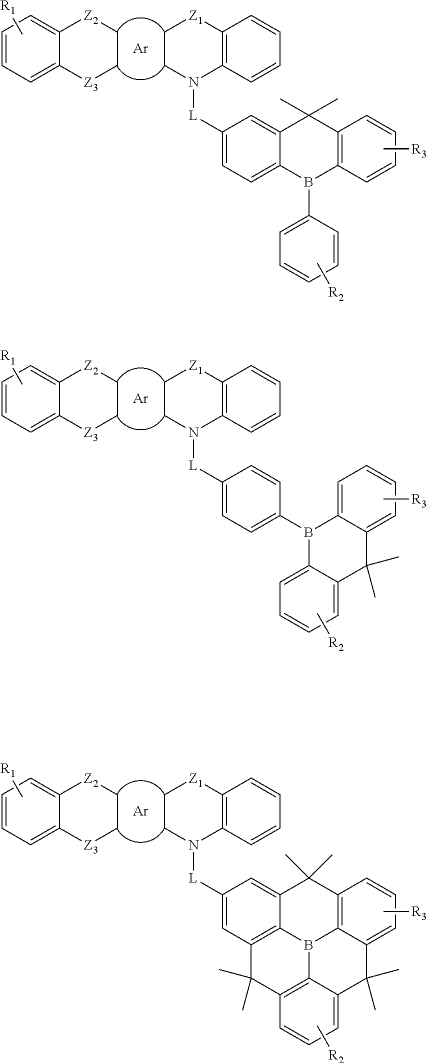 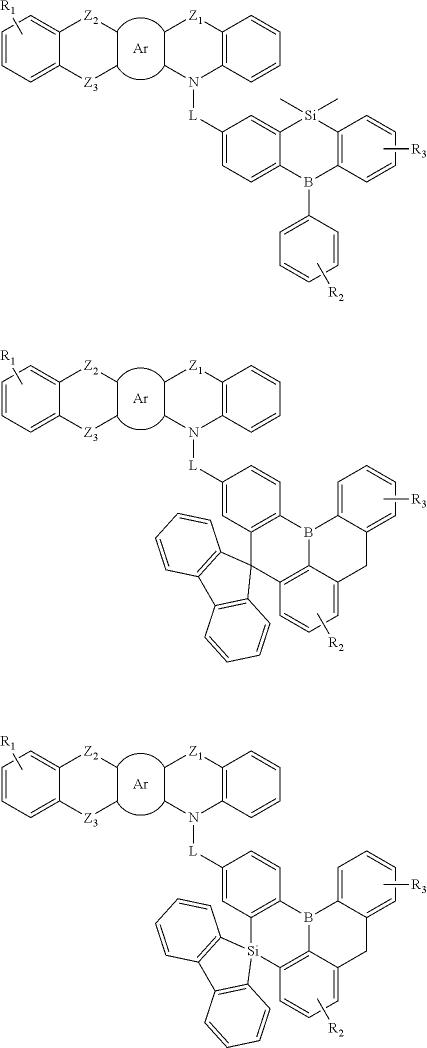
wherein, R₁, R₂, R₃, Z₁, Z₂, Z₃, and Ar are as defined above.

26. The D-A type compound according to claim 19, wherein the D-A type compound has a triplet energy level T₁≥2.2 eV.

27. The D-A type compound according to claim 19, wherein the D-A type compound has a glass transition temperature T_{g}≥100° C.

28. The D-A type compound according to claim 19, wherein the D-A type compound has a difference between the singlet and triplet energy levels Δ(S₁−T₁)≤0.30 eV.

29. A formulation comprising at least one D-A type compound according to claim 19 and at least one organic solvent.

30. The formulation according to claim 29, wherein the organic solvent is selected from aliphatic chain/ring substituted aromatic solvents, or aromatic ketone solvents, or aromatic ether solvents.

31. The formulation according to claim 29, wherein the organic solvent is selected from one of the group consisting of p-diisopropylbenzene, pentylbenzene, tetrahydronaphthalene, cyclohexyl benzene, chloronaphthalene, 1,4-dimethylnaphthalene, 3-isopropylbiphenyl, p-cymene, dipentylbenzene, tripentylbenzene, pentyltoluene, o-xylene, m-xylene, p-xylene, o-diethylbenzene, m-diethylbenzene, p-diethylbenzene, 1,2,3,4-tetramethylbenzene, 1,2,3,5-tetramethylbenzene, 1,2,4,5-tetramethylbenzene, butylbenzene, dodecylbenzene, dihexylbenzene, dibutylbenzene, p-diisopropylbenzene, 1-methoxynaphthalene, cyclohexylbenzene, dimethylnaphthalene, 3-isopropylbiphenyl, p-cymene, 1-methylnaphthalene, 1,2,4-trichlorobenzene, 1,3-dipropoxybenzene, 4,4-difluorodiphenylmethane, 1,2-dimethoxy-4-(1-propenyl)benzene, diphenylmethane, 2-phenylpyridine, 3-phenylpyridine, N-methyldiphenylamine 4-isopropylbiphenyl, α,α-dichlorodiphenylmethane, 4-(3-phenylpropyl)pyridine, benzylbenzoate, 1,1-di(3,4-dimethylphenyl)ethane, 2-isopropylnaphthalene, dibenzylether, and the like; solvents based on ketones: 1-tetralone, 2-tetralone, 2-(phenylepoxy)tetralone, 6-(methoxyl)tetralone, acetophenone, phenylacetone, benzophenone, and derivatives thereof, such as 4-methylacetophenone, 3-methylacetophenone, 2-methylacetophenone, 4-methylphenylacetone, 3-methylphenylacetone, 2-methylphenylacetone, isophorone, 2,6,8-trimethyl-4-nonanone, fenchone, 2-nonanone, 3-nonanone, 5-nonanone, 2-demayone, 2,5-hexanedione, phorone, di-n-amyl ketone; aromatic ether solvents: 3-phenoxytoluene, butoxybenzene, benzylbutylbenzene, p-anisaldehyde dimethyl acetal, tetrahydro-2-phenoxy-2H-pyran, 1,2-dimethoxy 4-(1-propenyl)benzene, 1,4-benzodioxane, 1,3-dipropylbenzene, 2,5-dimethoxytoluene, 4-ethylphenetole, 1,2,4-trimethoxybenzene, 4-(1-propenyl)-1,2-dimethoxybenzene, 1,3-dimethoxybenzene, glycidyl phenyl ether, dibenzyl ether, 4-tert-butylanisole, trans-p-propenylanisole, 1,2-dimethoxybenzene, 1-methoxynaphthalene, diphenyl ether, 2-phenoxymethyl ether, 2-phenoxytetrahydrofuran, ethyl-2-naphthyl ether, pentyl ether, hexyl ether, dioctyl ether, ethylene glycol dibutyl ether, diethylene glycol diethyl ether, diethylene glycol butyl methyl ether, diethylene glycol dibutyl ether, triethylene glycol dimethyl ether, triethylene glycol ethyl methyl ether, triethylene glycol butyl methyl ether, tripropylene glycol dimethyl ether, tetraethylene glycol dimethyl ether; and ester solvents: alkyl octoate, alkyl sebacate, alkyl stearate, alkyl benzoate, alkyl phenylacetate, alkyl cinnamate, alkyl oxalate, alkyl maleate, alkyl lactone and alkyl oleate.

32. The formulation according to claim 29, wherein the said organic solvent is selected from one of the group consisting of 2-nonanone, 3-nonanone, 5-nonanone, 2-demayone, 2,5-hexanedione, 2,6,8-trimethyl-4-demayone, phorone, di-n-pentyl ketone, and the like; or aliphatic ethers, such as amyl ether, hexyl ether, dioctyl ether, ethylene glycol dibutyl ether, diethylene glycol diethyl ether, diethylene glycol butyl methyl ether, diethylene glycol dibutyl ether, triethylene glycol dimethyl ether, triethyl ether alcohol ethyl methyl ether, triethylene glycol butyl methyl ether, tripropylene glycol dimethyl ether, and tetraethylene glycol dimethyl ether.

33. The formulation according to claim 29 further comprising another organic solvent.

34. An electronic device comprising at least one D-A type compound according to claim 19.

35. The electronic device according to claim 34, wherein the electronic device is selected from one of the group consisting of an organic light-emitting diode, an organic photovoltaic cell, an organic light-emitting electrochemical cell, an organic field effect transistor (OFET), an organic light-emitting field effect transistor, an organic sensor, and an organic plasmon emitting diode.

36. The electronic device according to claim 34, wherein the electronic device is an electroluminescent device, which comprises an anode, a cathode, and at least one light-emitting layer located between the anode and the cathode;
wherein the light-emitting layer comprises at least one D-A type compound, which has the following general formula (1): 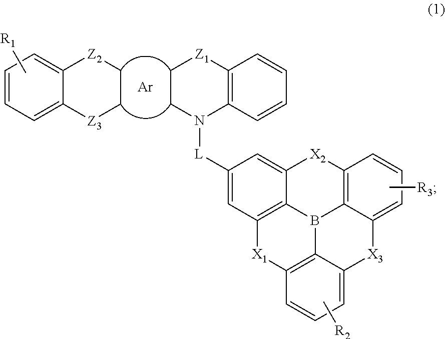
wherein L is a linking unit, -L- is selected from the group consisting of a single bond, a double bond, a triple bond, an aromatic group with a carbon atom number of 6 to 40, and a heteroaromatic group with a carbon atom number of 3 to 40;
Ar is an aromatic group with a carbon atom number of 6 to 20, or a heteroaromatic group with a carbon atom number of 3 to 20;
Z₁, Z₂ and Z₃ independently represent a single bond, N(R), B(R), C(R)₂, Si(R)₂, O, C═N(R), C═C(R)₂, P(R), P(═O)R, S, S═O or SO₂, respectively;
X₁, X₂ and X₃ independently optionally represent N(R), C(R)₂, Si(R)₂, O, C═N(R), C═C(R)₂, P(R), P(═O)R, S, S═O or SO₂, respectively;
R, R₁, R₂ and R₃ independently represent H, D, F, CN, aralkyl, alkenyl, alkynyl, nitrile, amine, nitro, acyl, alkoxy, carbonyl, sulfonyl, hydroxyl, alkyl with a carbon atom number of 1 to 30, cycloalkyl with a carbon atom number of 3 to 30, aromatic hydrocarbyl with a carbon atom number of 6 to 60, or aromatic heterocyclyl with a carbon atom number of 3 to 60, respectively;
and a light-emitting material, and
the light-emitting material is selected from the group consisting of a fluorescent emitter, a phosphorescent emitter, a TADF material and a light-emitting quantum dot.

37. The electronic device according to claim 36, wherein the light-emitting layer further comprises a light-emitting material, which is selected from the group consisting of a fluorescent emitter, a phosphorescent emitter, a TADF material and a light-emitting quantum dot.
